(19) United States
(12) Patent Application Publication
(10) Pub. No.: US 2015/0318498 A1
(43) Pub. Date: Nov. 5, 2015

(54) Metal Complexes

(71) Applicant: MERCK PATENT GMBH, Darmstadt (DE)

(72) Inventors: Philipp Stoessel, Frankfurt Am Main (DE); Esther Breuning, Ober-Ramstadt (DE); Joachim Kaiser, Darmstadt (DE)

(73) Assignee: Merck Patent GmbH, Darmstadt (DE)

(21) Appl. No.: 14/653,910

(22) PCT Filed: Nov. 27, 2013
(86) PCT No.: PCT/EP2013/003582

§ 371 Date: Jun. 19, 2015

(30) Foreign Application Priority Data
Dec. 21, 2012 (EP) 12008582.4

(51) Int. Cl. H01L 51/00; C09K 11/06; C07F 15/00

(52) U.S. Cl. CPC H01L 51/0085; C07F 15/0033; C09K 11/06; C09K 2211/185; C09K 2211/1044; C09K 2211/1011; C09K 2211/1029

(57) ABSTRACT

The present invention relates to metal complexes and to electronic devices, in particular organic electroluminescent devices, comprising these metal complexes.

The present invention relates to metal complexes and to electronic devices, in particular organic electroluminescent devices, comprising these metal complexes.

The structure of organic electroluminescent devices (OLEDs) in which organic semiconductors are employed as functional materials ist described, for example, in U.S. Pat. No. 4,539,507, U.S. Pat. No. 5,151,629, EP 0676461 and WO 98/27136. The emitting materials employed here are increasingly organometallic complexes which exhibit phosphorescence instead of fluorescence (M. A. Baldo et al., Appl. Phys. Lett. 1999, 75, 4-6). For quantum-mechanical reasons, an up to four-fold increase in the energy and power efficiency is possible using organometallic compounds as phosphorescence emitters. In general, however, there is still a need for improvement in OLEDs which exhibit triplet emission, in particular with respect to efficiency, operating voltage and lifetime.

In accordance with the prior art, the triplet emitters employed in phosphorescent OLEDs are, in particular, iridium complexes, such as, for example, iridium complexes which contain imidazophenanthridine derivatives or diimidazoquinazoline derivatives as ligands (WO 2007/095118). WO 2011/044988 discloses iridium complexes in which the ligand contains at least one carbonyl group. In general, further improvements, in particular with respect to efficiency, operating voltage and lifetime, are desirable in the case of phosphorescent emitters.

The object of the present invention is therefore the provision of novel metal complexes which are suitable as emitters for use in OLEDs and at the same time result in improved properties of the OLED, in particular with respect to efficiency, operating voltage and/or lifetime.

Surprisingly, it has been found that certain heteroleptic metal chelate complexes described in greater detail below achieve this object and exhibit improved properties in organic electroluminescent devices. These metal complexes emit, in particular, in the colours yellow-green, yellow, orange or red, i.e. with emission maxima in the range from about 540-650 nm. The present invention therefore relates to these metal complexes and to electronic devices, in particular organic electroluminescent devices, which comprise these complexes.

The invention thus relates to a compound of the formula (1),

[Ir(L)ₙ(L′)ₘ] formula (1)

where the compound of the general formula (1) contains a moiety Ir(L)ₙ of the formula (2):

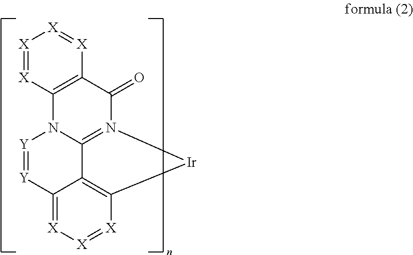

where the following applies to the symbols and indices used:
X is on each occurrence, identically or differently, CR or N, with the proviso that a maximum of two symbols X per ligand stand for N;
Y is on each occurrence, identically or differently, CR or N, with the proviso that a maximum of one symbol Y stands for N, or the two symbols Y together stand for a group of the following formula (3),

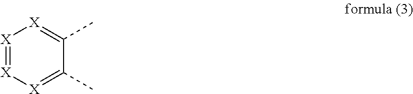

where the dashed bonds symbolise the linking of this group in the ligand;
R is on each occurrence, identically or differently, H, D, F, Cl, Br, I, N(R¹)₂, CN, Si(R¹)₃, B(OR¹)₂, C(═O)R¹, a straight-chain alkyl, alkoxy or thioalkoxy group having 1 to 40 C atoms or a straight-chain alkenyl or alkynyl group having 2 to 40 C atoms or a branched or cyclic alkyl, alkenyl, alkynyl, alkoxy or thioalkoxy group having 3 to 40 C atoms, each of which may be substituted by one or more radicals R¹, where one or more non-adjacent CH₂ groups may be replaced by R¹C═CR¹, Si(R¹)₂, C═O, NR¹, O, S or CONR¹ and where one or more H atoms may be replaced by D, F or CN, or an aromatic or heteroaromatic ring system having 5 to 60 aromatic ring atoms, which may in each case be substituted ed by one or more radicals R¹, or an aryloxy or heteroaryl-oxy group having 5 to 60 aromatic ring atoms, which may be substituted by one or more radicals R¹, or a diarylamino group, diheteroaryl-amino group or arylheteroarylamino group having 10 to 40 aromatic ring atoms, which may be substituted by one or more radicals R¹; two or more adjacent radicals R here may also form a mono- or poly-cyclic, aliphatic, aromatic and/or benzo-fused ring system with one another;
R¹ is on each occurrence, identically or differently, H, D, F, N(R²)₂, CN, Si(R²)₃, B(OR²)₂, C(═O)R², a straight-chain alkyl, alkoxy or thioalkoxy group having 1 to 40 C atoms or a straight-chain alkenyl or alkynyl group having 2 to 40 C atoms or a branched or cyclic alkyl, alkenyl, alkynyl, alkoxy or thioalkoxy group having 3 to 40 C atoms, each of which may be substituted by one or more radicals R², where one or more non-adjacent CH₂ groups may be replaced by R²C═CR², Si(R²)₂, C═O, NR², O, S or CONR² and where one or more H atoms may be replaced by D, F or CN, or an aromatic or heteroaromatic ring system having 5 to 60 aromatic ring atoms, which may in each case be substituted by one or more radicals R², or an aryloxy or heteroaryl-oxy group having 5 to 60 aromatic ring atoms, which may be substituted by one or more radicals R², or a diarylamino group, diheteroaryl-amino group or arylheteroarylamino group having 10 to 40 aromatic ring atoms, which may be substituted by one or more radicals R²; two or more adjacent radicals R¹ here may form a mono- or polycyclic, aliphatic ring system with one another;
R² is on each occurrence, identically or differently, H, D, F or an aliphatic, aromatic and/or heteroaromatic organic radical having 1 to 20 C atoms, in particular a hydrocarbon radical, in which, in addition, one or more H atoms may be replaced by D or F; two or more substituents R² here may also form a mono- or polycyclic, aliphatic or aromatic ring system with one another;
L′ is, identically or differently on each occurrence, a monoanionic bidentate ligand which is different from L and whose coordinating atoms are selected, identically or differently on each occurrence, from the group consisting of C, N, O and S;
n is 1 or 2;
m is 1 or 2;

with the proviso that n+m=3.

The complexen of the formula (1) are thus heteroleptic complexes.

In the following description, “adjacent groups X” means that the groups X are bonded directly to one another in the structure.

Furthermore, “adjacent” in the definition of the radicals means that these radicals are bonded to the same C atom or to C atoms which are bonded directly to one another or, if they are not bonded to directly bonded C atoms, they are bonded in the next-possible position in which a substituent can be bonded. This is explained again with reference to a specific ligand in the following diagrammatic representation of adjacent radicals:

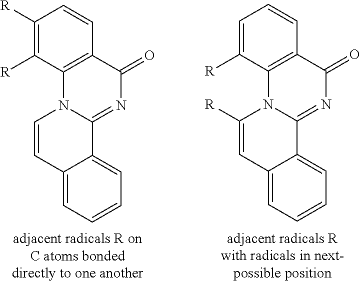

An aryl group in the sense of this invention contains 6 to 40 C atoms; a heteroaryl group in the sense of this invention contains 2 to 40 C atoms and at least one heteroatom, with the proviso that the sum of C atoms and heteroatoms is at least 5. The heteroatoms are preferably selected from N, O and/or S. An aryl group or heteroaryl group here is taken to mean either a simple aromatic ring, i.e. benzene, or a simple heteroaromatic ring, for example pyridine, pyrimidine, thiophene, etc., or a condensed aryl or heteroaryl group, for example naphthalene, anthracene, phenanthrene, quinoline, isoquinoline, etc.

An aromatic ring system in the sense of this invention contains 6 to 60 C atoms in the ring system. A heteroaromatic ring system in the sense of this invention contains 2 to 60 C atoms and at least one heteroatom in the ring system, with the proviso that the sum of C atoms and heteroatoms is at least 5. The heteroatoms are preferably selected from N, O and/or S. An aromatic or heteroaromatic ring system in the sense of this invention is intended to be taken to mean a system which does not necessarily contain only aryl or heteroaryl groups, but instead in which, in addition, a plurality of aryl or heteroaryl groups may be connected by a non-aromatic unit (preferably less than 10% of the atoms other than H), such as, for example, an sp³-hybridised C, N or O atom or a carbonyl group. Thus, for example, systems such as 9,9′-spirobifluorene, 9,9-diarylfluorene, triarylamine, diaryl ether, stilbene, etc., are also intended to be taken to be aromatic ring systems in the sense of this invention, as are systems in which two or more aryl groups are interrupted, for example, by a linear or cyclic alkylene group or by a silylene group.

A cyclic alkyl, alkoxy or thioalkoxy group in the sense of this invention is taken to mean a monocyclic, bicyclic or polycyclic group.

For the purposes of the present invention, a C₁- to C₄₀-alkyl group, in which, in addition, individual H atoms or CH₂ groups may be substituted by the above-mentioned groups, is taken to mean, for example, the radicals methyl, ethyl, n-propyl, i-propyl, n-butyl, i-butyl, s-butyl, t-butyl, 2-methyl-butyl, n-pentyl, s-pentyl, tert-pentyl, 2-pentyl, neopentyl, cyclopentyl, n-hexyl, s-hexyl, tert-hexyl, 2-hexyl, 3-hexyl, cyclohexyl, 2-methylpentyl, neohexyl, n-heptyl, 2-heptyl, 3-heptyl, 4-heptyl, cycloheptyl, 1-methylcyclo-hexyl, n-octyl, 2-ethylhexyl, cyclooctyl, 1-bicyclo[2.2.2]octyl, 2-bicyclo-[2.2.2]octyl, 2-(2,6-dimethyl)octyl, 3-(3,7-dimethyl)octyl, trifluoromethyl, pentafluoroethyl or 2,2,2-trifluoroethyl. An alkenyl group is taken to mean, for example, ethenyl, propenyl, butenyl, pentenyl, cyclopentenyl, hexenyl, cyclohexenyl, heptenyl, cycloheptenyl, octenyl, cyclooctenyl or cyclooctadienyl. An alkynyl group is taken to mean, for example, ethynyl, propynyl, butynyl, pentynyl, hexynyl, heptynyl or octynyl. A C₁- to C₄₀-alkoxy group is taken to mean, for example, methoxy, trifluoromethoxy, ethoxy, n-propoxy, i-propoxy, n-butoxy, i-butoxy, s-butoxy, t-butoxy or 2-methylbutoxy. An aromatic or heteroaromatic ring system having 5-60 aromatic ring atoms, which may also in each case be substituted by the above-mentioned radicals R and which may be linked to the aromatic or heteroaromatic ring system via any desired positions, is taken to mean, for example, groups derived from benzene, naphthalene, anthracene, benzanthracene, phenanthrene, benzophenanthrene, pyrene, chrysene, perylene, fluoranthene, benzofluoranthene, naphthacene, pentacene, benzopyrene, biphenyl, biphenylene, terphenyl, terphenylene, fluorene, spirobifluorene, dihydrophenanthrene, dihydropyrene, tetrahydropyrene, cis- or trans-indenofluorene, cis- or trans-monobenzoindenofluorene, cis- or trans-dibenzoindenofluorene, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, indolocarbazole, indenocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubin, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

The complexes according to the invention can be facial or pseudofacial, or they can be meridional or pseudomeridional.

In a preferred embodiment, the index n=1, i.e. the complex according to the invention contains one ligand L and two ligands L′. This is preferred, in particular, if the ligand L′ is an ortho-metallated ligand which is coordinated to the iridium via one carbon atom and one nitrogen atom.

In a further preferred embodiment, the index n=2, i.e. the complex according to the invention contains two ligands L and one ligand L′. This is not only a preferred embodiment if the ligand L′ is coordinated to the iridium via one carbon atom and one nitrogen atom, but is also preferred if the ligand L′ is a ligand which is coordinated to the iridium via two oxygen atoms, two nitrogen atoms or one oxygen atom and one nitrogen atom.

In a further preferred embodiment of the invention, a total of 0, 1 or 2 of the symbols X and Y in the ligand L stand for N. Particularly preferably, a total of 0 or 1 of the symbols X and Y in the ligand L stand for N. Very particularly preferably, none of the symbols X and Y stand for N, i.e. the symbols X stand, identically or differently on each occurrence, for CR and the symbols Y stand, identically or differently on each occurrence, for CR or the symbols Y together stand for a group of the formula (3). In a preferred embodiment of the invention, the symbols X in the ring which is coordinated to the iridium via the carbon atom stand, identically or differently on each occurrence, for CR. Especially preferably, all symbols X and Y stand, identically or differently on each occurrence, for CR.

Preferred embodiments of the formula (2) are the structures of the following formulae (4) to (12),

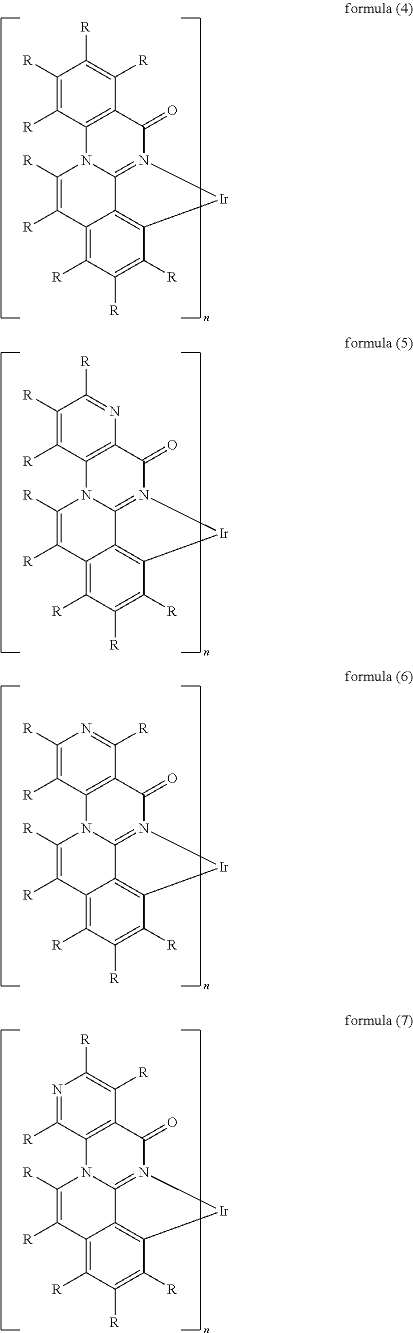

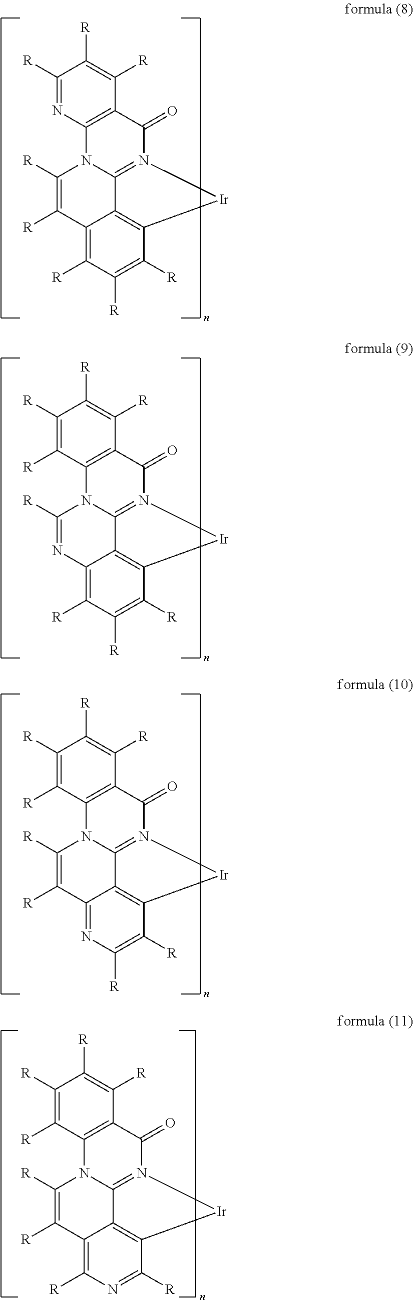

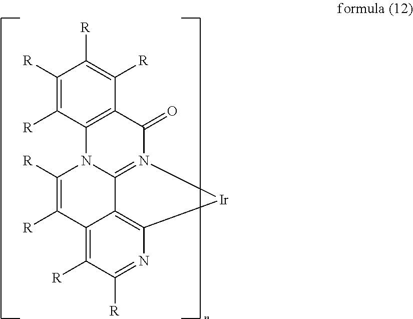

where the symbols and indices used have the meanings given above.

Preferred moieties MLₙ in which the two symbols Y together stand for a group of the formula (3) are the structures of the following formulae (13) to (24),

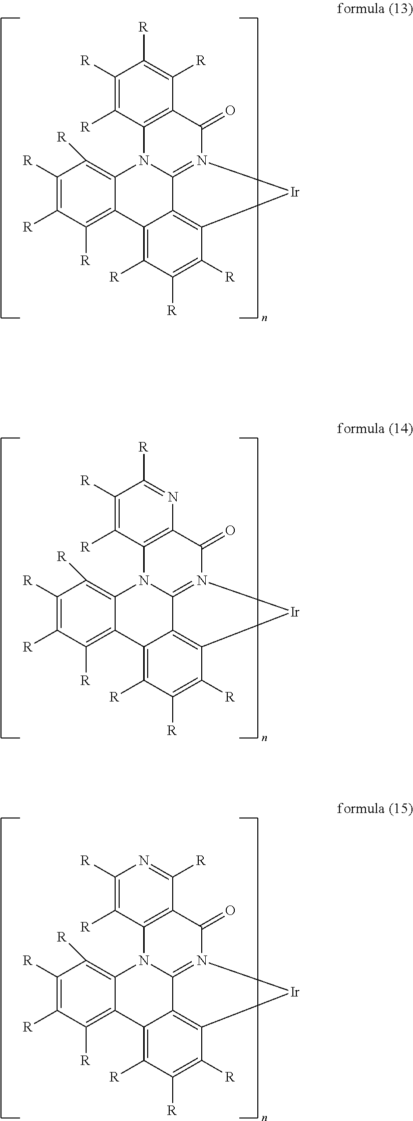

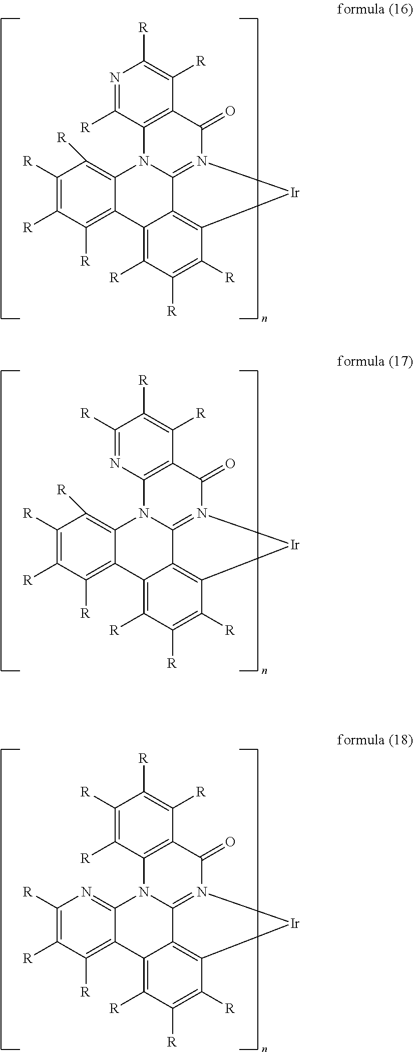

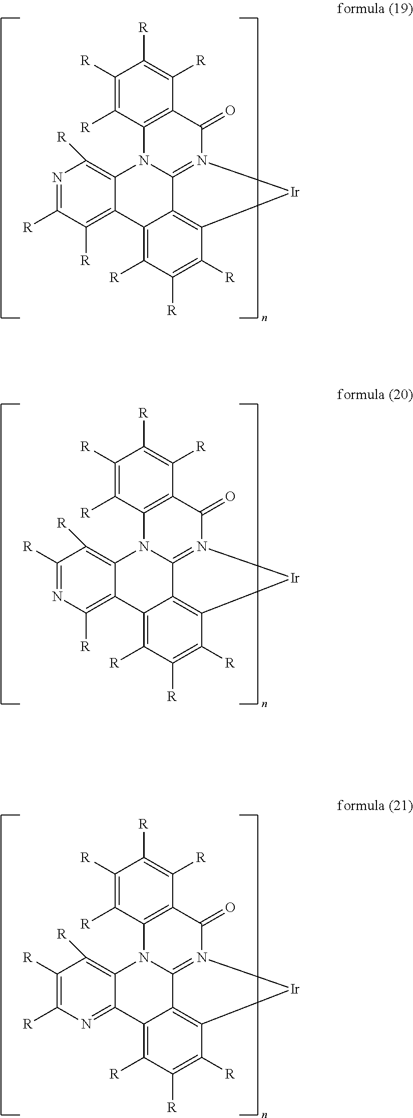

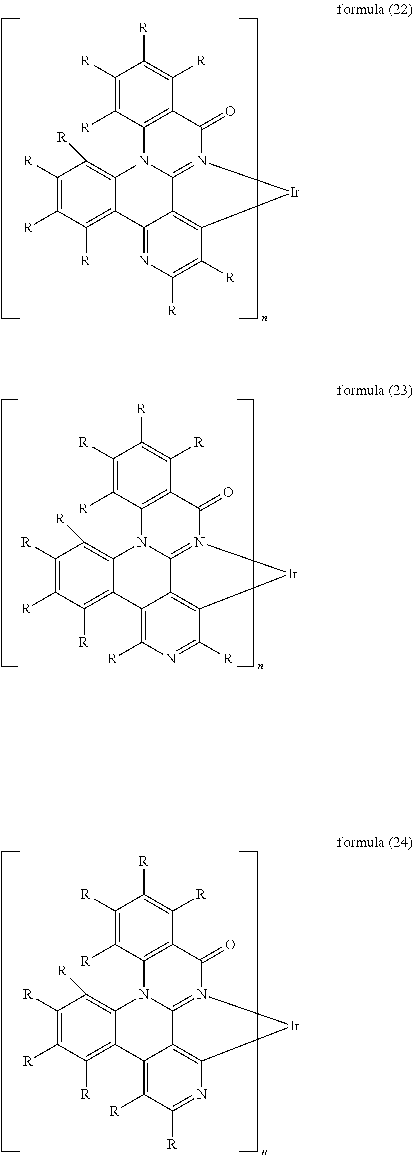

where the symbols and indices used have the meanings given above.

In the above-mentioned structures, the radical R which is bonded to the iridium in the ortho-position to the coordination is preferably selected from the group consisting of H, D, F and methyl.

Larger condensed ligands L may also arise through ring formation of the substituents R. This is shown by way of example for the structures of the following formulae (4a) to (4e), where ring formation is likewise possible on the other ligands mentioned above,

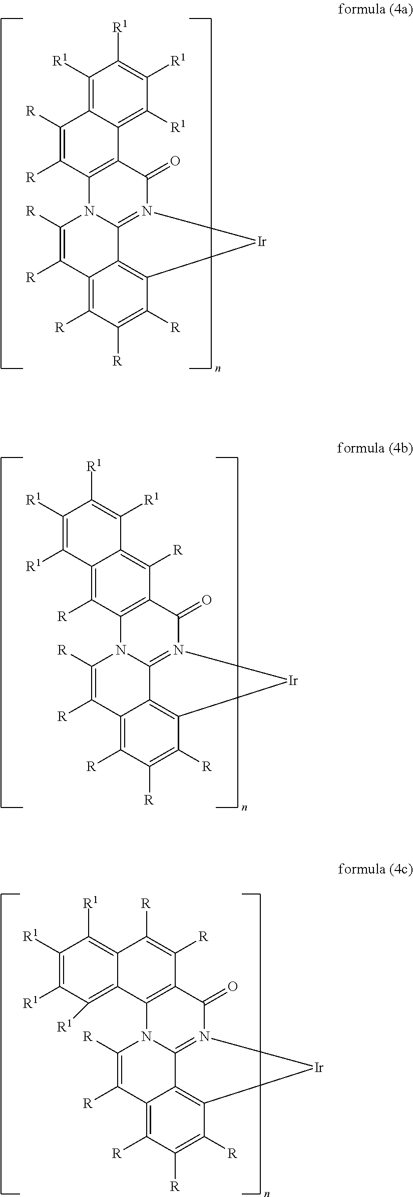

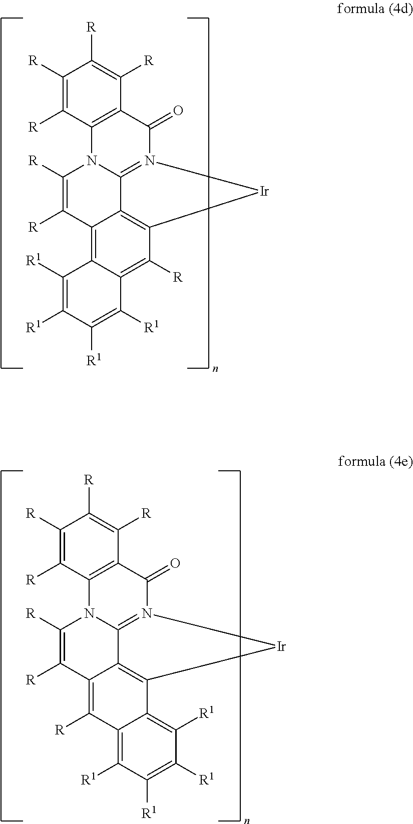

where the symbols and indices used have the meanings given above.

If one or more groups X or Y in the moieties of the formula (2) stand for N, i.e. in the case of moieties of the formulae (5) to (12) or (14) to (24), it is preferred for a group R which is not equal to hydrogen or deuterium to be bonded as substituent adjacent to this nitrogen atom. This R is preferably a group selected from CF₃, OCF₃, alkyl or alkoxy groups having 1 to 10 C atoms, in particular branched or cyclic alkyl or alkoxy groups having 3 to 10 C atoms, a dialkylamino group having 2 to 10 C atoms, aromatic or heteroaromatic ring systems or aralkyl or heteroaralkyl groups. These groups are bulky groups. Furthermore, this radical R can preferably also form a ring with an adjacent radical R. These are then preferably structures of the formulae (25) or (26), as described in greater detail below.

If the radical R which is adjacent to a nitrogen atom stands for an alkyl group, this alkyl group then preferably has 3 to 10 C atoms. It is furthermore preferably a secondary or tertiary alkyl group in which the secondary or tertiary C atom is either bonded directly to the ligand or is bonded to the ligand via a CH₂ group. This alkyl group is particularly preferably selected from the structures of the following formulae (R-1) to (R-33), where in each case the linking of these groups to the ligand is also drawn in:

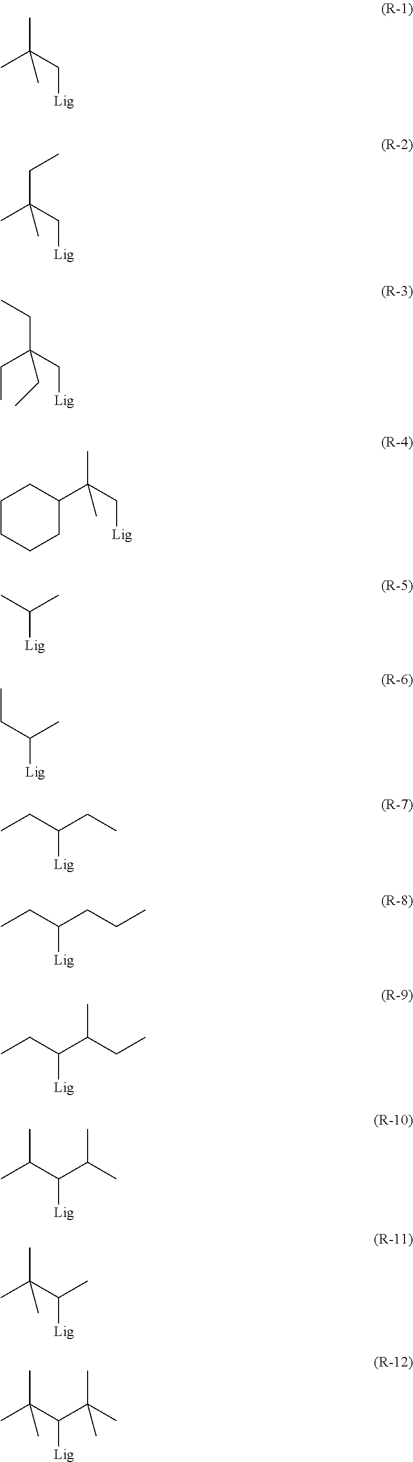

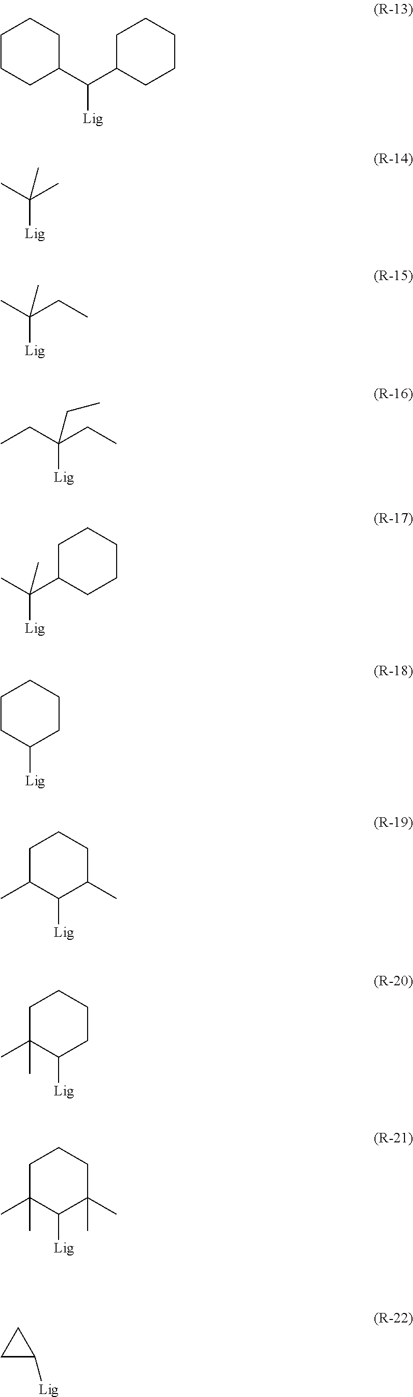

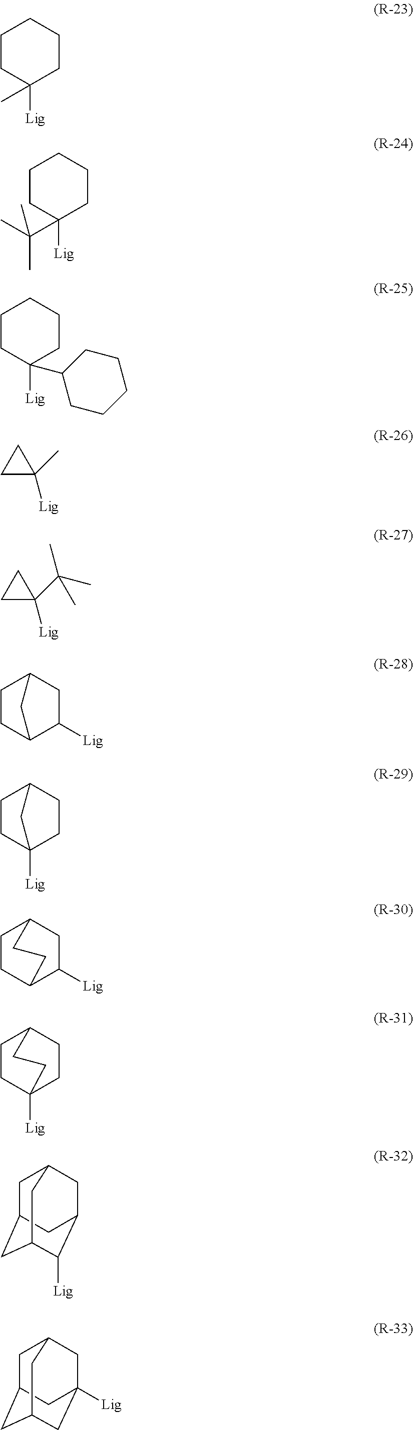

where Lig denotes the linking of the alkyl group to the ligand.

If the radical R which is adjacent to a nitrogen atom stands for an alkoxy group, this alkoxy group then preferably has 3 to 10 C atoms. This alkoxy group is preferably selected from the structures of the following formulae (R-34) to (R-47), where in each case the linking of these groups to the ligand is also drawn in:

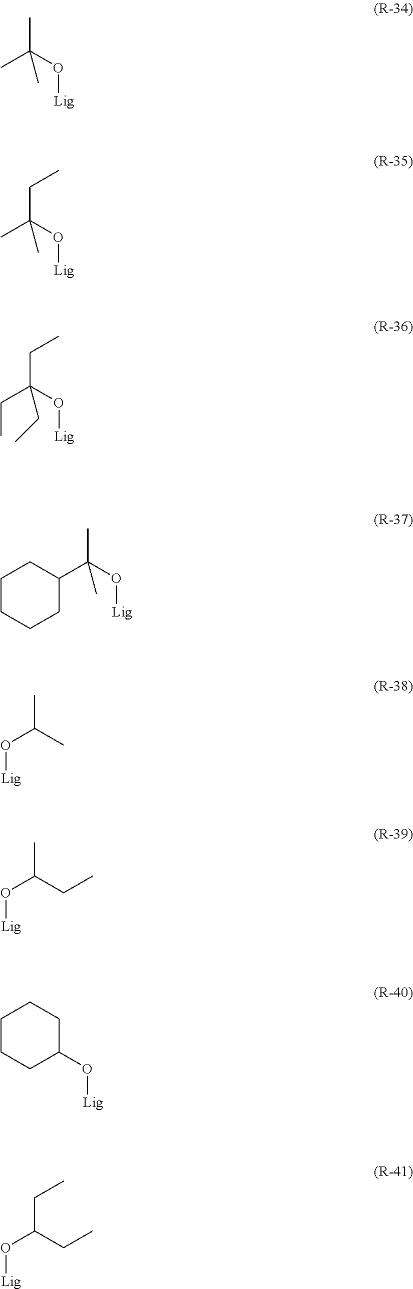

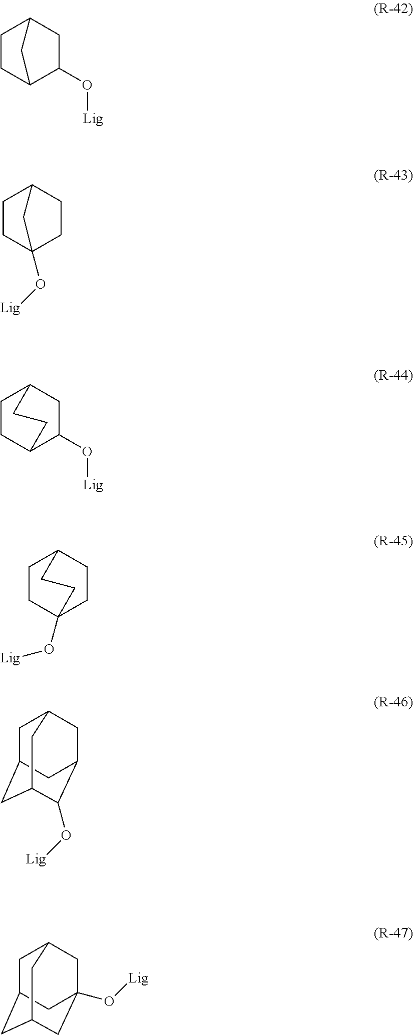

where Lig denotes the linking of the alkoxy group to the ligand.

If the radical R which is adjacent to a nitrogen atom stands for a dialkylamino group, each of these alkyl groups then preferably has 1 to 8 C atoms, particularly preferably 1 to 6 C atoms. Examples of suitable alkyl groups are methyl, ethyl or the structures shown above as groups (R-1) to (R-33). The dialkylamino group is particularly preferably selected from the structures of the following formulae (R-48) to (R-55), where in each case the linking of these groups to the ligand is also drawn in:

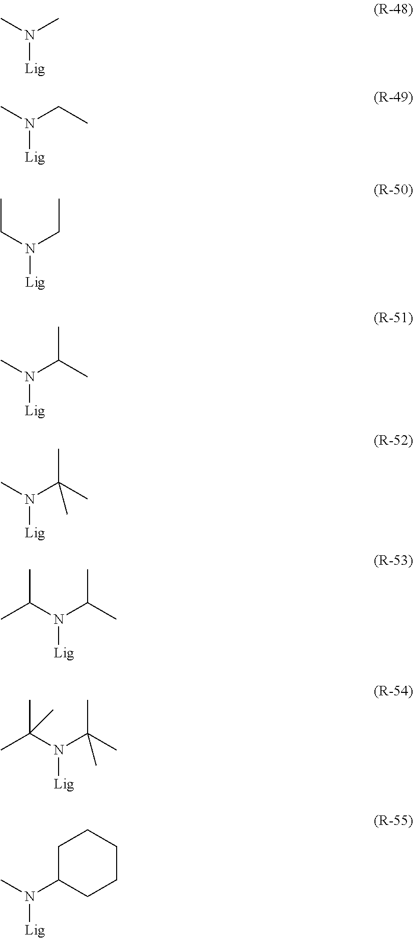

where Lig denotes the linking of the dialkylamino group to the ligand.

If the radical R which is adjacent to a nitrogen atom stands for an aralkyl group, this aralkyl group is then preferably selected from the structures of the following formulae (R-56) to (R-69), where in each case the linking of these groups to the ligand is also drawn in:

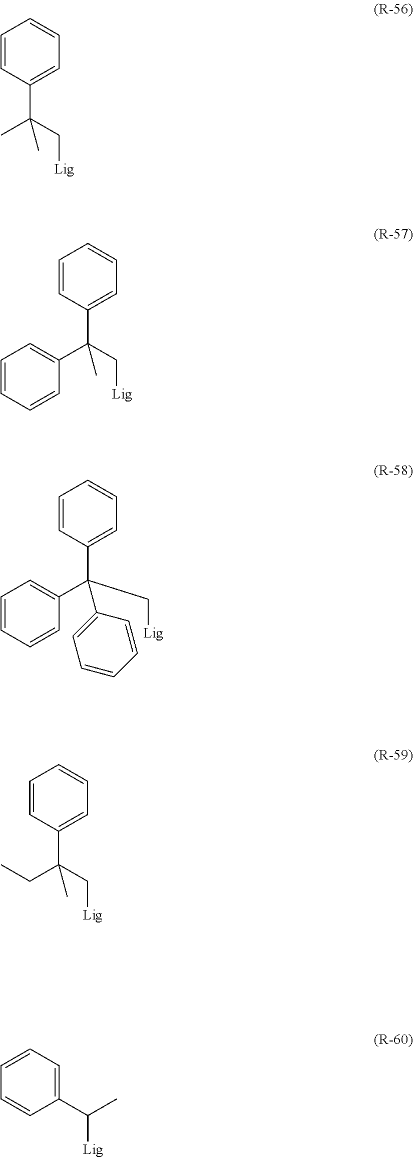

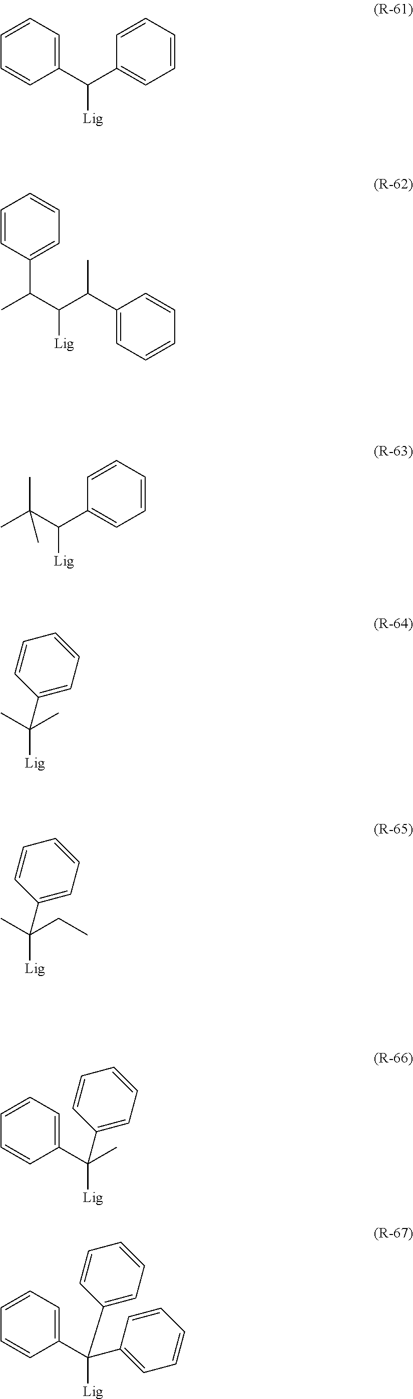

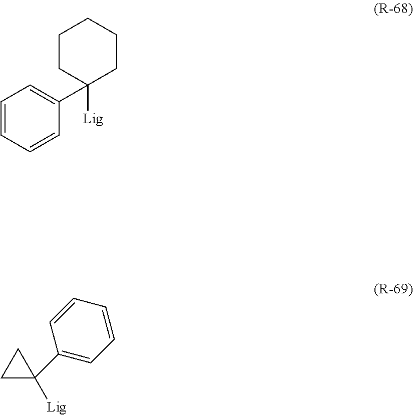

where Lig denotes the linking of the aralkyl group to the ligand, and the phenyl groups may in each case be substituted by one or more radicals R¹.

If the radical R which is adjacent to a nitrogen atom stands for an aromatic or heteroaromatic ring system, this aromatic or heteroaromatic ring system then preferably has 5 to 30 aromatic ring atoms, particularly preferably 5 to 24 aromatic ring atoms. This aromatic or heteroaromatic ring system furthermore preferably contains no aryl or heteroaryl groups in which more than two aromatic six-membered rings are condensed directly onto one another. The aromatic or heteroaromatic ring system particularly preferably contains no condensed aryl or heteroaryl groups at all, and it very particularly preferably contains only phenyl groups. The aromatic ring system here is preferably selected from the structures of the following formulae (R-70) to (R-88), where in each case the linking of these groups to the ligand is also drawn in:

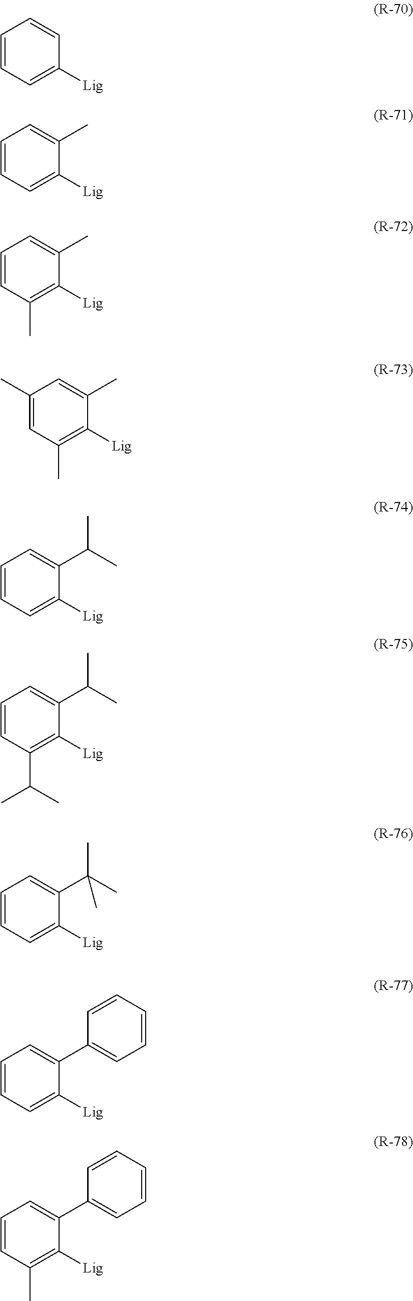

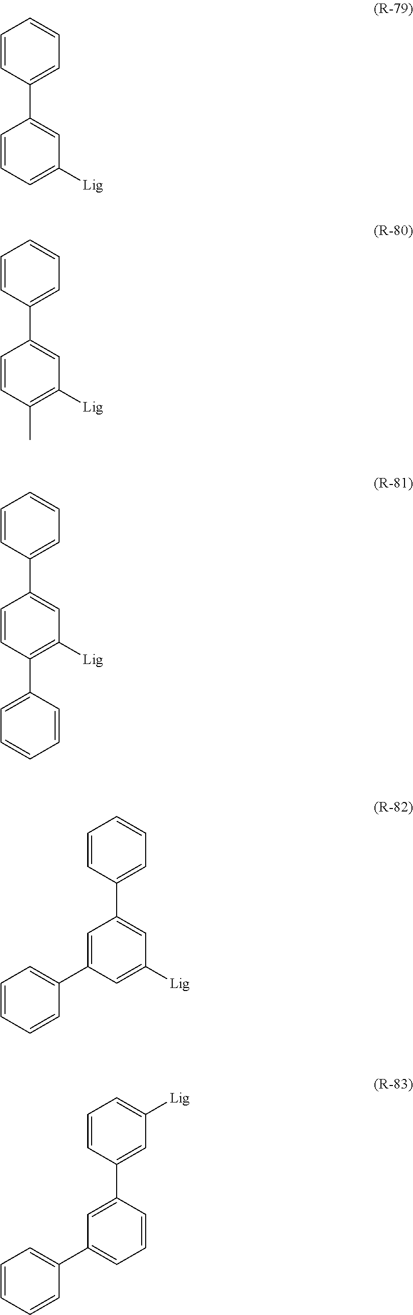

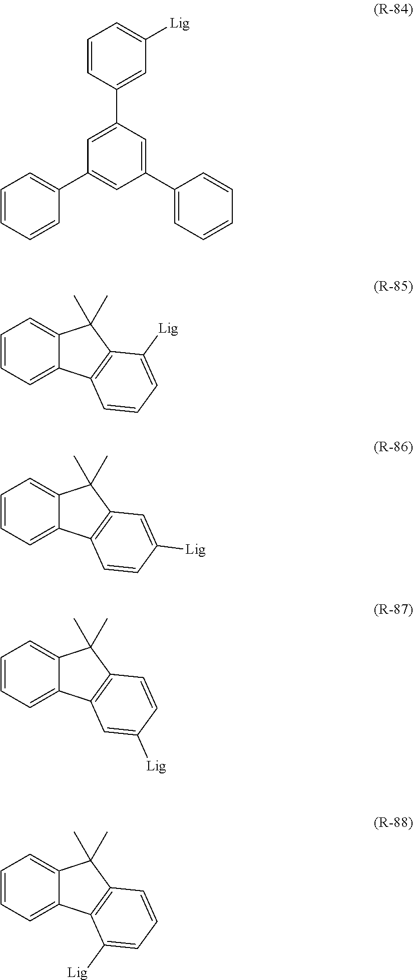

where Lig denotes the linking of the aromatic ring system to the ligand, and the phenyl groups may in each case be substituted by one or more radicals R¹.

Furthermore, the heteroaromatic ring system is preferably selected from the structures of the following formulae (R-89) to (R-119), where in each case the linking of these groups to the ligand is also drawn in:

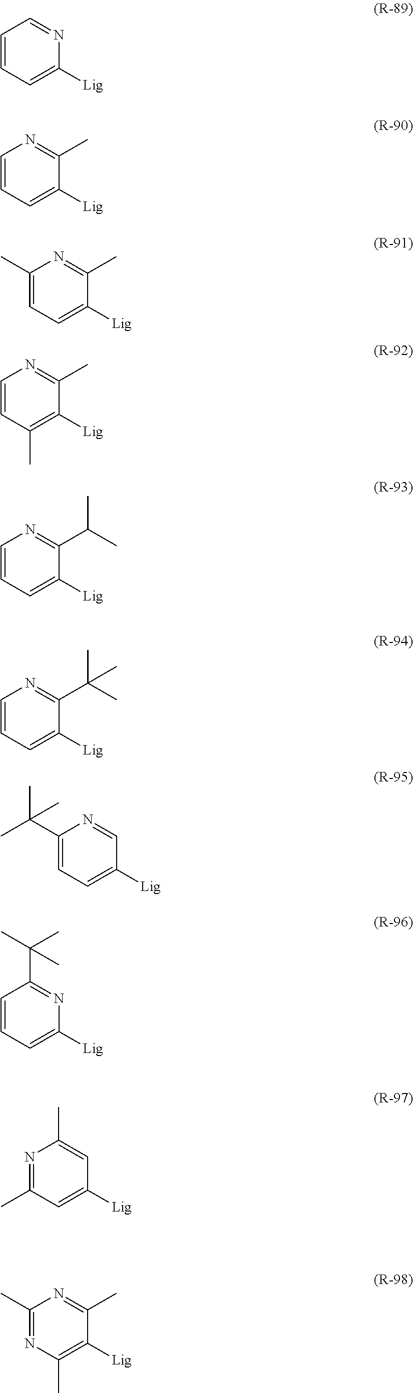

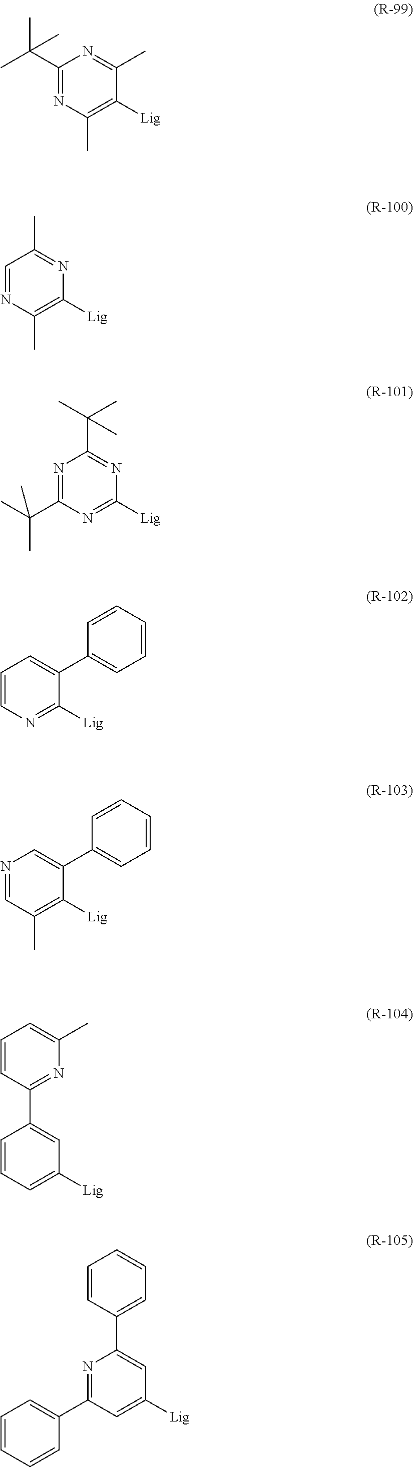

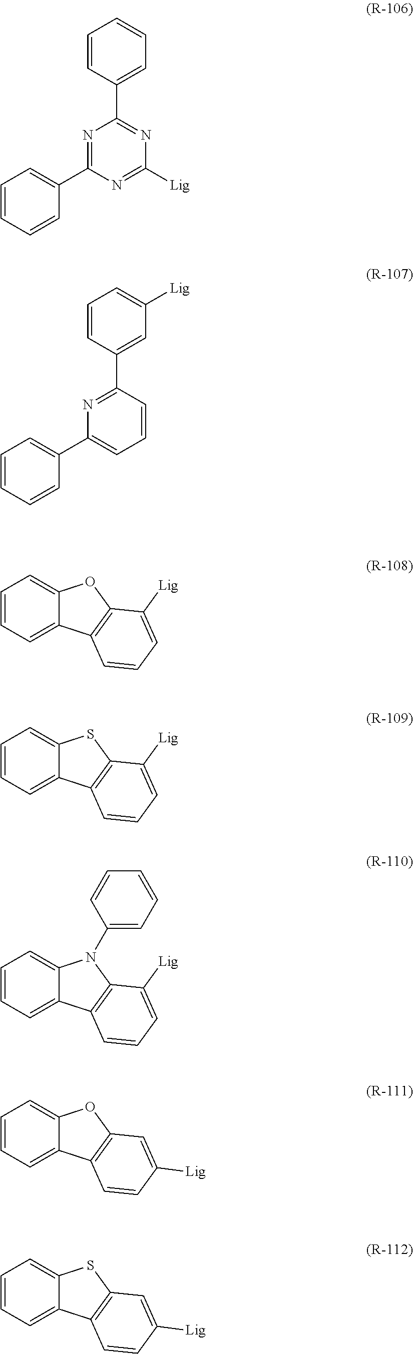

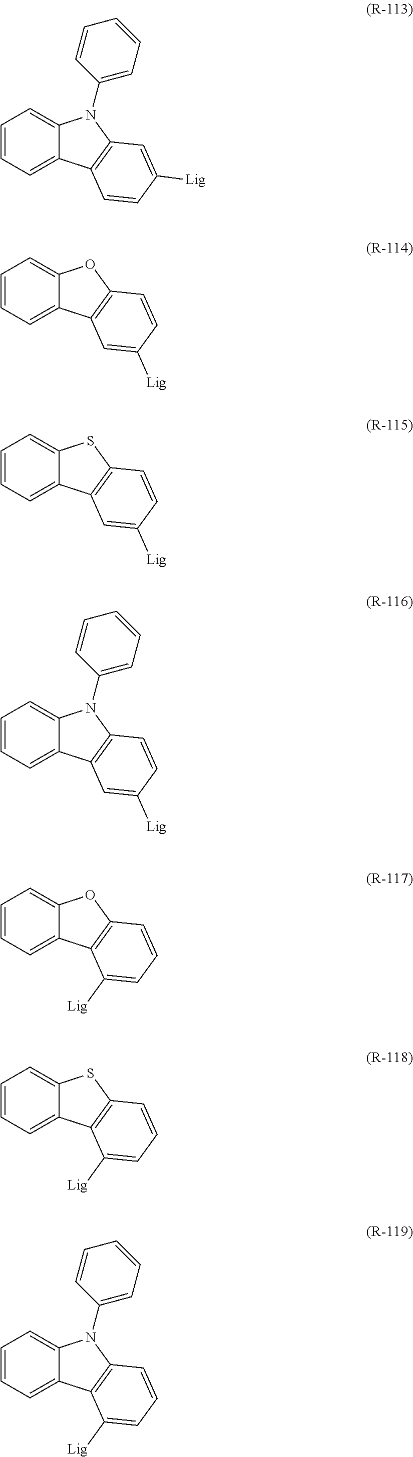

where Lig denotes the linking of the heteroaromatic ring system to the ligand, and the aromatic and heteroaromatic groups may in each case be substituted by one or more radicals R¹.

In a preferred embodiment of the invention, adjacent radicals R and/or R¹ do not form a ring with one another.

In another preferred embodiment, two adjacent groups X in the moiety of the formula (2) stand for CR and/or two adjacent radicals Y stand for CR and the respective radicals R, together with the C atoms, form a ring of one of the following formulae (25) to (31); it is likewise preferred for two radicals R which are bonded to C atoms which are bonded directly to one another in the moieties of the formulae (4) to (24), together with the C atoms to which they are bonded, to form a ring with one another, so that one of the structures of one of the following formulae (25) to (31) arises:

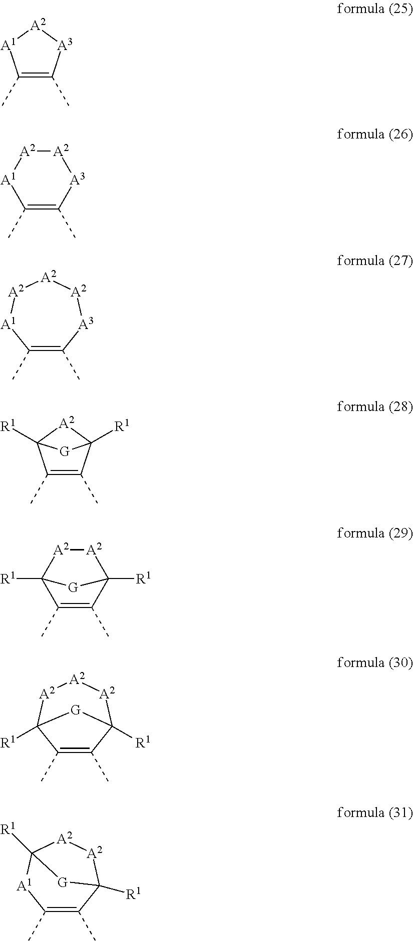

where R¹ and R² have the meanings given above, where a plurality of R¹ may also be linked to one another and thus may form a further ring system, the dashed bonds indicate the linking of the two carbon atoms in the ligand, and furthermore:
A¹, A³ are, identically or differently on each occurrence, C(R³)₂, O, S, NR³ or C(═O);
A² is, identically or differently on each occurrence, C(R¹)₂, O, S, NR³ or C(═O); or A²-A² in formula (26), (27), (28), (29), (30) or (31) may, apart from a combination of the above-mentioned groups, stand for —CR²═CR²— or an ortho-linked arylene or heteroarylene group having 5 to 14 aromatic ring atoms, which may be substituted by one or more radicals R²;
G is an alkylene group having 1, 2 or 3 C atoms, which may be substituted by one or more radicals R², —CR²═CR²— or an ortho-linked arylene or heteroarylene group having 5 to 14 aromatic ring atoms, which may be substituted by one or more radicals R²;
R³ is, identically or differently on each occurrence, F, a straight-chain alkyl or alkoxy group having 1 to 10 C atoms, a branched or cyclic alkyl or alkoxy group having 3 to 10 C atoms, each of which may be substituted by one or more radicals R², where one or more non-adjacent CH₂ groups may be replaced by R²C═CR², C≡C, Si(R²)₂, C═O, NR², O, S or CONR² and where one or more H atoms may be replaced by D or F, or an aromatic or heteroaromatic ring system having 5 to 24 aromatic ring atoms, which may in each case be substituted by one or more radicals R², or an aryloxy or heteroaryloxy group having 5 to 24 aromatic ring atoms, which may be substituted by one or more radicals R², or an aralkyl or heteroaralkyl group having 5 to 24 aromatic ring atoms, which may be substituted by one or more radicals R²; two radicals R³ here which are bonded to the same carbon atom may form an aliphatic or aromatic ring system with one another and thus form a Spiro system; furthermore, R³ may form an aliphatic ring system with an adjacent radical R or R¹;

with the proviso that two heteroatoms in these groups are not bonded directly to one another and two groups C═O are not bonded directly to one another.

The groups of the formulae (25) to (31) may be present in any position of the moiety of the formula (2) in which two groups X or two groups Y are bonded directly to one another. Preferred positions in which a group of the formulae (25) to (31) is present are the moieties of the following formulae (2a), (2b) and (2c),

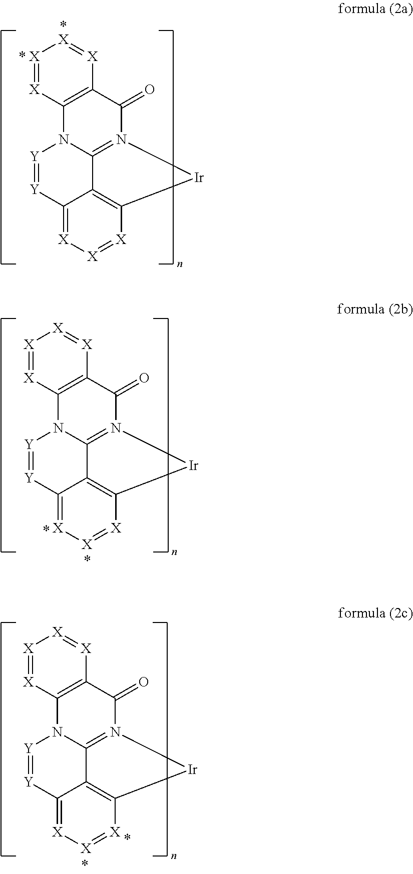

where the symbols and indices used have the meanings given above, and *in each case indicates the position at which the two adjacent groups X stand for CR and the respective radicals R, together with the C atoms, form a ring of one of the formulae (25) to (31).

In the structures of the formulae (25) to (31) depicted above and the further embodiments of these structures mentioned as preferred, a double bond is formally shown between the two carbon atoms. This represents a simplification of the chemical structure since these two carbon atoms are bonded into an aromatic or heteroaromatic system and the bond between these two carbon atoms is thus formally between the bond order of a single bond and that of a double bond. The drawing-in of the formal double bond should thus not be interpreted as limiting for the structure, but instead it is apparent to the person skilled in the art that this is an aromatic bond.

It is essential in the groups of the formulae (25) to (31) that these do not contain any acidic benzylic protons. Benzylic protons are taken to mean protons which are bonded to a carbon atom which is bonded directly to the ligand. The absence of acidic benzylic protons is achieved in the formulae (25) to (27) through A¹ and A³, if they stand for C(R³)₂, being defined in such a way that R³ is not equal to hydrogen. The absence of acidic benzylic protons is achieved in formulae (28) to (31) through it being a bicyclic structure. Owing to the rigid spatial arrangement, R¹, if it stands for H, is significantly less acidic than benzylic protons, since the corresponding anion of the bicyclic structure is not mesomerism-stabilised. Even if R¹ in formulae (28) to (31) stands for H, this is therefore a non-acidic proton in the sense of the present application.

In a preferred embodiment of the structure of the formulae (25) to (31), a maximum of one of the groups A¹, A² and A³ stands for a heteroatom, in particular for O or NR³, and the other groups stand for C(R³)₂ or C(R¹)_{2,} or A¹ and A³ stand, identically or differently on each occurrence, for O or NR³ and A² stands for C(R¹)₂. In a particularly preferred embodiment of the invention, A¹ and A³ stand, identically or differently on each occurrence, for C(R³)₂ and A² stands for C(R¹)₂ and particularly preferably for C(R³)₂. Preferred embodiments of the formula (25) are thus the structures of the formulae (25-A), (25-B), (25-C) and (25-D), and particularly preferred embodiment of the formula (25-A) are the structures of the formulae (25-E) and (25-F),

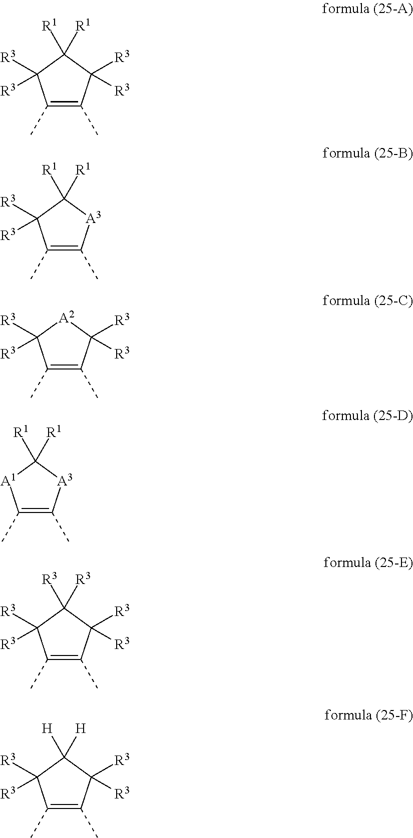

where R¹ and R³ have the meanings given above, and A¹, A² and A³ stand, identically or differently on each occurrence, for O or NR³.

Preferred embodiments of the formula (26) are the structures of the following formulae (26-A) to (26-F),

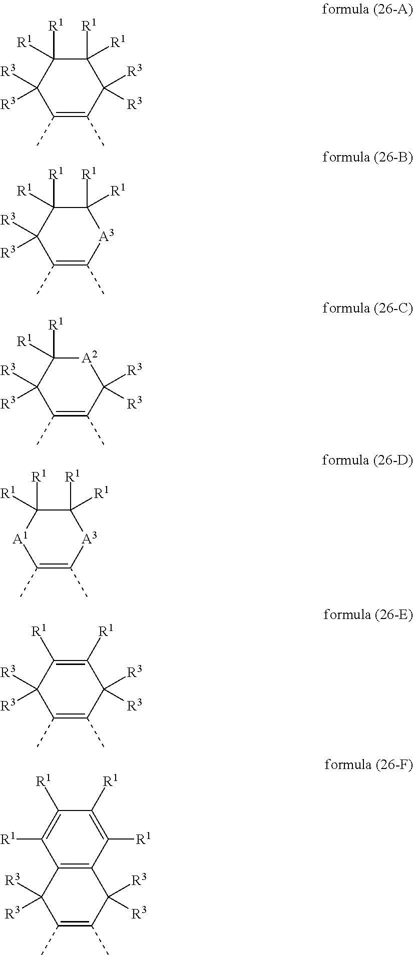

where R¹ and R³ have the meanings given above, and A¹, A² and A³ stand, identically or differently on each occurrence, for O or NR³.

Preferred embodiments of the formula (27) are the structures of the following formulae (27-A) to (27-E),

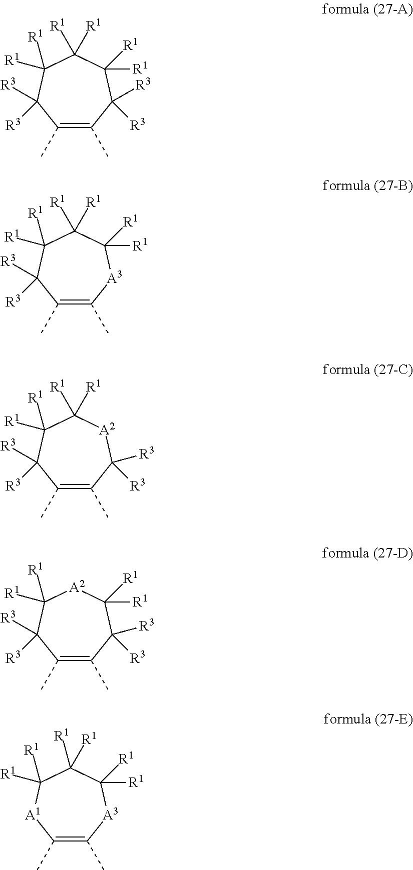

where R¹ and R³ have the meanings given above, and A¹, A² and A³ stand, identically or differently on each occurrence, for O or NR³.

In a preferred embodiment of the structure of the formula (28), the radicals R¹ which are bonded to the bridgehead stand for H, D, F or CH₃. A² furthermore preferably stands for C(R¹)₂ or O, and particularly preferably for C(R³)₂. Preferred embodiments of the formula (28) are thus the structures of the formulae (28-A) and (28-B), and a particularly preferred embodiment of the formula (28-A) is a structure of the formula (28-C),

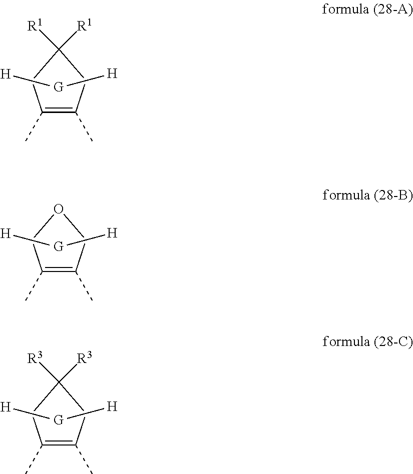

where the symbols used have the meanings given above.

In a preferred embodiment of the structure of the formulae (29), (30) and (31), the radicals R¹ which are bonded to the bridgehead stand for H, D, F or CH₃, particularly preferably for H. A² furthermore preferably stands for C(R¹)₂. Preferred embodiments of the formulae (29), (30) and (31) are thus the structures of the formulae (29-A), (30-A) and (31-A),

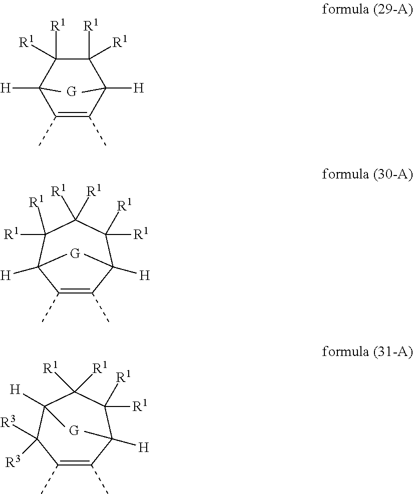

where the symbols used have the meanings given above.

The group G in the formulae (28), (28-A), (28-B), (28-C), (29), (29-A), (30), (30-A), (31) and (31-A) furthermore preferably stands for a 1,2-ethylene group, which may be substituted by one or more radicals R², where R² preferably stands, identically or differently on each occurrence, for H or an alkyl group having 1 to 4 C atoms, or an ortho-arylene group having 6 to 10 C atoms, which may be substituted by one or more radicals R², but is preferably unsubstituted, in particular an ortho-phenylene group, which may be substituted by one or more radicals R², but is preferably unsubstituted.

In a further preferred embodiment of the invention, R³ in the groups of the formulae (25) to (31) and in the preferred embodiments stands, identically or differently on each occurrence, for F, a straight-chain alkyl group having 1 to 10 C atoms or a branched or cyclic alkyl group having 3 to 20 C atoms, where in each case one or more non-adjacent CH₂ groups may be replaced by R²C═CR² and one or more H atoms may be replaced by D or F, or an aromatic or heteroaromatic ring system having 5 to 14 aromatic ring atoms, which may in each case be substituted by one or more radicals R²; two radicals R³ here which are bonded to the same carbon atom may form an aliphatic or aromatic ring system with one another and thus form a spiro system; furthermore, R³ may form an aliphatic ring system with an adjacent radical R or R¹.

In a particularly preferred embodiment of the invention, R³ in the groups of the formulae (25) to (31) and in the preferred embodiments stands, identically or differently on each occurrence, for F, a straight-chain alkyl group having 1 to 3 C atoms, in particular methyl, or an aromatic or heteroaromatic ring system having 5 to 12 aromatic ring atoms, each of which may be substituted by one or more radicals R², but is preferably unsubstituted; two radicals R³ here which are bonded to the same carbon atom may form an aliphatic or aromatic ring system with one another and thus form a Spiro system; furthermore, R³ may form an aliphatic ring system with an adjacent radical R or R¹.

Examples of particularly suitable groups of the formula (25) are the groups shown below:

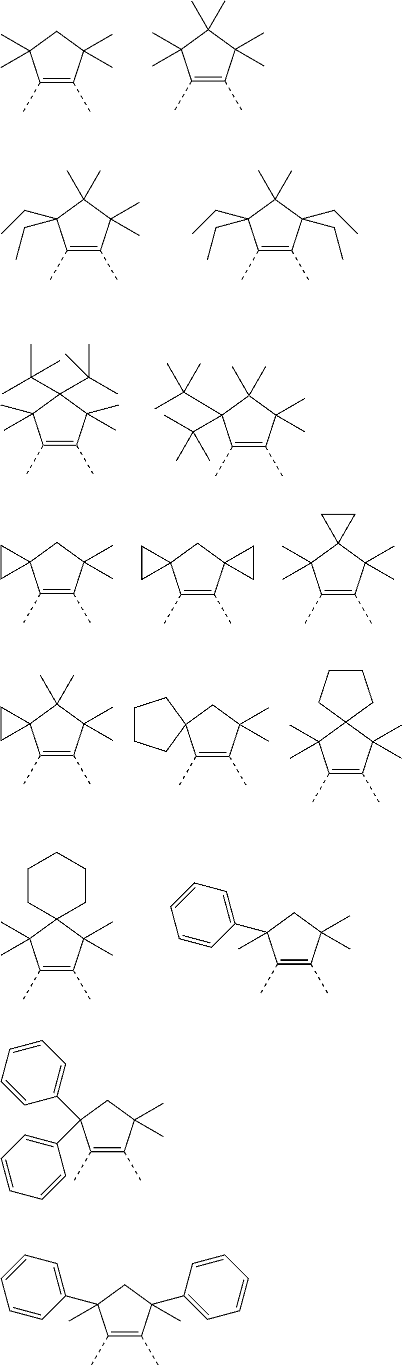

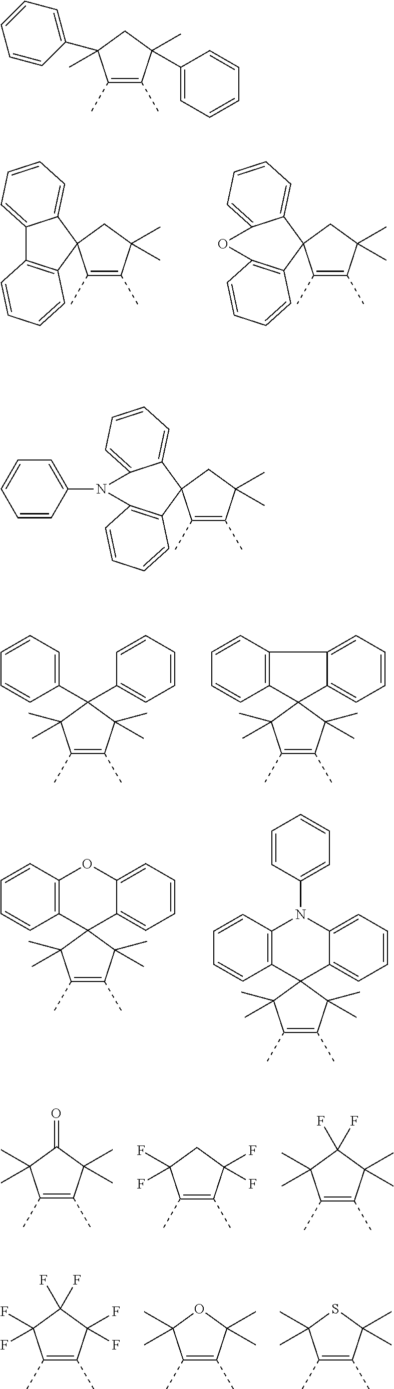

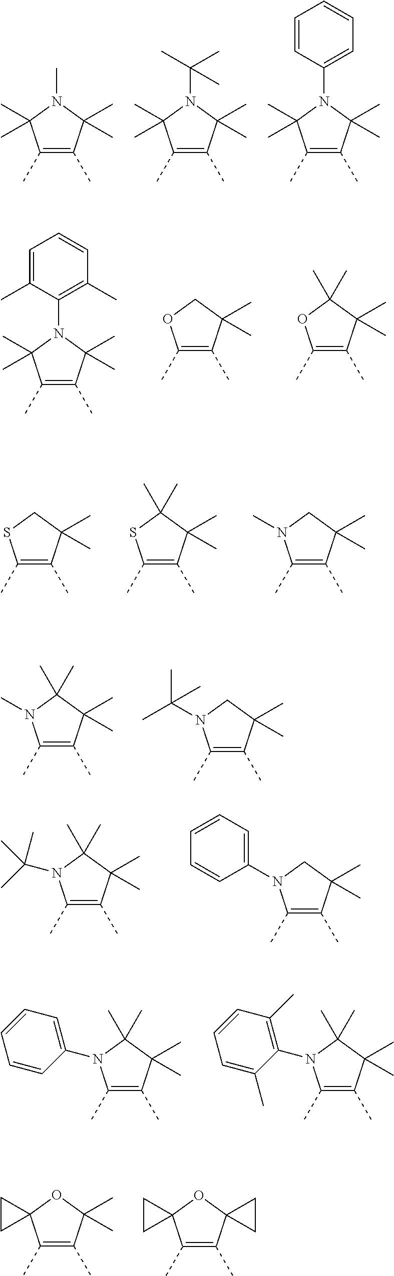

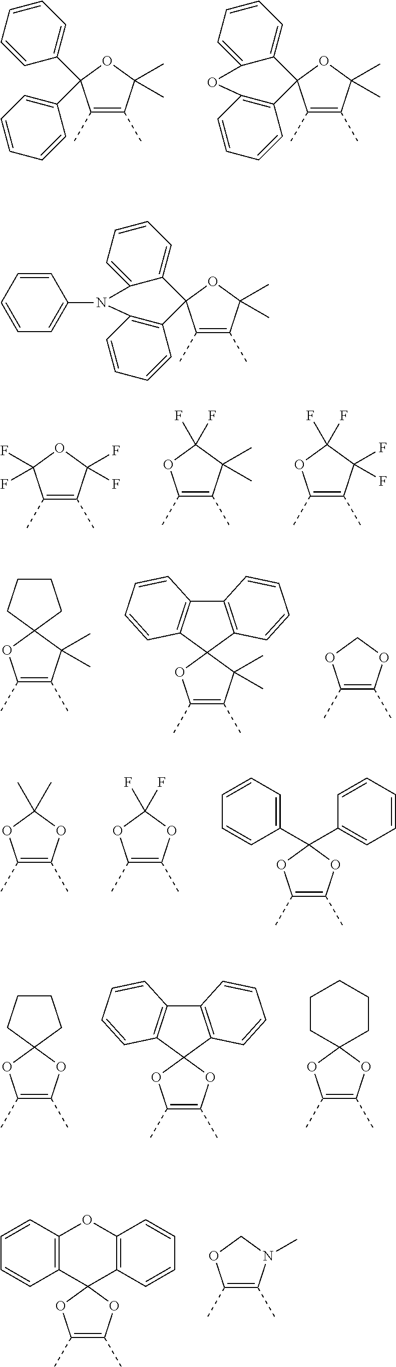

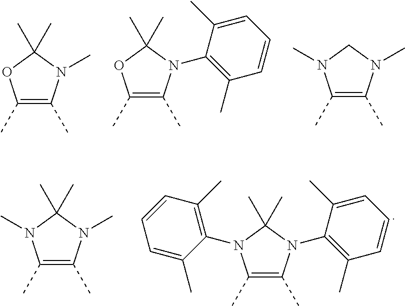

Examples of particularly suitable groups of the formula (26) are the groups shown below:

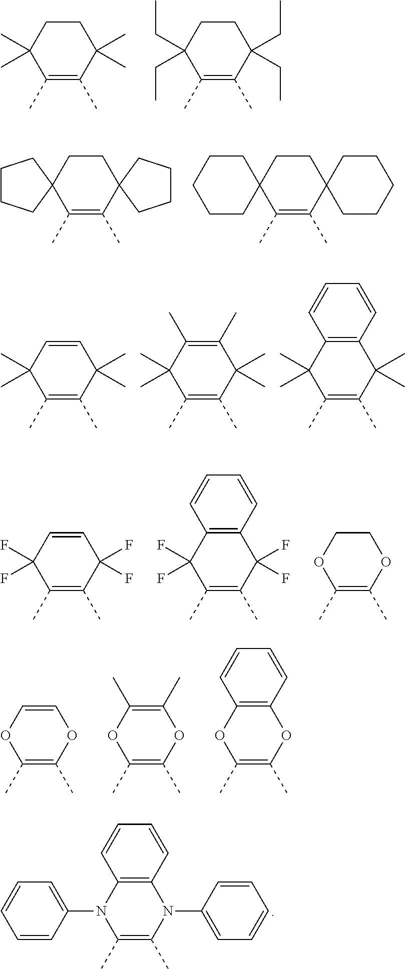

Examples of particularly suitable groups of the formulae (26), (30) and (31) are the groups shown below:

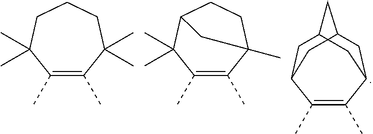

Examples of particularly suitable groups of the formula (28) are the groups shown below:

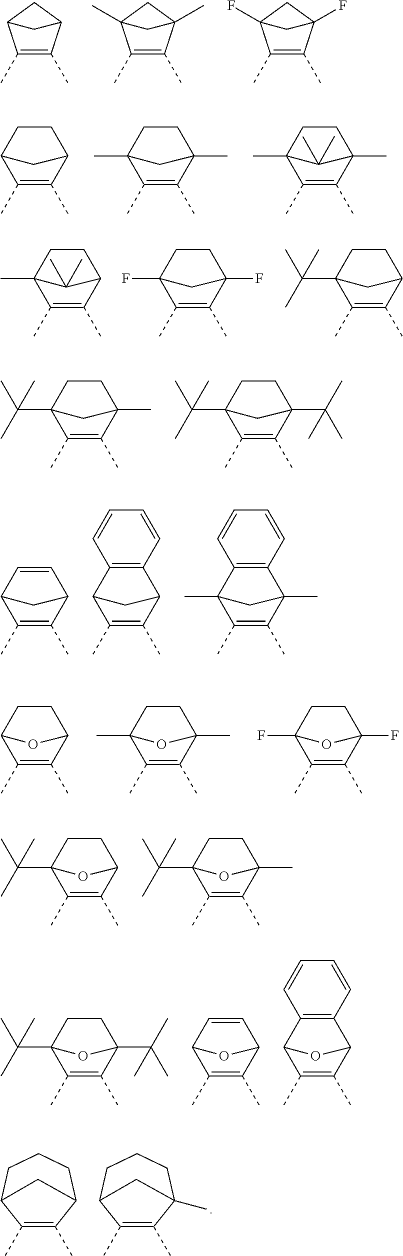

Examples of particularly suitable groups of the formula (29) are the groups shown below:

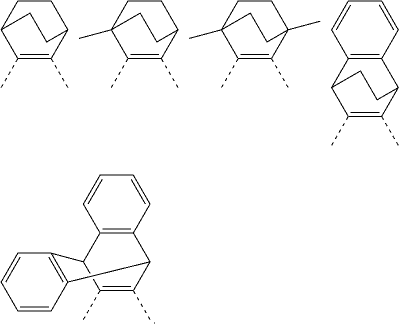

In particular, the use of condensed-on bicyclic structures of this type may also result in chiral ligands L owing to the chirality of the structures. Both the use of enantiomerically pure ligands and also the use of the racemate may be suitable here. It may also be suitable, in particular, to use not only one enantiomer of a ligand in the metal complex according to the invention, but intentionally both enantiomers, so that, for example, a complex (+L)₂(−L)M or a complex (+L)(−L)₂M forms, where +L or −L in each case denotes the corresponding + or − enantiomer of the ligand. This may have advantages with respect to the solubility of the corresponding complex compared with complexes which contain only +L or only −L as ligand.

If further or other radicals R are bonded in the moiety of the formula (2), these radicals R are preferably selected on each occurrence, identically or differently, from the group consisting of H, D, F, N(R¹)₂, CN, Si(R¹)₃, C(═O)R¹, a straight-chain alkyl group having 1 to 10 C atoms or an alkenyl group having 2 to 10 C atoms or a branched or cyclic alkyl group having 3 to 10 C atoms, each of which may be substituted by one or more radicals R¹, where one or more H atoms may be replaced by D or F, or an aromatic or heteroaromatic ring system having 5 to 24 aromatic ring atoms, which may in each case be substituted by one or more radicals R¹; two adjacent radicals R or R with R¹ here may also form a mono- or polycyclic, aliphatic or aromatic ring system with one another. These radicals R are particularly preferably selected on each occurrence, identically or differently, from the group consisting of H, D, F, a straight-chain alkyl group having 1 to 6 C atoms or a branched or cyclic alkyl group having 3 to 10 C atoms, where one or more H atoms may be replaced by F, or an aromatic or heteroaromatic ring system having 5 to 18 aromatic ring atoms, which may in each case be substituted by one or more radicals R¹; two adjacent radicals R or R with R¹ here may also form a mono- or polycyclic, aliphatic or aromatic ring system with one another. In the case of an aromatic or heteroaromatic ring system, it is preferred for this to have not more than two aromatic 6-membered rings condensed directly onto one another, in particular absolutely no aromatic 6-membered rings condensed directly onto one another.

Preferred ligands L′ as can occur in formula (1) are described below. The ligands L′ are by definition monoanionic bidentate ligands which coordinate to the iridium via two atoms, which are selected, identically or differently, from the group consisting of C, N, O and S. Preference is given to ligands which coordinate to the iridium via C and N, C and O, O and O or O and N.

In a preferred embodiment of the invention, the the ligands L′ are selected from 1,3-diketonates derived from 1,3-diketones, such as, for example, acetylacetone, benzoylacetone, 1,5-diphenylacetylacetone, dibenzoylmethane, bis(1,1,1-trifluoroacetyl)methane, 2,2,6,6-tetramethyl-3,5-heptanedione, 3-ketonates derived from 3-ketoesters, such as, for example, ethyl acetoacetate, carboxylates derived from aminocarboxylic acids, such as, for example, pyridine-2-carboxylic acid, quinoline-2-carboxylic acid, glycine, N,N-dimethylglycine, alanine, N,N-dimethylaminoalanine, carboxylates, 8-hydroxy- or 8-thiohydroxyquinolines and salicyliminates derived from salicylimines, such as, for example, methylsalicylimine, ethylsalicylimine, phenylsalicylimine.

In a further preferred embodiment of the invention, the ligands L′ are bidentate monoanionic ligands L′ which, with the iridium, form a cyclometallated five- or six-membered ring with at least one iridium-carbon bond, in particular a cyclometallated five-membered ring. These are, in particular, ligands as are generally used in the area of phosphorescent metal complexes for organic electroluminescent devices, i.e. ligands of the type phenylpyridine, naphthylpyridine, phenylquinoline, phenylisoquinoline, etc., each of which may be substituted by one or more radicals R. A multiplicity of ligands of this type is known to the person skilled in the art in the area of phosphorescent electroluminescent devices, and he will be able, without inventive step, to select further ligands of this type as ligand L′ for compounds of the formula (1). The combination of two groups, as represented by the following formulae (32) to (59), where one group is bonded via a neutral atom and the other group is bonded via a negatively charged atom, is generally particularly suitable for this purpose. The neutral atom here is, in particular, a neutral nitrogen atom or a carbene carbon atom and the negatively charged atom is, in particular, a negatively charged carbon atom, a negatively charged nitrogen atom or a negatively charged oxygen atom. The ligand L′ can then be formed from the groups of the formulae (32) to (59) by these groups bonding to one another in each case at the position denoted by #. The position at which the groups coordinate to the metal is denoted by *. Furthermore, two adjacent radicals R which are each bonded to the two groups of the formulae (32) to (59) form an aliphatic or aromatic ring system with one another.

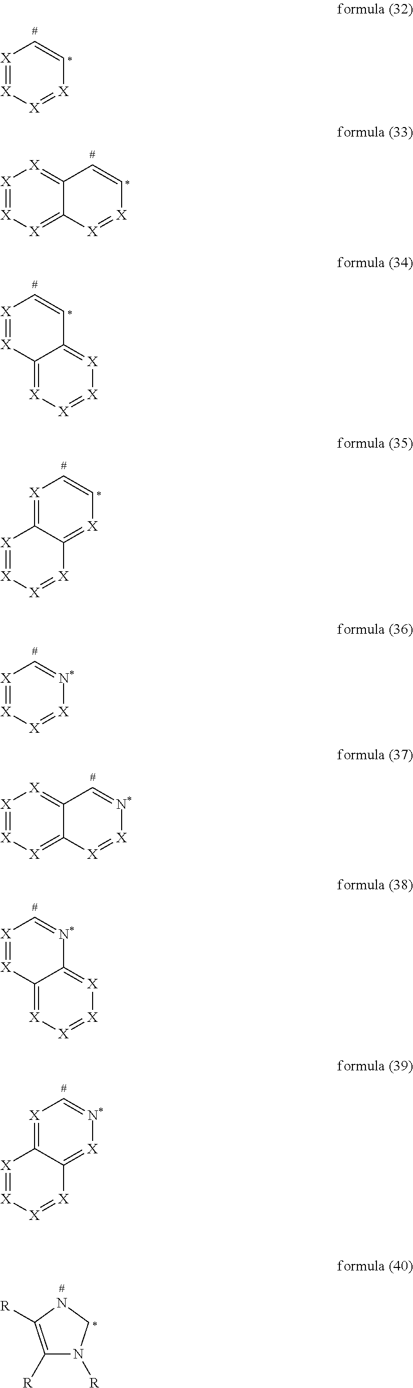

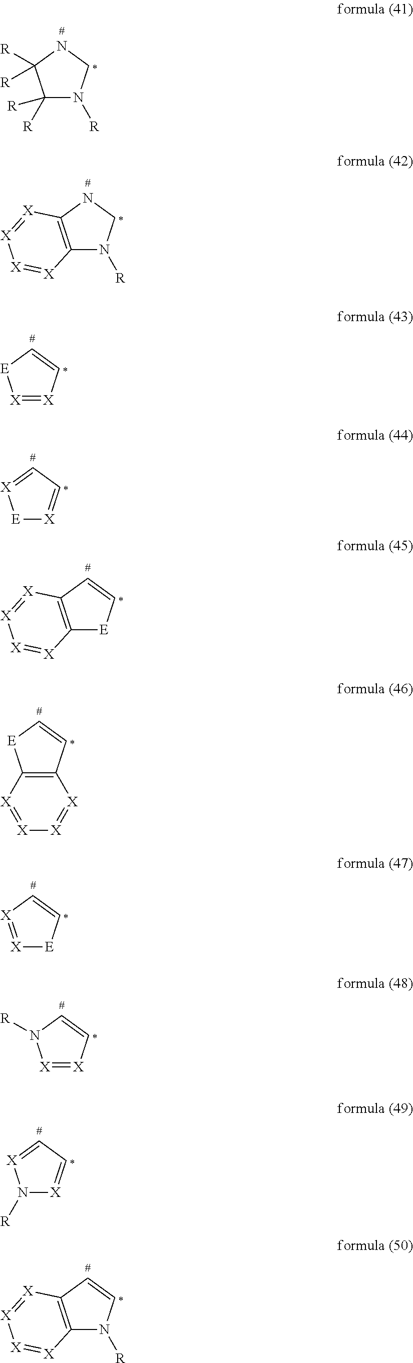

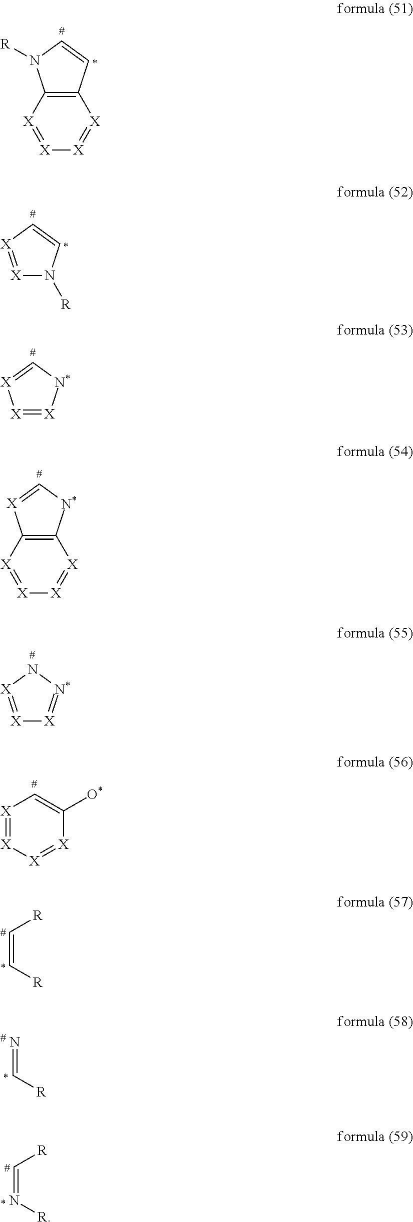

The symbols used here have the same meaning as described above, E stands for O, S or CR₂, and preferably a maximum of two symbols X in each group stand for N, particularly preferably a maximum of one symbol X in each group stands for N. Very particularly preferably, all symbols X stand for CR.

In a very particularly preferred embodiment of the invention, the ligand L′ is a monoanionic ligand formed from two of the groups of the formulae (32) to (59), where one of these groups is coordinated to the iridium via a negatively charged carbon atom and the other of these groups is coordinated to the iridium via a neutral nitrogen atom.

It may likewise be preferred for two adjacent symbols X in these ligands to stand for a group of the above-mentioned formula (25) or (26).

The further preferred radicals R in the structures shown above are defined like the radicals R of the ligand L.

The ligands L and L′ may also be chiral, depending on the structure. This is the case, in particular, if they contain a bicyclic group of the formulae (28) to (31) or if they contain substituents, for example alkyl, alkoxy, dialkylamino or aralkyl groups, which have one or more stereocentres. Since the basic structure of the complex may also be a chiral structure, the formation of diastereomers and a plurality of enantiomer pairs is possible. The complexes according to the invention then encompass both the mixtures of the various diastereomers or the corresponding racemates and also the individual isolated diastereomers or enantiomers.

The compounds according to the invention may also be rendered soluble by suitable substitution, for example by relatively long alkyl groups (about 4 to 20 C atoms), in particular branched alkyl groups, or optionally substituted aryl groups, for example xylyl, mesityl or branched terphenyl or quaterphenyl groups. Compounds of this type are then soluble in adequate concentration in common organic solvents at room temperature in order to enable the complexes to be processed from solution, for example by printing processes.

The preferred embodiments mentioned above can be combined with one another as desired. In a particularly preferred embodiment of the invention, the preferred embodiments mentioned above apply simultaneously.

The metal complexes according to the invention can in principle be prepared by various processes. However, the processes described below have proven particularly suitable.

The present invention therefore furthermore relates to a process for the preparation of the compounds of the formula (1) according to the invention by reaction of the corresponding free ligands with iridium alkoxides of the formula (60), with iridium ketoketonates of the formula (61), with iridium halides of the formula (62) or with dimeric iridium complexes of the formula (63) or (64),

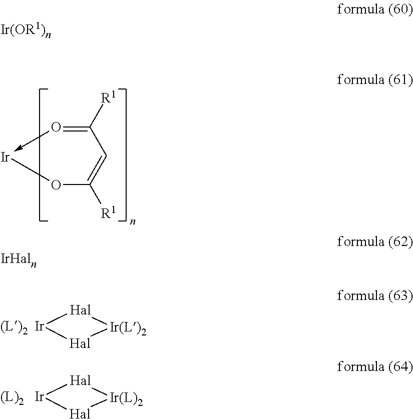

where the symbols and indices L′, m, n and R¹ have the meanings indicated above, and Hal=F, Cl, Br or I.

It is likewise possible to use iridium compounds which carry both alkoxide and/or halide and/or hydroxyl and also ketoketonate radicals. These compounds may also be charged. Corresponding iridium compounds which are particularly suitable as starting materials are disclosed in WO 2004/085449. [IrCl₂(acac)₂]-, for example Na[IrCl₂(acac)₂], is particularly suitable. Further particularly suitable iridium starting materials are iridium(III) tris(acetylacetonate) and iridium(III) tris(2,2,6,6-tetramethyl-3,5-heptane-dionate).

The synthesis of the complexes is preferably carried out as described in WO 2002/060910 and in WO 2004/085449. Heteroleptic complexes can also be synthesised, for example, in accordance with WO 05/042548. The synthesis here can also be activated, for example, thermally, photochemically and/or by microwave radiation. Furthermore, the synthesis can also be carried out in an autoclave at elevated pressure and/or elevated temperature.

The synthesis of the complexes according to the invention can preferably be carried out in accordance with Scheme 1. Firstly, reaction of the free ligands L-H with a suitable Ir precursor, preferably iridium(III) chloride hydrate, in the presence of a protic solvent or solvent mixture gives the chloro-bridged dimeric iridium complexes, which are then reacted further with a ligand L′, optionally with addition of additives, such as bases or salts (WO 2007/065523).

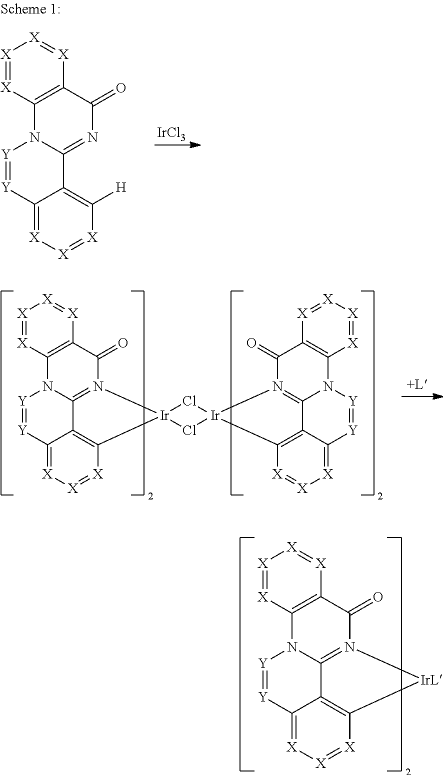

The preparation of heteroleptic iridium complexes can be carried out entirely analogously starting from the chloro-bridged dimer [(L′)₂IrCl]₂ by reaction with the free ligand L-H (Scheme 2).

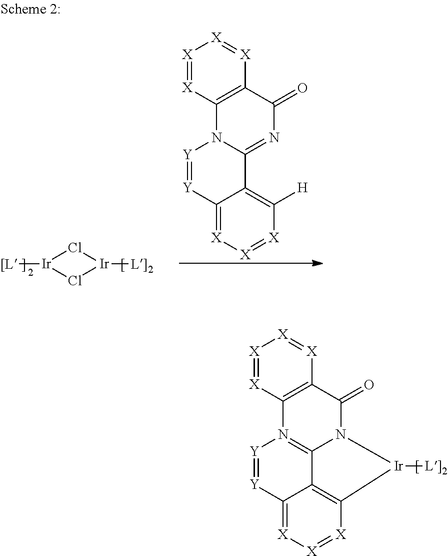

This process usually gives mixtures comprising complex types of the formula Ir(L)₂(L′) and of the formula Ir(L)(L′)₂, which can be separated by chromatography. The relative amounts of the complex types of the formula Ir(L)₂(L′) and of the formula Ir(L)(L′)₂ can be controlled through the stoichiometric ratio of [Ir(L)₂Cl]₂ to ligand L′. Thus, in the case of a stoichiometric ratio of [Ir(L)₂Cl]₂ to L′ of 1:2 to about 1:6, the product of the formula Ir(L)₂(L′) is formed in the majority, whereas in the case of a stoichiometric ratio of [Ir(L)₂Cl]₂ to L′ of about 1:8 to about 1:25, the product of the formula Ir(L)(L′)₂ is formed in the majority.

Instead of starting from the chloro-bridged dimer, the synthesis can also be carried out by reaction of the ligands L with iridium complexes of the formula [Ir(L′)₂(HOMe)₂]A or [Ir(L′)₂(NCMe)₂]A or by reaction of the ligands L′ with iridium complexes of the formula [Ir(L)₂(HOMe)₂]A or [Ir(L)₂(NCMe)₂]A, where A in each case represents a non-coordinating anion, such as, for example, triflate, tetrafluoroborate, hexafluorophosphate, etc., in dipolar protic solvents, such as, for example, ethylene glycol, propylene glycol, glycerol, diethylene glycol, triethylene glycol, etc.

In the case of a stoichiometric ratio of [Ir(L′)₂(HOMe)₂]A or [Ir(L′)₂(NCMe)₂]A to L of 1:1, predominantly the complexes of the formula Ir(L)(L′)₂ are obtained. In the case of a stoichiometric ratio of [Ir(L′)₂(HOMe)₂]A or [Ir(L′)₂(NCMe)₂]A to L of 1:2 or greater, essentially the complexes of the formula Ir(L)₂(L′) are formed, meaning that this method is highly suitable for the preparation of these complexes in good yield. The crude products comprising the two complex types of the formula Ir(L)₂(L′) and of the formula Ir(L)(L′)₂ can be separated by chromatography and thus purified.

The synthetic methods explained here can be used, inter alia, for the preparation of the structures according to the invention depicted below.

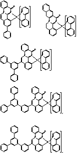

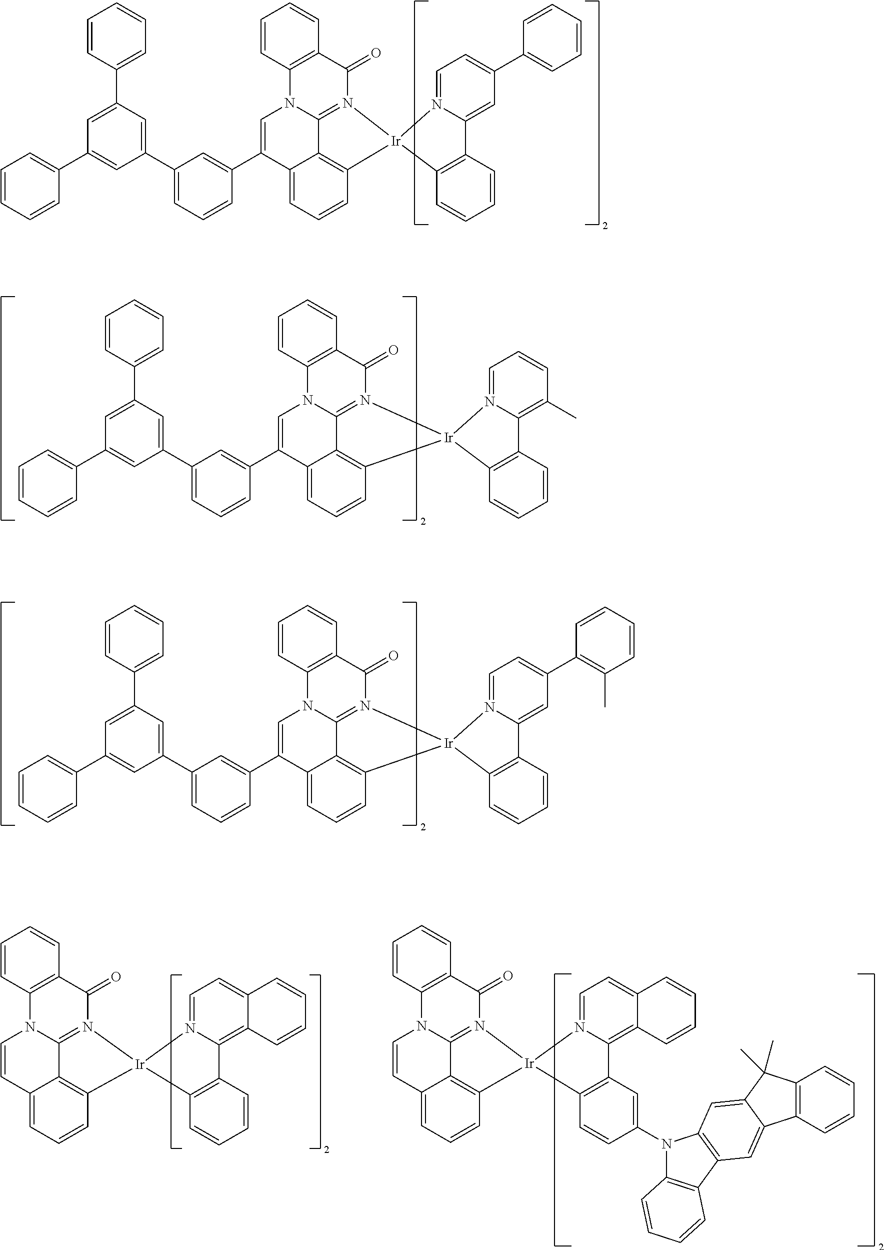

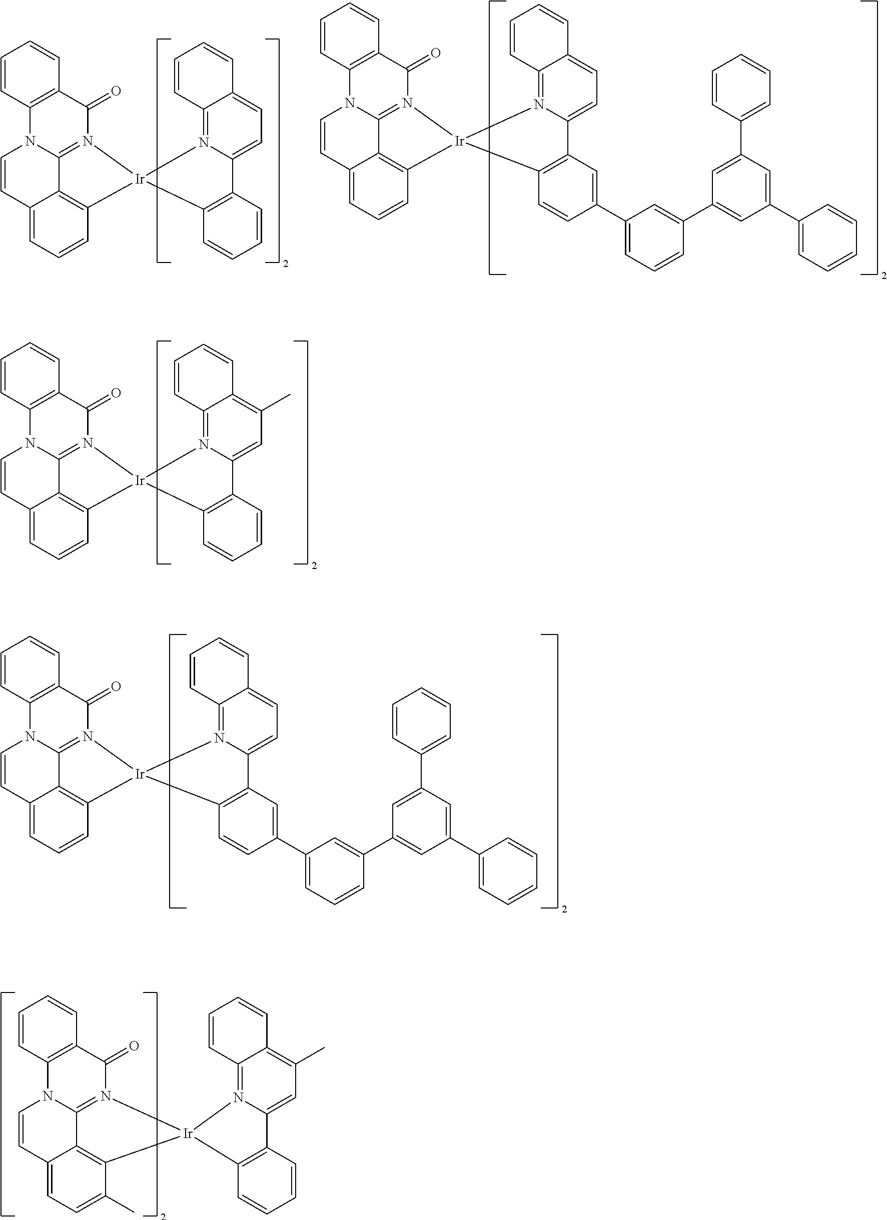

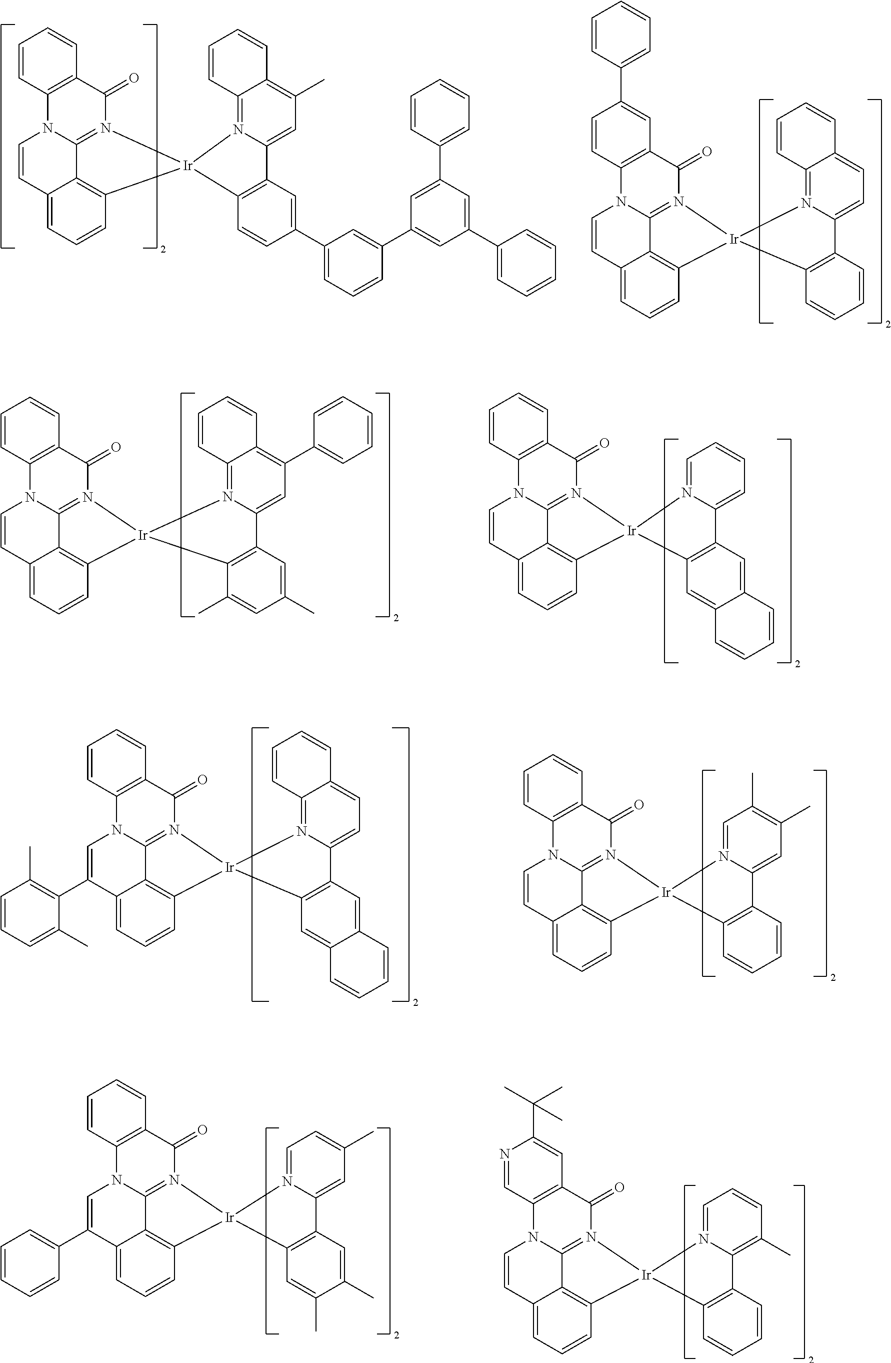

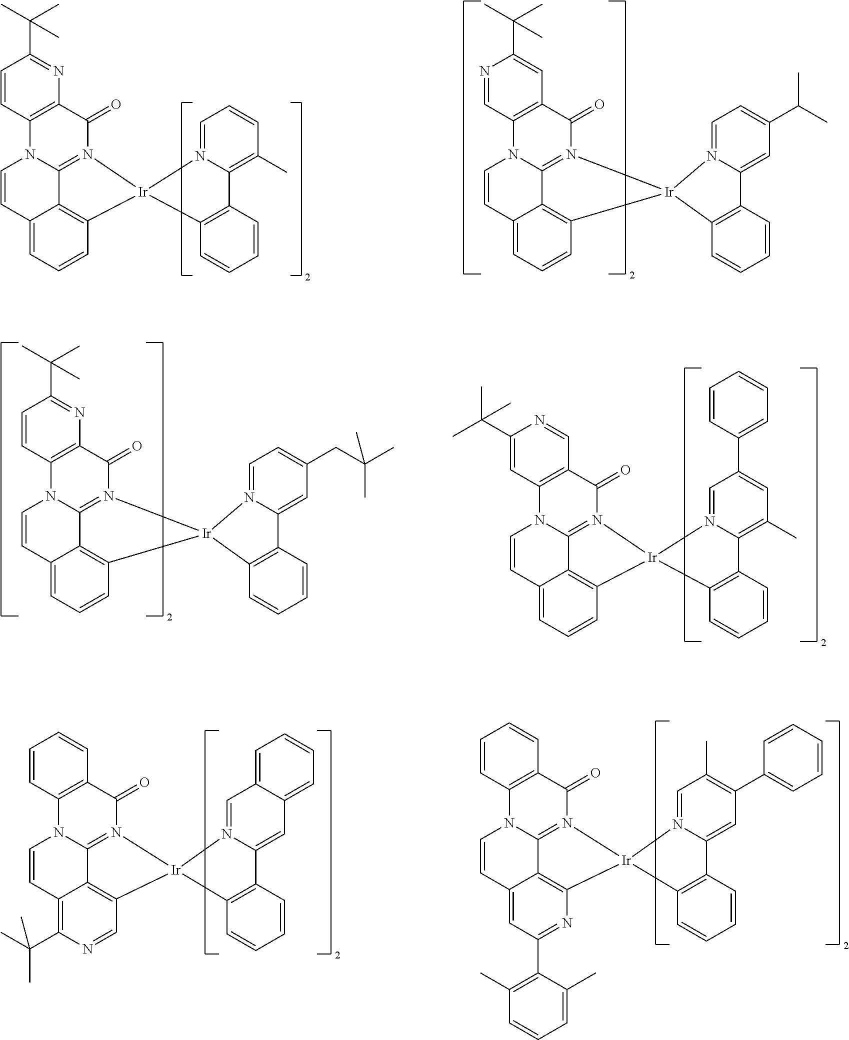

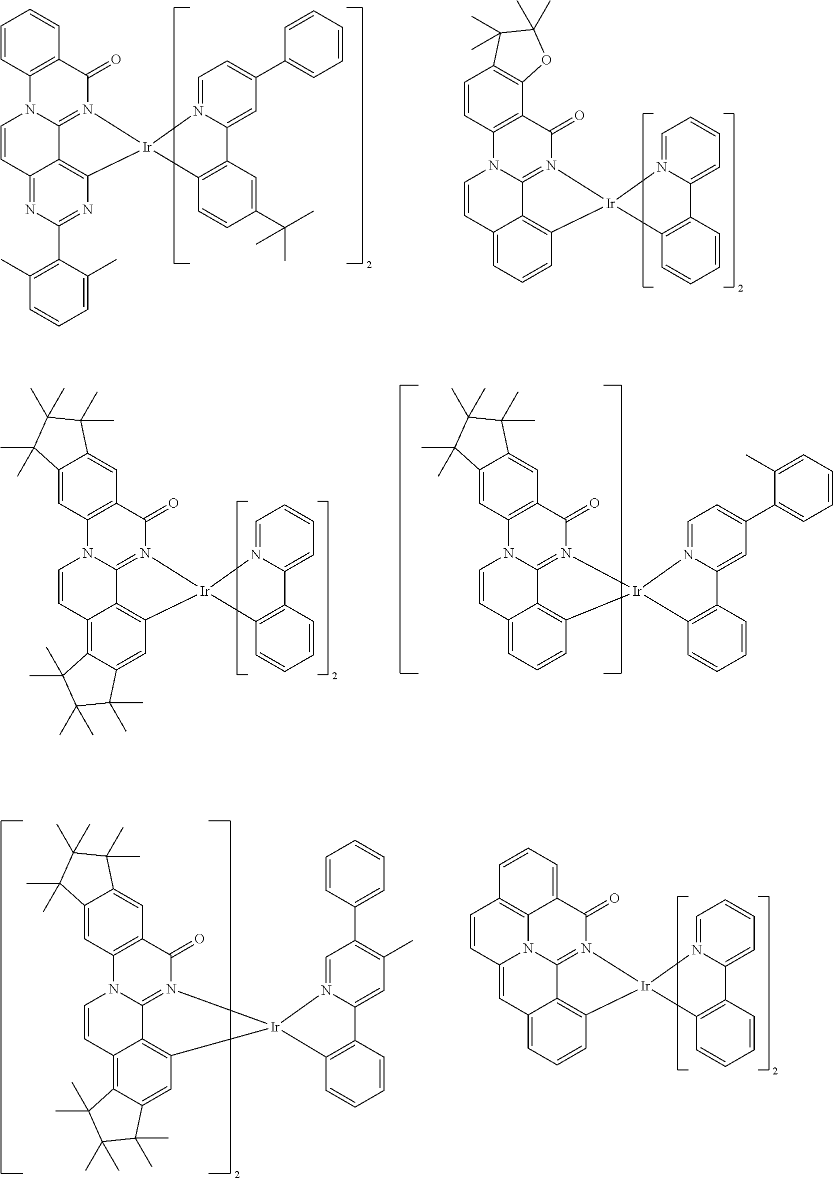

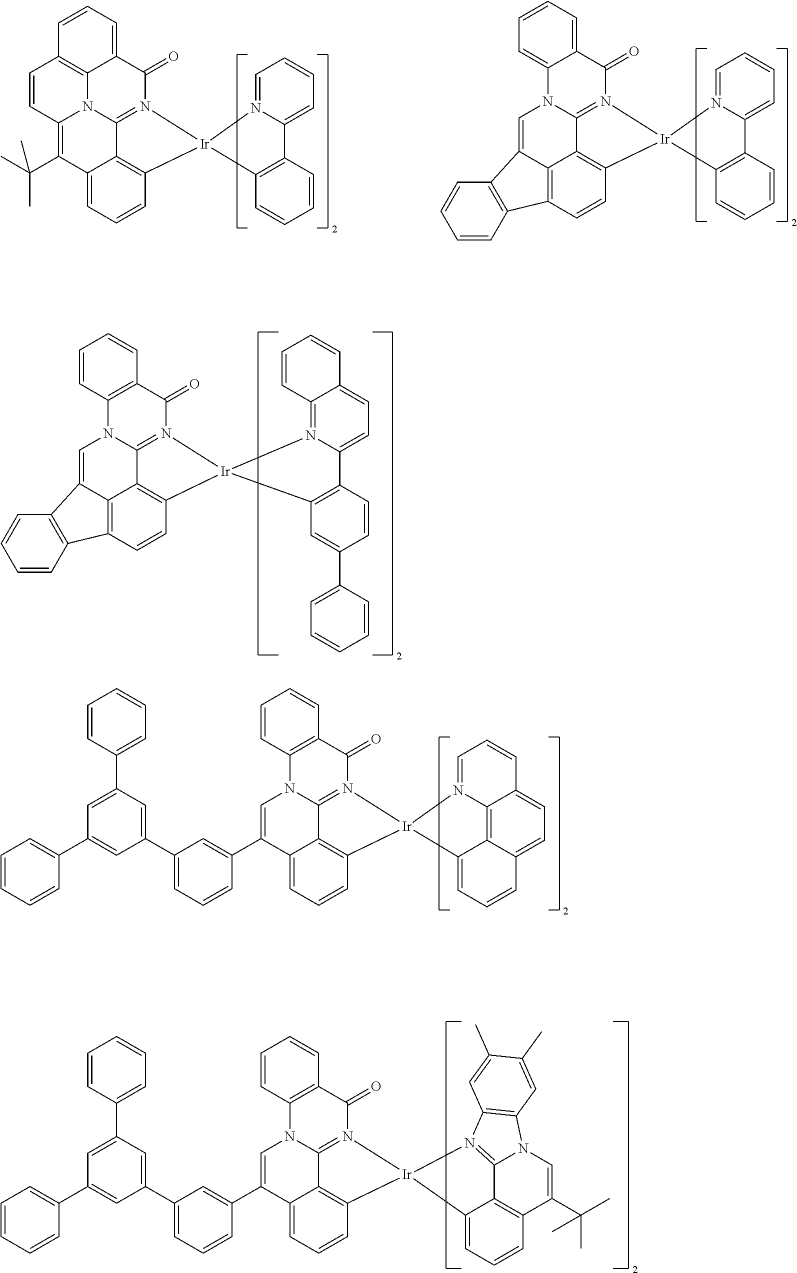

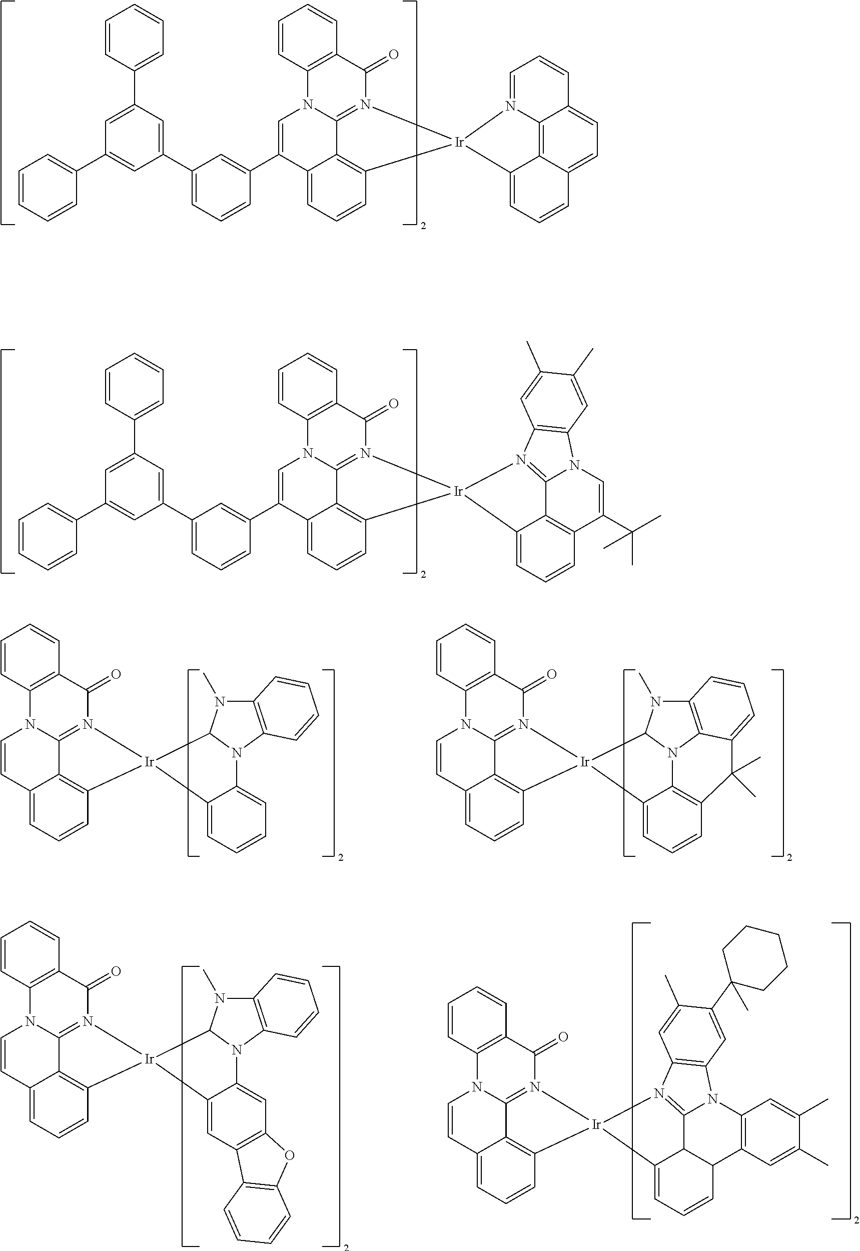

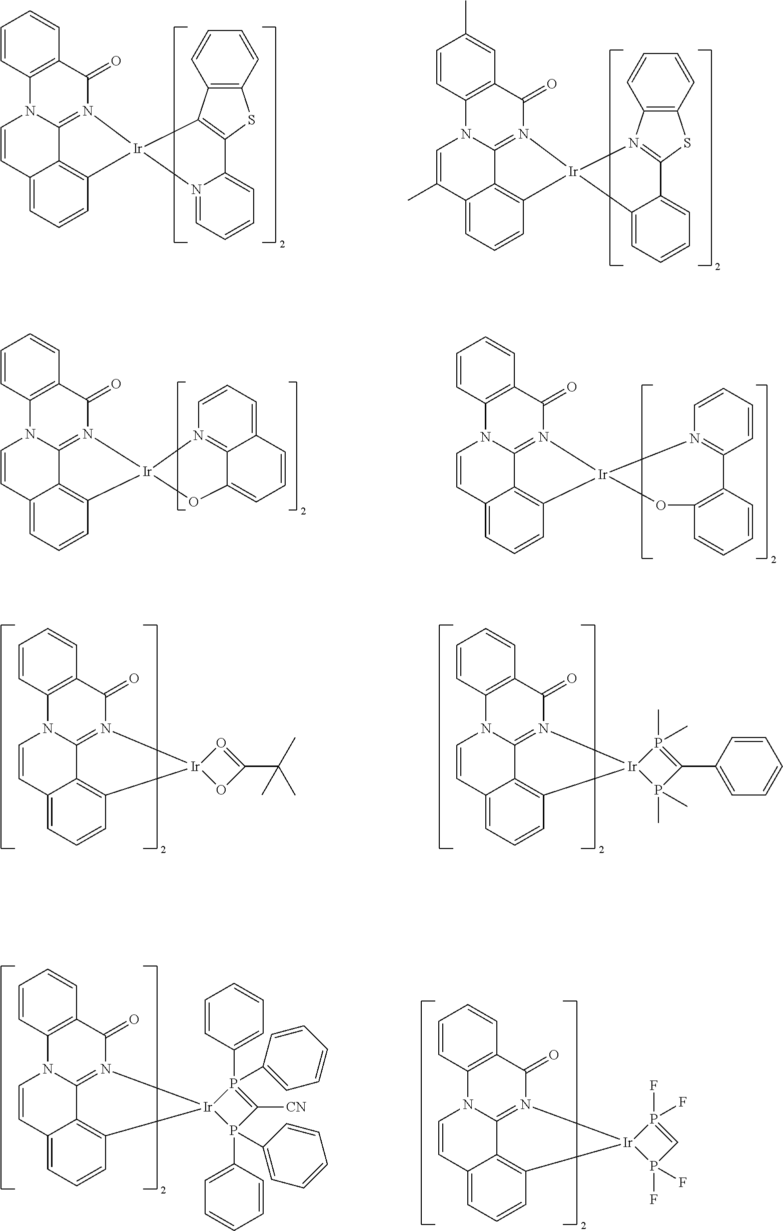

For the processing of the compounds according to the invention from the liquid phase, for example by spin coating or by printing processes, formulations of the compounds according to the invention are necessary. These formulations can be, for example, solutions, dispersions or emulsions. It may be preferred to use mixtures of two or more solvents for this purpose. Suitable and preferred solvents are, for example, toluene, anisole, o-, m- or p-xylene, methyl benzoate, mesitylene, tetralin, veratrol, THF, methyl-THF, THP, chlorobenzene, dioxane, phenoxytoluene, in particular 3-phenoxytoluene, (-)-fenchone, 1,2,3,5-tetramethylbenzene, 1,2,4,5-tetramethylbenzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, a-terpineol, benzothiazole, butyl benzoate, cumene, cyclohexanol, cyclohexanone, cyclohexylbenzene, decalin, dodecylbenzene, ethyl benzoate, indane, methyl benzoate, NMP, pcymene, phenetole, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol monobutyl ether, tripropylene glycol dimethyl ether, tetraethylene glycol dimethyl ether, 2-isopropylnaphthalene, pentylbenzene, hexylbenzene, heptylbenzene, octylbenzene, 1,1-bis(3,4-dimethylphenyl)ethane or mixtures of these solvents.

The present invention therefore furthermore relates to a formulation comprising a compound according to the invention and at least one further compound. The further compound may be, for example, a solvent, in particular one of the above-mentioned solvents or a mixture of these solvents. However, the further compound may also be a further organic or inorganic compound which is likewise employed in the electronic device, for example a matrix material. Suitable matrix materials are shown below in connection with the organic electroluminsscent device. This further compound may also be polymeric.

The complexes of the formula (1) described above or the preferred embodiments indicated above can be used as active component in an electronic device. The present invention therefore furthermore relates to the use of a compound of the formula (1) or according to one of the preferred embodiments in an electronic device. The compounds according to the invention can furthermore be employed for the generation of singlet oxygen, in photocatalysis or in oxygen sensors.

The present invention still furthermore relates to an electronic device comprising at least one compound of the formula (1) or according to one of the preferred embodiments.

An electronic device is taken to mean a device which comprises an anode, a cathode and at least one layer, where this layer comprises at least one organic or organometallic compound. The electronic device according to the invention thus comprises an anode, a cathode and at least one layer which comprises at least one compound of the formula (1) given above. Preferred electronic devices here are selected from the group consisting of organic electroluminescent devices (OLEDs, PLEDs), organic integrated circuits (O-ICs), organic field-effect transistors (O-FETs), organic thin-film transistors (O-TFTs), organic light-emitting transistors (O-LETs), organic solar cells (O-SCs), organic optical detectors, organic photoreceptors, organic field-quench devices (O-FQDs), light-emitting electrochemical cells (LECs) or organic laser diodes (O-lasers), comprising at least one compound of the formula (1) given above in at least one layer. Particular preference is given to organic electroluminescent devices. Active components are generally the organic or inorganic materials which have been introduced between the anode and cathode, for example charge-injection, charge-transport or charge-blocking materials, but in particular emission materials and matrix materials. The compounds according to the invention exhibit particularly good properties as emission material in organic electroluminescent devices. A preferred embodiment of the invention is therefore organic electroluminescent devices.

The organic electroluminescent device comprises cathode, anode and at least one emitting layer. Apart from these layers, it may also comprise further layers, for example in each case one or more hole-injection layers, hole-transport layers, hole-blocking layers, electron-transport layers, electron-injection layers, exciton-blocking layers, electron-blocking layers, charge-generation layers and/or organic or inorganic p/n junctions. Inter-layers, which have, for example, an exciton-blocking function and/or control the charge balance in the electroluminescent device, may likewise be introduced between two emitting layers. However, it should be pointed out that each of these layers does not necessarily have to be present.

The organic electroluminescent device here may comprise one emitting layer or a plurality of emitting layers. If a plurality of emission layers are present, these preferably have in total a plurality of emission maxima between 380 nm and 750 nm, resulting overall in white emission, i.e. various emitting compounds which are able to fluoresce or phosphoresce are used in the emitting layers. A preferred embodiment is three-layer systems, where the three layers exhibit blue, green and orange or red emission (see, for example, WO 2005/011013), or systems which have more than three emitting layers. A further preferred embodiment is two-layer systems, where the two layers exhibit either blue and yellow or cyan and orange emission. Two-layer systems are of particular interest for lighting applications. Embodiments of this type with the compounds according to the invention are particularly suitable, since they frequently exhibit yellow or orange emission. The white-emitting electroluminescent devices can be employed for lighting apllications or as backlight for displays or with colour filters as displays.

In a preferred embodiment of the invention, the organic electroluminescent device comprises the compound of the formula (1) or the preferred embodiments indicated above as emitting compound in one or more emitting layers.

If the compound of the formula (1) is employed as emitting compound in an emitting layer, it is preferably employed in combination with one or more matrix materials. The mixture comprising the compound of the formula (1) and the matrix material comprises between 1 and 99% by vol., preferably between 2 and 90% by vol., particularly preferably between 3 and 40% by vol., especially between 5 and 15% by vol., of the compound of the formula (1), based on the entire mixture comprising emitter and matrix material. Correspondingly, the mixture comprises between 99.9 and 1% by vol., preferably between 98 and 10% by vol., particularly preferably between 97 and 60% by vol., in particular between 95 and 85% by vol., of the matrix material or matrix materials, based on the entire mixture comprising emitter and matrix material.

The matrix material employed can in general be all materials which are known for this purpose in accordance with the prior art. The triplet level of the matrix material is preferably higher than the triplet level of the emitter.

Suitable matrix materials for the compounds according to the invention are ketones, phosphine oxides, sulfoxides and sulfones, for example in accordance with WO 2004/013080, WO 2004/093207, WO 2006/005627 or WO 2010/006680, triarylamines, carbazole derivatives, for example CBP (N,N-biscarbazolylbiphenyl), m-CBP or the carbazole derivatives disclosed in WO 2005/039246, US 2005/0069729, JP 2004/288381, EP 1205527, WO 2008/086851 or US 2009/0134784, indolocarbazole derivatives, for example in accordance with WO 2007/063754 or WO 2008/056746, indenocarbazole derivatives, for example in accordance with WO 2010/136109 or WO 2011/000455, azacarbazoles, for example in accordance with EP 1617710, EP 1617711, EP 1731584, JP 2005/347160, bipolar matrix materials, for example in accordance with WO 2007/137725, silanes, for example in accordance with WO 2005/111172, azaboroles or boronic esters, for example in accordance with WO 2006/117052, diazasilole derivatives, for example in accordance with WO 2010/054729, diazaphosphole derivatives, for example in accordance with WO 2010/054730, triazine derivatives, for example in accordance with WO 2010/015306, WO 2007/063754 or WO 2008/056746, zinc complexes, for example in accordance with EP 652273 or WO 2009/062578, beryllium complexes, dibenzofuran derivatives, for example in accordance with WO 2009/148015, or bridged carbazole derivatives, for example in accordance with US 2009/0136779, WO 2010/050778, WO 2011/042107 or WO 2011/088877.

It may also be preferred to employ a plurality of different matrix materials as a mixture. Suitable for this purpose are, in particular, mixtures of at least one electron-transporting matrix material and at least one hole-transporting matrix material or mixtures of at least two electron-transporting matrix materials or mixtures of at least one hole- or electron-transporting matrix material and at least one further material having a large band gap, which is thus substantially electrically inert and does not participate or does not participate to a significant extent in charge transport, as described, for example, in WO 2010/108579. A preferred combination is, for example, the use of an aromatic ketone or a triazine derivative with a triarylamine derivative or a carbazole derivative as mixed matrix for the metal complex according to the invention.

It is furthermore preferred to employ a mixture of two or more triplet emitters together with a matrix. The triplet emitter having the shorter-wave emission spectrum serves as co-matrix for the triplet-emitter having the longer-wave emission spectrum. Thus, for example, blue- or green-emitting triplet emitters can be employed as co-matrix for the complexes of the formula (1) according to the invention.

The cathode preferably comprises metals having a low work function, metal alloys or multilayered structures comprising various metals, such as, for example, alkaline-earth metals, alkali metals, main-group metals or lanthanoids (for example Ca, Ba, Mg, Al, In, Mg, Yb, Sm, etc.). Also suitable are alloys comprising an alkali metal or alkaline-earth metal and silver, for example an alloy comprising magnesium and silver. In the case of multilayered structures, further metals which have a relatively high work function, such as, for example, Ag, may also be used in addition to the said metals, in which case combinations of the metals, such as, for example, Ca/Ag or Ba/Ag, are generally used. It may also be preferred to introduce a thin interlayer of a material having a high dielectric constant between a metallic cathode and the organic semiconductor. Suitable for this purpose are, for example, alkali metal or alkaline-earth metal fluorides, but also the corresponding oxides or carbonates (for example LiF, Li₂O, BaF_{2,} MgO, NaF, CsF, Cs₂CO_{3,} etc.). The layer thickness of this layer is preferably between 0.5 and 5 nm.

The anode preferably comprises materials having a high work function. The anode preferably has a work function of greater than 4.5 eV vs. vacuum. Suitable for this purpose are on the one hand metals having a high redox potential, such as, for example, Ag, Pt or Au. On the other hand, metal/metal oxide electrodes (for example Al/Ni/NiOₓ, Al/PtOₓ) may also be preferred. For some applications, at least one of the electrodes must be transparent or partially transparent in order either to facilitate irradiation of the organic material (O-SCs) or the coupling-out of light (OLEDs/PLEDs, O-LASERs). A preferred structure uses a transparent anode. Preferred anode materials here are conductive mixed metal oxides. Particular preference is given to indium tin oxide (ITO) or indium zinc oxide (IZO). Preference is furthermore given to conductive, doped organic materials, in particular conductive doped polymers.

All materials as are used in accordance with the prior art for the layers can generally be used in the further layers, and the person skilled in the art will be able to combine each of these materials with the materials according to the invention in an electronic device without inventive step.

The device is correspondingly structured (depending on the application), provided with contacts and finally hermetically sealed, since the lifetime of such devices is drastically shortened in the presence of water and/or air.

Preference is furthermore given to an organic electroluminescent device, characterised in that one or more layers are coated by means of a sublimation process, in which the materials are vapour-deposited in vacuum sublimation units at an initial pressure of usually less than 10⁻⁵ mbar, preferably less than 10⁻⁶ mbar. It is also possible for the initial pressure to be even lower, for example less than 10⁻⁷ mbar.

Preference is likewise given to an organic electroluminescent device, characterised in that one or more layers are coated by means of the OVPD (organic vapour phase deposition) process or with the aid of carrier-gas sublimation, in which the materials are applied at a pressure of between 10⁻⁵ mbar and 1 bar. A special case of this process is the OVJP (organic vapour jet printing) process, in which the materials are applied directly through a nozzle and thus structured (for example M. S. Arnold et al., Appl. Phys. Lett. 2008, 92, 053301).

Preference is furthermore given to an organic electroluminescent device, characterised in that one or more layers are produced from solution, such as, for example, by spin coating, or by means of any desired printing process, such as, for example, screen printing, flexographic printing or offset printing, but particularly preferably LITI (light induced thermal imaging, thermal transfer printing) or ink-jet printing. Soluble compounds are necessary for this purpose, which are obtained, for example, through suitable substitution.

The organic electroluminescent device may also be produced as a hybrid system by applying one or more layers from solution and applying one or more other layers by vapour deposition. Thus, for example, it is possible to apply an emitting layer comprising a compound of the formula (1) and a matrix material from solution and to apply a hole-blocking layer and/or an electron-transport layer on top by vacuum vapour deposition.

These processes are generally known to the person skilled in the art and can be applied by him without problems to organic electroluminescent devices comprising compounds of the formula (1) or the preferred embodiments indicated above.

The electronic devices according to the invention, in particular organic electroluminescent devices, are distinguished by the following surprising advantages over the prior art:
1. Organic electroluminescent devices comprising compounds of the formula (1) as emitting materials have a very good lifetime.
2. Organic electroluminescent devices comprising compounds of the formula (1) as emitting materials have very good efficiency.
3. Organic electroluminescent devices comprising compounds of the formula (1) as emitting materials have a very low operating voltage.

These advantages mentioned above are not accompanied by an impairment of the other electronic properties. In particular, the lifetime and/or efficiency of the compounds according to the invention are better than the lifetime or efficiency of the corresponding homoleptic complexes IrL₃.

The invention is explained in greater detail by the following examples, without wishing to restrict it thereby. The person skilled in the art will be able to use the descriptions to synthesise further compounds according to the invention without inventive step and use them in electronic devices and will thus be able to carry out the invention throughout the range disclosed.

### EXAMPLES

The following syntheses are carried out, unless indicated otherwise, in dried solvents under a protective-gas atmosphere. The metal complexes are additionally handled with exclusion of light or under yellow light. The solvents and reagents can be purchased, for example, from Sigma-ALDRICH or ABCR. The numbers in the case of the compounds known from the lterature, which are in some cases also indicated in square brackets, are the CAS numbers of the compounds.

A: Synthesis of Synthones S

### Example S1

### 5,6-Dibromo-1,1,2,2,3,3-hexamethylindane, S1

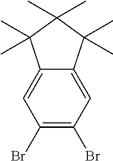

1.3 g of anhydrous iron(III) chloride are added to a solution of 101.2 g (500 mmol) of 1,1,2,2,3,3-hexamethylindane [91324-94-6] in 1000 ml of dichloromethane, and then, with exclusion of light, a mixture of 76.8 ml (1.5 mol) of bromine and 100 ml of dichloromethane is added dropwise at such a rate that the temperature does not exceed 25° C.; if necessary, the mixture is counter-cooled using a cold-water bath. When the addition is complete, the reaction mixture is stirred at 35° C. for a further 30 h, 1000 ml of saturated sodium sulfite solution are then slowly added, the aqueous phase is separated off, the organic phase is washed three times with 1000 ml of water each time, dried over sodium sulfate, filtered through a short silica-gel column, and the solvent is then stripped off. Finally, the solid is recrystallised once from ethanol. Yield: 163.9 g (455 mmol), 91%; purity: about 98% according to ¹H-NMR.

The following compounds are prepared analogously:

| Ex. | Starting material | Product | Yield |
|---|---|---|---|
| S2 | 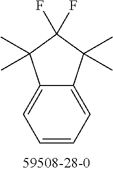 | 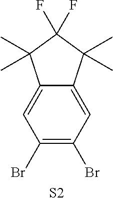 | 83% |
| S3 | 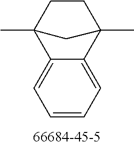 | 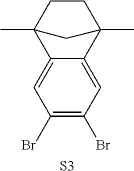 | 79% |
| S4 | 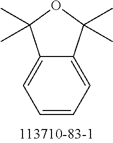 | 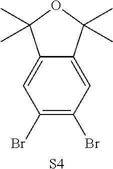 | 84% |
| S5 | 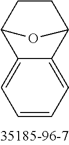 [SMILES: c1ccc2c(c1)C1CCC2O1] | 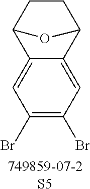 | 81% |

### Example S6

### 7-Bromo-1,2,3,4-tetrahydro-1,4-methanonaphthalene-6-carboxylic acid, S6

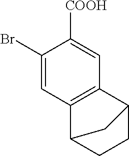 [SMILES: O=C(O)c1cc2c(cc1Br)C1CCC2C1]

Procedure analogous to J. Organomet. Chem., L. S. Chen et al., 1980, 193, 283-292. 40 ml (100 mmol) of n-butyllithium, 2.5M in hexane, precooled to −110° C., are added to a solution, cooled to −110° C., of 30.2 g (100 mmol) of 6,7-dibromo-1,2,3,4-tetrahydro-1,4-methanonaphthalene [42810-32-2] in a mixture of 1000 ml of THF and 1000 ml of diethyl ether at such a rate that the temperature does not exceed −105° C. The mixture is stirred for a further 30 min., and a dry stream of carbon dioxide is then passed into the reaction mixture with vigorous stirring for 15 min. The mixture is then allowed to warm slowly to room temperature, 55 ml of 2N HCl are added, the mixture is stirred at room temperature for a further 30 min., and the solvent is then stripped off in vacuo. The residue is dissolved in 500 ml of dichloromethane, the organic phase is washed once with 300 ml of 0.1N HCl and once with 100 ml of saturated sodium chloride solution and dried over magnesium sulfate. Finally, the solvent is removed in vacuo, the residue is washed by stirring in 150 ml of MeOH, the colourless solid is filtered off with suction, washed with a little methanol and dried in vacuo. Yield: 17.7 g (66 mmol), 66%; purity: about 95% according to ¹H-NMR.

The following compounds are prepared analogously:

| Ex. | Starting material | Product | Yield |
|---|---|---|---|
| S7 | 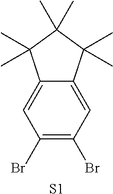 | 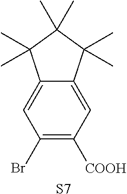 | 70% |
| S8 | 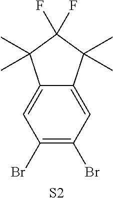 | 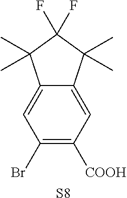 | 73% |
| S9 | 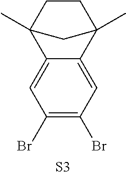 | 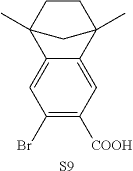 | 69% |
| S10 | 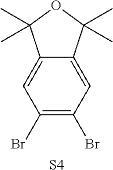 | 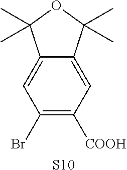 | 65% |
| S11 | 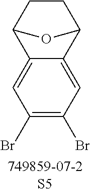 | 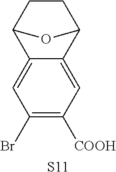 [SMILES: O=C(O)c1cc2c(cc1Br)C1CCC2O1 ; "S11"] | 73% |

### Example S12

### 3-Bromobiphenyl-2-carbonyl chloride, S12

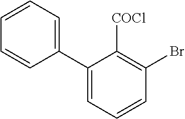 [SMILES: O=C(Cl)c1c(Br)cccc1-c1ccccc1]

94.3 ml (1.1 mol) of oxalyl chloride are added dropwise to a suspension of 277.1 g (1.0 mol) of 3-bromobiphenyl-2-carboxylic acid [94654-52-1] in 1000 ml of THF and 0.1 ml of DMF at such a rate that moderate evolution of gas (caution: HCl and CO) commences. When the addition is complete, stirring is continued at 40° C. until the evolution of gas is complete, and the excess oxalyl chloride and the THF are then removed at 40° C. in vacuo. The residue is employed without further purification for the synthesis of the ligands. Yield: quantitative.

The following compounds are prepared analogously:

| Ex. | Carboxylic acid | Carboxylic acid chloride | Yield |
|---|---|---|---|
| S13 | 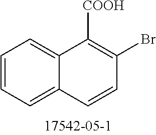 [SMILES: O=C(O)c1c(Br)ccc2ccccc12] | 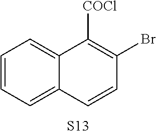 [SMILES: O=C(Cl)c1c(Br)ccc2ccccc12 ; "S13"] | quant. |
| S14 | 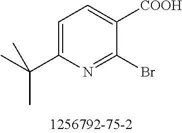 | 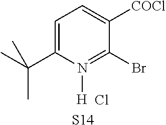 | quant. |
| S15 | 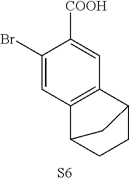 [SMILES: O=C(O)c1cc2c(cc1Br)C1CCC2C1 ; "S6"] | 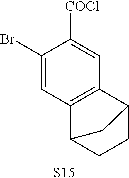 [SMILES: O=C(Cl)c1cc2c(cc1Br)C1CCC2C1 ; "S15"] | quant. |
| S16 | 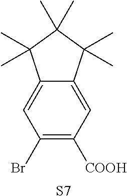 | 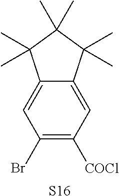 | quant. |
| S17 | 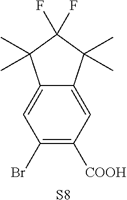 | 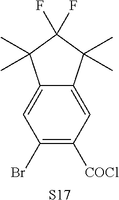 | quant. |
| S18 | 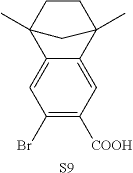 | 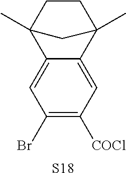 | quant. |
| S19 | 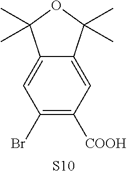 | 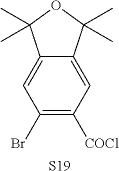 | quant. |
| S20 | 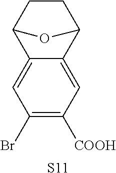 [SMILES: O=C(O)c1cc2c(cc1Br)C1CCC2O1 ; "S11"] | 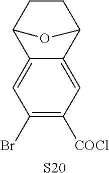 [SMILES: O=C(Cl)c1cc2c(cc1Br)C1CCC2O1 ; "S20"] | quant. |

### Example L1

### 6H-Isoquino[2,1-a]quinazolin-6-one, L1

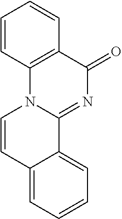 [SMILES: O=c1nc2c3ccccc3ccn2c2ccccc12]

A mixture of 219.5 g (1.0 mmol) of 2-bromobenzoyl chloride [7154-66-7] and 150 ml of dichloromethane is added dropwise to a vigorously stirred mixture, cooled to 0° C., of 144.2 g (1.0 mol) of 1-aminoisoquinoline [1532-84-9], 180.2 ml (1.3 mol) of triethylamine and 1300 ml of dichloromethane (DCM) at such a rate that the temperature does not exceed +5° C. When the addition is complete, the mixture is allowed to warm slowly to room temperature and is stirred at room temperature for a further 12 h. The reaction mixture is then washed 4× with 1000 ml of water each time and once with 1000 ml of saturated sodium chloride solution and dried over magnesium sulfate. The drying agent is filtered off and rinsed with 1000 ml of DCM, the filtrate is subsequently freed completely from DCM in vacuo. The residue is dissolved in 2000 ml of o-xylene, 327.2 g (1.0 mmol) of caesium carbonate, 9.5 g (50 mmol) of copper(I) iodide and 200 g of glass beads (diameter 3 mm) are added, and the mixture is heated under reflux with very vigorous stirring for 48 h. The o-xylene is substantially distilled off, the reaction mixture is allowed to cool, 1500 ml of DCM are added, the reaction mixture is filtered through a short Celite bed with suction, the bed is rinsed twice with 300 ml of DCM each time, the solvent is then removed in vacuo, and the residue is washed by stirring with 1000 ml of ethanol at 50° C. for 2 h. After cooling, the solid is filtered off with suction, washed once with 200 ml of ethanol, dried in vacuo and then sublimed at T about 160° C./p about 1×10⁻⁴ mbar in order to remove readily volatile and non-volatile components. Yield: 94.5 g (383 mmol), 38%. Purity: >99.5% according to ¹H-NMR.

The following ligands L are prepared analogously:

| Ex. | Amine | Carboxylic acid chloride | Ligand | Yield |
|---|---|---|---|---|
| L2 | 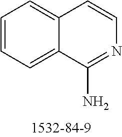 [SMILES: Nc1nccc2ccccc12] | 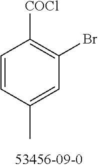 | 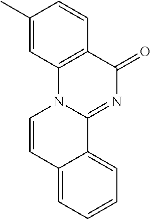 [SMILES: Cc1ccc2c(=O)nc3c4ccccc4ccn3c2c1] | 36% |
| L3 | 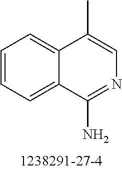 | 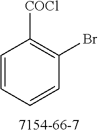 | 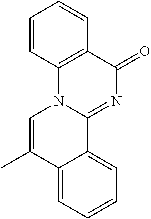 [SMILES: Cc1cn2c3ccccc3c(=O)nc2c2ccccc12] | 40% |
| L4 | 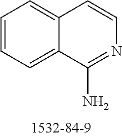 [SMILES: Nc1nccc2ccccc12] | 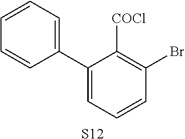 [SMILES: O=C(Cl)c1c(Br)cccc1-c1ccccc1 ; "S12"] | 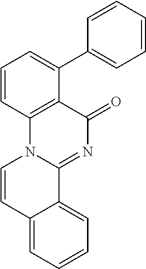 [SMILES: O=c1nc2c3ccccc3ccn2c2cccc(-c3ccccc3)c12] | 37% |
| L5 | 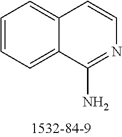 [SMILES: Nc1nccc2ccccc12] | 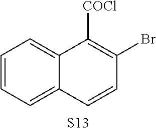 [SMILES: O=C(Cl)c1c(Br)ccc2ccccc12 ; "S13"] | 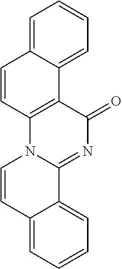 [SMILES: O=c1nc2c3ccccc3ccn2c2ccc3ccccc3c12] | 39% |
| L6 | 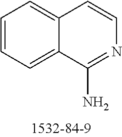 [SMILES: Nc1nccc2ccccc12] | 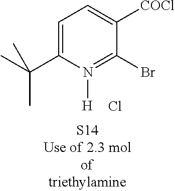 | 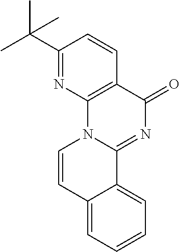 [SMILES: CC(C)(C)c1ccc2c(=O)nc3c4ccccc4ccn3c2n1] | 36% |
| L7 | 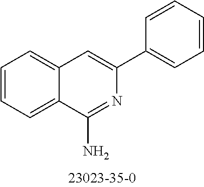 [SMILES: Nc1nc(-c2ccccc2)cc2ccccc12] | 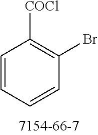 | 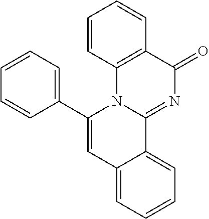 [SMILES: O=c1nc2c3ccccc3cc(-c3ccccc3)n2c2ccccc12] | 24% |
| L8 | 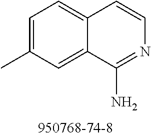 | 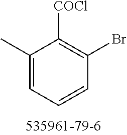 | 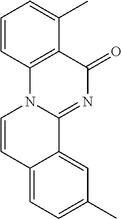 [SMILES: Cc1ccc2ccn3c4cccc(C)c4c(=O)nc3c2c1] | 43% |
| L9 | 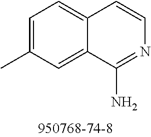 | 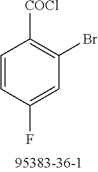 [SMILES: O=C(Cl)c1ccc(F)cc1Br] | 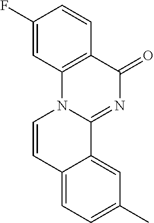 [SMILES: Cc1ccc2ccn3c4cc(F)ccc4c(=O)nc3c2c1] | 40% |
| L10 | 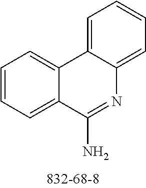 [SMILES: Nc1nc2ccccc2c2ccccc12] | 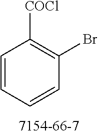 | 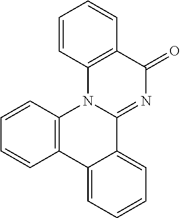 [SMILES: O=c1nc2c3ccccc3c3ccccc3n2c2ccccc12] | 32% |
| L11 | 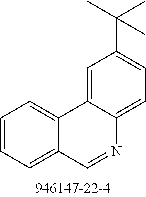 [SMILES: CC(C)(C)c1ccc2ncc3ccccc3c2c1] | 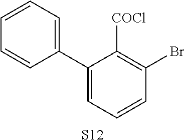 [SMILES: O=C(Cl)c1c(Br)cccc1-c1ccccc1 ; "S12"] | 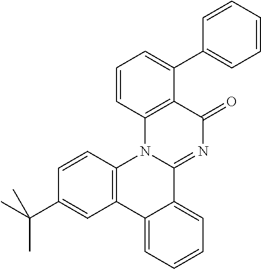 [SMILES: CC(C)(C)c1ccc2c(c1)c1ccccc1c1nc(=O)c3c(-c4ccccc4)cccc3n21] | 30% |
| L12 | 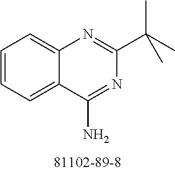 | 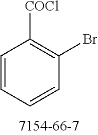 | 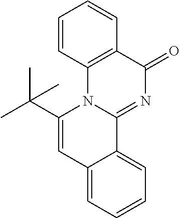 [SMILES: CC(C)(C)c1cc2ccccc2c2nc(=O)c3ccccc3n12] | 33% |
| L13 | 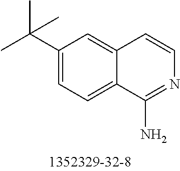 | 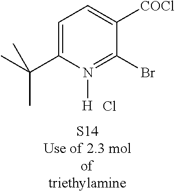 | 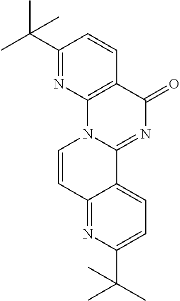 [SMILES: CC(C)(C)c1ccc2c(ccn3c4nc(C(C)(C)C)ccc4c(=O)nc23)n1] | 37% |
| L14 | 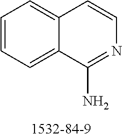 [SMILES: Nc1nccc2ccccc12] | 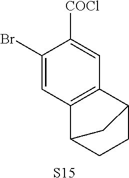 [SMILES: O=C(Cl)c1cc2c(cc1Br)C1CCC2C1 ; "S15"] | 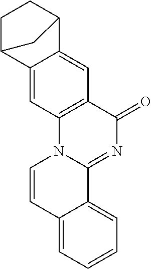 [SMILES: O=c1nc2c3ccccc3ccn2c2cc3c(cc12)C1CCC3C1] | 35% |
| L15 | 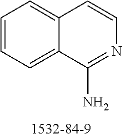 [SMILES: Nc1nccc2ccccc12] | 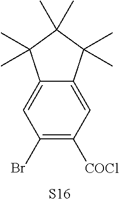 | 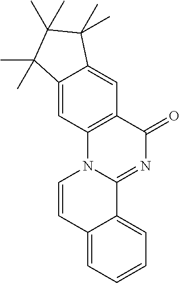 [SMILES: CC1(C)c2cc3c(=O)nc4c5ccccc5ccn4c3cc2C(C)(C)C1(C)C] | 41% |
| L16 | 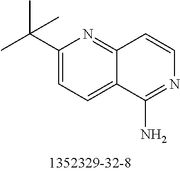 | 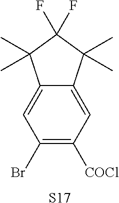 | 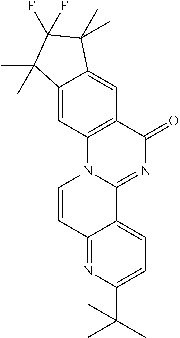 [SMILES: CC(C)(C)c1ccc2c(ccn3c4cc5c(cc4c(=O)nc23)C(C)(C)C(F)(F)C5(C)C)n1] | 30% |
| L17 | 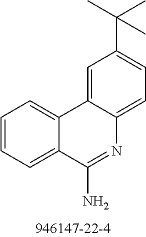 [SMILES: CC(C)(C)c1ccc2nc(N)c3ccccc3c2c1] | 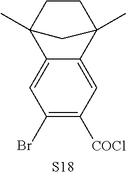 | 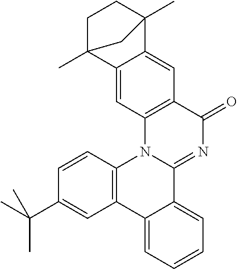 [SMILES: CC(C)(C)c1ccc2c(c1)c1ccccc1c1nc(=O)c3cc4c(cc3n21)C1(C)CCC4(C)C1] | 26% |
| L18 | 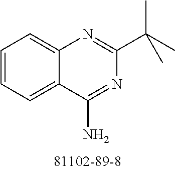 | 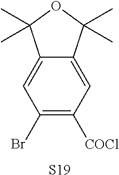 | 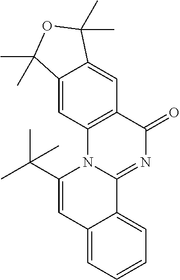 [SMILES: CC(C)(C)c1cc2ccccc2c2nc(=O)c3cc4c(cc3n12)C(C)(C)OC4(C)C] | 27% |
| L19 | 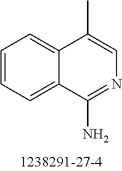 | 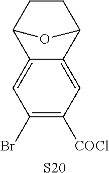 [SMILES: O=C(Cl)c1cc2c(cc1Br)C1CCC2O1 ; "S20"] | 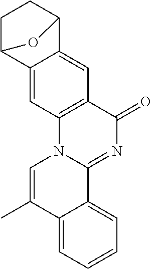 [SMILES: Cc1cn2c3cc4c(cc3c(=O)nc2c2ccccc12)C1CCC4O1] | 38% |

C: Synthesis of the Metal Complexes

1) Complexes of the Formula [Ir(L)₂Cl]₂:

A mixture of 10 mmol of sodium bisacetylacetonatodichloroiridate(III) [770720-50-8], 22 mmol of the ligand L and a glass-clad magnetic stirrer bar are introduced into a cylindrical reaction vessel (volume 40 ml) with screw cap and Teflon septum under inert gas (nitrogen or argon). The reaction mixture is slowly heated with stirring until a melt forms. The temperature is then slowly increased in 20° C. steps every 20 min. until the final temperature (see below) has been reached, with the acetylacetone forming being discharged via a cannula in the septum. When the final temperature has been reached, the reaction mixture is kept at the final temperature for a further 20 h. After cooling under protective gas, the sinter cake is mechanically comminuted, stirred with 100 g of glass beads (diameter 3 mm) in 100 ml of the suspension medium indicated (the suspension medium is selected so that the ligand is readily soluble therein, but the chloro dimer of the formula [Ir(L)₂Cl]₂ has low solubility therein, typical suspension media are diethyl ether, tert-butyl methyl ether, ethyl acetate, DCM, acetone, ethyl acetate, toluene, etc.) for 3 h and mechanically digested in the process. The fine suspension is decanted off from the glass beads, the solid ([Ir(L)₂Cl]₂, which still contains about 2 eq. of NaCl, called crude chloro dimer below) is filtered off with suction and dried in vacuo. The crude chloro dimer obtained in this way is subsequently employed without further purification.

The following iridium complexes are obtained analogously:

| | | | Final temp. | |
|---|---|---|---|---|
| | Ligand | | Suspension | |
| Ex. | L | Ir complex | medium | Yield |
| [Ir(L1)₂Cl]₂ | L1 | 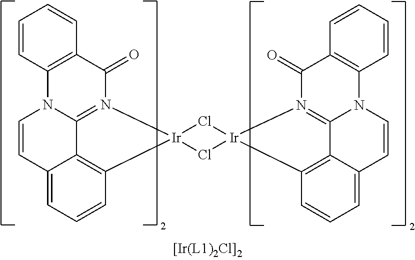 | 260° C. Ethyl acetate | 93% |
| [Ir(L2)₂Cl]₂ | L2 | [Ir(L2)₂Cl]₂ | 260° C. | 90% |
| | | | Ethyl acetate | |
| [Ir(L3)₂Cl]₂ | L3 | [Ir(L3)₂Cl]₂ | 260° C. | 94% |
| | | | Ethyl acetate | |
| [Ir(L4)₂Cl]₂ | L4 | [Ir(L4)₂Cl]₂ | 270° C. | 95% |
| | | | Ethyl acetate | |
| [Ir(L5)₂Cl]₂ | L5 | [Ir(L5)₂Cl]₂ | 280° C. | 91% |
| | | | Ethyl acetate | |
| [Ir(L6)₂Cl]₂ | L6 | [Ir(L6)₂Cl]₂ | 260° C. | 90% |
| | | | Acetone | |
| [Ir(L7)₂Cl]₂ | L7 | [Ir(L7)₂Cl]₂ | 260° C. | 86% |
| | | | Toluene | |
| [Ir(L8)₂Cl]₂ | L8 | [Ir(L8)₂Cl]₂ | 280° C. | 92% |
| | | | Ethyl acetate | |
| [Ir(L9)₂Cl]₂ | L9 | [Ir(L9)₂Cl]₂ | 280° C. | 92% |
| | | | Ethyl acetate | |
| [Ir(L10)₂Cl]₂ | L10 | [Ir(L10)₂Cl]₂ | 290° C. | 95% |
| | | | THF | |
| [Ir(L11)₂Cl]₂ | L11 | [Ir(L11)₂Cl]₂ | 270° C. | 90% |
| | | | Ethyl acetate | |
| [Ir(L12)₂Cl]₂ | L12 | [Ir(L12)₂Cl]₂ | 270° C. | 89% |
| | | | MeO-t-Bu | |
| [Ir(L13)₂Cl]₂ | L13 | [Ir(L13)₂Cl]₂ | 280° C. | 78% |
| | | | DCM | |
| [Ir(L14)₂Cl]₂ | L14 | [Ir(L14)₂Cl]₂ | 270° C. | 90% |
| | | | Ethyl acetate | |
| [Ir(L15)₂Cl]₂ | L15 | [Ir(L15)₂Cl]₂ | 270° C. | 90% |
| | | | Ethyl acetate | |
| [Ir(L16)₂Cl]₂ | L16 | [Ir(L16)₂Cl]₂ | 270° C. | 92% |
| | | | Ethyl acetate | |
| [Ir(L17)₂Cl]₂ | L17 | [Ir(L17)₂Cl]₂ | 290° C. | 93% |
| | | | Toluene | |
| [Ir(L18)₂Cl]₂ | L18 | [Ir(L18)₂Cl]₂ | 270° C. | 89% |
| | | | Ethyl acetate | |
| [Ir(L19)₂Cl]₂ | L19 | [Ir(L19)₂Cl]₂ | 270° C. | 93% |
| | | | MeO-t-Bu | |

2) Complexes of the Formula Ir(L)₂(L′) with Ligands L′ Containing O—O, O—N, N—N Donor Atoms

The crude chloro dimer of the formula [Ir(L)₂Cl]₂ obtained in 1) is suspended in a mixture of 75 ml of 2-ethoxyethanol and 25 ml of water, and 13 mmol of the ligand L′ and 15 mmol of sodium carbonate are added. After stirring under reflux for 20 h and exclusion of light, a further 75 ml of water are added dropwise, the mixture is cooled, the solid is filtered off with suction, washed three times with 50 ml of water each time and three times with 50 ml of methanol each time and dried in vacuo. The dry solid is placed on a Celite bed with a depth of 3-5 cm in a continuous hot extractor and then extracted with the extractant indicated (initially introduced amount about 300 ml, the extractant is selected so that the complex is readily soluble therein at elevated temperature and has low solubility therein at low temperature, particularly suitable extractants are hydrocarbons, such as toluene, xylenes, mesitylene, naphthalene, o-dichlorobenzene, acetone, ethyl acetate (EA), dichloromethane (DCM), etc.). When the extraction is complete, the extractant is evaporated to about 100 ml in vacuo. Metal complexes which have excessively good solubility in the extractant are brought to crystallisation by evaporation of the eluate to 50 ml and dropwise addition of 200 ml of methanol. The solid of the suspensions obtained in this way is filtered off with suction, washed once with about 50 ml of methanol and dried. After drying, the purity of the metal complex is determined by means of NMR and/or HPLC. If the purity is below 99.5%, the hot-extraction step is repeated; when a purity of 99.5-99.9% has been reached, the metal complex is heated or sublimed. Besides the hot-extraction method of purification, the purification can also be carried out by chromatography on silica gel or aluminium oxide using suitable eluents (see below). The heating is carried out in a high vacuum (p about 10⁻⁶ mbar) in the temperature range from about 200-300° C. The sublimation is carried out in a high vacuum (p about 10⁻⁶ mbar) in the temperature range from about 250-400° C., where the sublimation is preferably carried out in the form of a fractional sublimation.

| Ex. | [Ir(L)₂Cl]₂ | Co— ligand L′ | Ir(L)₂(L′) Purification method Extractant Eluent | Yield |
|---|---|---|---|---|
| [Ir(L1)₂(L′1) | [Ir(L1)₂Cl]₂ | 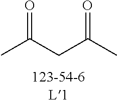 | 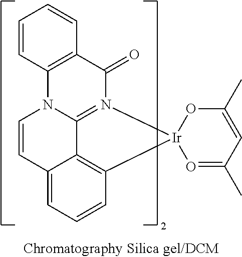 | 45% |
| [Ir(L12)₂(L′1) | [Ir(L12)₂Cl]₂ | L′1 | 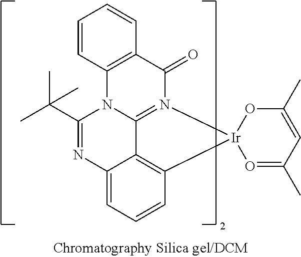 | 44% |
| [Ir(L15)₂(L′1) | [Ir(L15)₂Cl]₂ | L′1 | 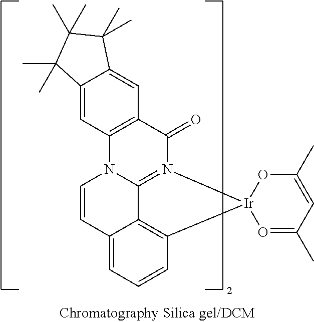 | 49% |
| [Ir(L11)₂(L′2) | [Ir(L11)₂Cl]₂ | 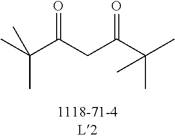 | 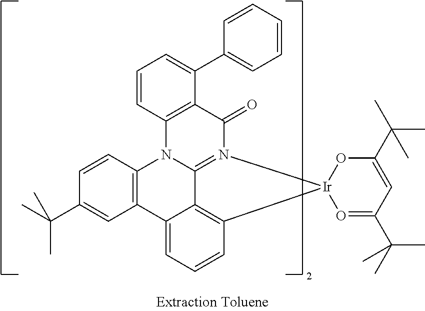 | 36% |
| [Ir(L7)₂(L′2) | [Ir(L7)₂Cl]₂ | L′2 | 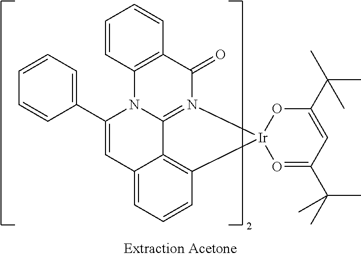 | 44% |
| [Ir(L8)₂(L′2) | [Ir(L8)₂Cl]₂ | L′2 | 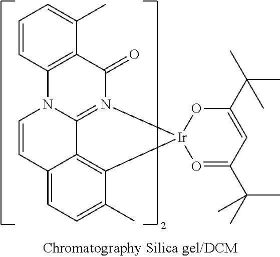 | 29% |
| [Ir(L13)₂(L′3) | [Ir(L13)₂Cl]₂ | 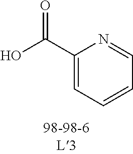 | 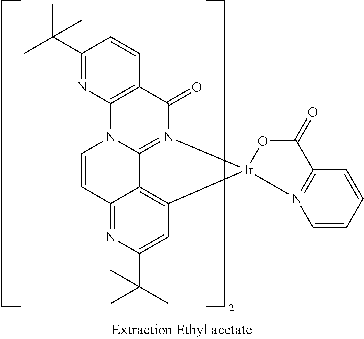 | 37% |
| [Ir(L5)₂(L′4) | [Ir(L5)₂Cl]₂ | 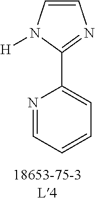 [SMILES: c1ccc(-c2ncc[nH]2)nc1] | 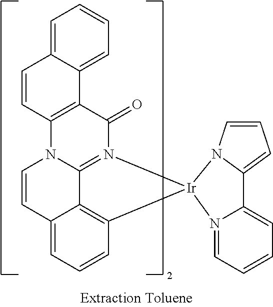 | 39% |
| [Ir(L16)₂(L′5) | [Ir(L16)₂Cl]₂ | 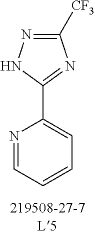 [SMILES: FC(F)(F)c1n[nH]c(-c2ccccn2)n1] | 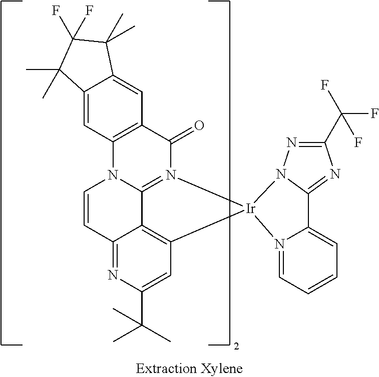 | 47% |

2) Heteroleptic Tris-Ortho-Metallated Complexes of the Formula Ir(L)₂(L′) and of the Formula Ir(L)(L′)₂from Ir(L)₂Cl]₂

The above-mentioned compounds are obtained by reaction of the crude chloro dimers of the formula [Ir(L)₂Cl]₂ with the ligands L′ in dipolar protic solvents (ethylene glycol, propylene glycol, glycerol, diethylene glycol, triethylene glycol, etc.). Mixtures are usually formed comprising both complex types of the formula Ir(L)₂(L′) and of the formula Ir(L)(L′)₂, which can be separated by chromatography. The relative amounts of the complex types of the formula Ir(L)₂(L′) and of the formula Ir(L)(L′)₂ can be controlled through the stoichiometric ratio of [Ir(L)₂Cl]₂ to co-ligand L′. Thus, in the case of a stoichiometric ratio of [Ir(L)₂Cl]₂ to L′ of 1:2 to about 1:6, the product of the formula Ir(L)₂(L′) is formed in the majority, whereas in the case of a stoichiometric ratio of [Ir(L)₂Cl]₂ to L′ of about 1:8 to about 1:25, the product of the formula Ir(L)(L′)₂ is formed in the majority.

The crude chloro dimer of the formula [Ir(L)₂Cl]₂ obtained in 1) is initially introduced in 100 ml of the solvent indicated. The reaction mixture is degassed by passing-through of a stream of inert gas (nitrogen or argon) with stirring. The indicated amount of ligand L′ is then added, and the mixture is stirred at 160° C. for 48 h with exclusion of light. After cooling to 70° C., 100 ml of ethanol are added dropwise, the mixture is allowed to cool with stirring, the precipitated solid is filtered off with suction, washed three times with 30 ml of ethanol each time and dried in vacuo. The complexes of the formula Ir(L)₂(L′) and of the formula Ir(L)(L′)₂ are isolated by chromatography, with the progress being monitored on TLC cards. Clean fractions are combined, evaporated virtually to dryness, during which the product frequently crystallises out. Ethanol is then added, the product is transferred onto a protective-gas frit with EtOH, washed a number of times with a little ethanol and dried in vacuo. If necessary, the product is rechromatographed until a purity >99.5% or more has been reached. The heating is carried out in a high vacuum (p about 10⁻⁶ mbar) in the temperature range from about 200-300° C. The sublimation is carried out in a high vacuum (p about 10⁻⁶ mbar) in the temperature range from about 250-400° C., where the sublimation is preferably carried out in the form of a fractional sublimation.

| | | | Ir(L)₂(L′) Ir(L)(L′)₂ Stoichiometry | |
|---|---|---|---|---|
| Ex. | [Ir(L)₂Cl]₂ | Co— ligand L′ | Solvent [Ir(L)2Cl]2:L′ Adsorbent/eluent | Yield |
| Ir(L1)₂(L′6) | [Ir(L1)₂Cl]₂ | 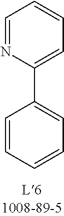 [SMILES: c1ccc(-c2ccccn2)cc1] | 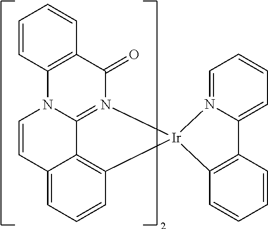 | 30% |
| Ir(L1)(L′6)₂ | | | 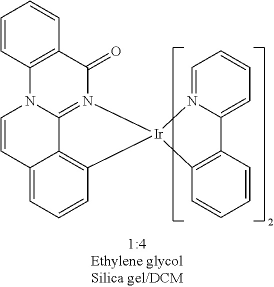 | 10% |
| Ir(L1)₂(L′6) | [Ir(L1)₂Cl]₂ | L′6 | 1:12 | 12% |
| Ir(L1)(L′6)₂ | | | Ethylene glycol | 38% |
| | | | Silica gel/DCM | |
| Ir(L1)₂(L′6) | [Ir(L1)₂Cl]₂ | L′6 | 1:25 | 6% |
| Ir(L1)(L′6)₂ | | | Ethylene glycol | 40% |
| | | | Silica gel/DCM | |
| Ir(L1)₂(L′7) Ir(L1)(L′7)₂ | [Ir(L1)₂Cl]₂ | 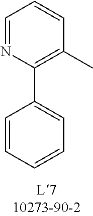 | 1:5 Ethylene glycol Silica gel/DCM | 37% 11% |
| Ir(L1)₂(L′7) | [Ir(L1)₂Cl]₂ | L′7 | 1:12 | 11% |
| Ir(L1)(L′7)₂ | | | Ethylene glycol | 41% |
| | | | Silica gel/DCM | |
| Ir(L1)₂(L′8) Ir(L1)(L′8)₂ | [Ir(L1)₂Cl]₂ | 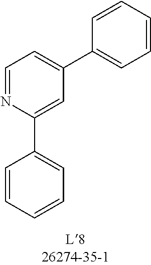 [SMILES: c1ccc(-c2ccnc(-c3ccccc3)c2)cc1] | 1:5 Ethylene glycol Silica gel/DCM | 39% 12% |
| Ir(L1)₂(L′8) | [Ir(L1)₂Cl]₂ | L′8 | 1:12 | 9% |
| Ir(L1)(L′8)₂ | | | Ethylene glycol | 44% |
| | | | Silica gel/DCM | |
| Ir(L2)₂(L′9) Ir(L2)(L′9)₂ | [Ir(L2)₂Cl]₂ | 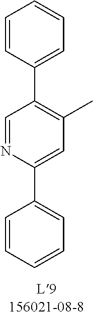 [SMILES: Cc1cc(-c2ccccc2)ncc1-c1ccccc1] | 1:8 Ethylene glycol Silica gel/DCM | 17% 31% |
| Ir(L3)₂(L′8) Ir(L3)(L′8)₂ | [Ir(L3)₂Cl]₂ | 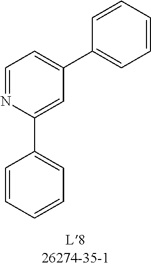 [SMILES: c1ccc(-c2ccnc(-c3ccccc3)c2)cc1] | 1:8 Ethylene glycol Silica gel/DCM | 18% 30% |
| Ir(L4)₂(L′10) Ir(L4)(L′10)₂ | [Ir(L4)₂Cl]₂ | 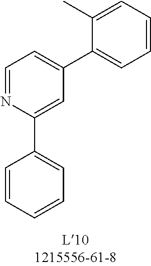 [SMILES: Cc1ccccc1-c1ccnc(-c2ccccc2)c1] | 1:12 Ethylene glycol Silica gel/DCM | 14% 41% |
| Ir(L5)₂(L′11) Ir(L5)(L′11)₂ | [Ir(L5)₂Cl]₂ | 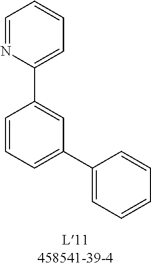 [SMILES: c1ccc(-c2cccc(-c3ccccn3)c2)cc1] | 1:12 Propylene glycol Silica gel EA/n-hexane 2/1 | 15% 33% |
| Ir(L6)₂(L′12) Ir(L6)(L′12)₂ | [Ir(L6)₂Cl]₂ | 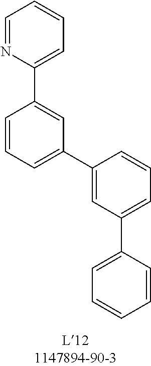 [SMILES: c1ccc(-c2cccc(-c3cccc(-c4ccccn4)c3)c2)cc1] | 1:12 Ethyelen glycol Silica gel/DCM | 14% 36% |
| Ir(L7)₂(L′13) Ir(L7)(L′13)₂ | [Ir(L7)₂Cl]₂ | 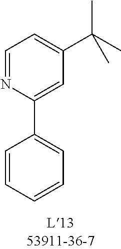 [SMILES: CC(C)(C)c1ccnc(-c2ccccc2)c1] | 1:6 Ethylene glycol Silica gel/DCM | 30% 17% |
| Ir(L8)₂(L′6) | [Ir(L8)₂Cl]₂ | L′6 | 1:12 | — |
| Ir(L8)(L′6)₂ | | | Ethylene glycol | 33% |
| | | | Silica gel/DCM | |
| Ir(L9)₂(L′14) Ir(L9)(L′14)₂ | [Ir(L9)₂Cl]₂ | 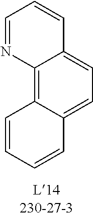 [SMILES: c1ccc2c(c1)ccc1cccnc12] | 1:5 Ethylene glycol/185° C. Silica gel/DCM | 18% 23% |
| Ir(L10)₂(L′15) Ir(L10)(L′15)₂ | [Ir(L10)₂Cl]₂ | 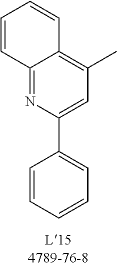 [SMILES: Cc1cc(-c2ccccc2)nc2ccccc12] | 1:12 Ethylene glycol Silica gel/DCM | 23% 31% |
| Ir(L11)₂(L′8) | [Ir(L11)₂Cl]₂ | L′8 | 1:12 | 16% |
| Ir(L11)(L′8)₂ | | | Ethylene glycol | 39% |
| | | | Silica gel/DCM | |
| Ir(L12)₂(L′16) Ir(L12)(L′16)₂ | [Ir(L12)₂Cl]₂ | 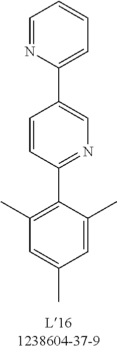 | 1:10 Ethylene glycol/185° C. Silica gel/DCM | 8% 25% |
| Ir(L13)₂(L′17) Ir(L13)(L′17)₂ | [Ir(L13)₂Cl]₂ | 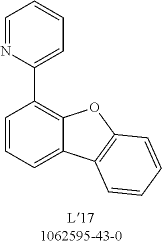 [SMILES: c1ccc(-c2cccc3c2oc2ccccc23)nc1] | 1:12 Ethylene glycol Silica gel/toluene | 15% 37% |
| Ir(L14)₂(L′8) | [Ir(L14)₂Cl]₂ | L′8 | 1:12 | 16% |
| Ir(L14)(L′8)₂ | | | Ethylene glycol | 40% |
| | | | Silica gel | |
| | | | DCM/n-hexane | |
| | | | 1/2 | |
| | | | Isol. as mixture of the diastereomers | |
| Ir(L15)₂(L′18) Ir(L15)(L′18)₂ | [Ir(L15)₂Cl]₂ | 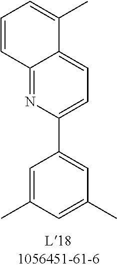 [SMILES: Cc1cc(C)cc(-c2ccc3c(C)cccc3n2)c1] | 1:10 Ethylene glycol/185° C. Silica gel/DCM | 15% 24% |
| Ir(L16)₂(L′19) Ir(L16)(L′19)₂ | [Ir(L16)₂Cl]₂ | 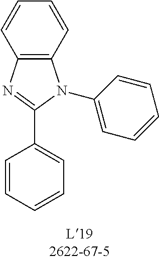 [SMILES: c1ccc(-c2nc3ccccc3n2-c2ccccc2)cc1] | 1:12 Ethylene glycol Silica gel/DCM | 17% 56% |
| Ir(L17)₂(L′20) Ir(L17)(L′20)₂ | [Ir(L17)₂Cl]₂ | 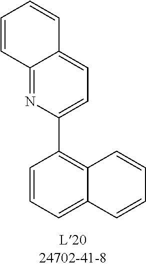 [SMILES: c1ccc2nc(-c3cccc4ccccc34)ccc2c1] | 1:12 Ethylene glycol Silica gel/DCM Isol. as mixture of the diastereomers | 15% 41% |
| Ir(L18)₂(L′21) Ir(L18)(L′21)₂ | [Ir(L18)₂Cl]₂ | 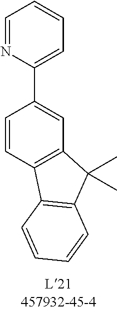 [SMILES: CC1(C)c2ccccc2-c2ccc(-c3ccccn3)cc21] | 1:12 Ethylene glycol Silica gel/DCM | 12% 38% |
| Ir(L19)₂(L′22) Ir(L19)(L′22)₂ | [Ir(L19)₂Cl]₂ | 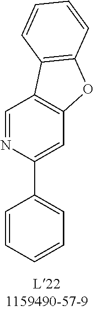 [SMILES: c1ccc(-c2cc3oc4ccccc4c3cn2)cc1] | 1:12 Ethylene glycol Silica gel/DCM Isol. as mixture of the diastereomers | 14% 40% |

3) Heteroleptic Tris-Ortho-Metallated Complexes of the Formula Ir(L)₂(L′) and of the formula Ir(L)(L′)₂ from [Ir(L′)₂(HOMe)₂]A or Ir(L′)₂(NCMe)₂]A

The above-mentioned compounds are obtained by reaction of the ligands L with iridium complexes of the formula [Ir(L′)₂(HOMe)₂]A or [Ir(L′)₂(NCMe)₂]A (A=non-coordinating anion, such as, for example, triflate, tetrafluoroborate, hexafluorophosphate, etc.) in dipolar protic solvents (ethylene glycol, propylene glycol, glycerol, diethylene glycol, triethylene glycol, etc.). In the case of a stoichiometric ratio of [Ir(L′)₂(HOMe)₂]A or [Ir(L′)₂(NCMe)₂]A to L of 1:1, predominantly the complexes of the formula Ir(L)(L′)₂ are obtained. In the case of a stoichiometric ratio of [Ir(L′)₂(HOMe)₂]A or [Ir(L′)₂(NCMe)₂]A to L of 1:2 or greater, essentially the complexes of the formula Ir(L)₂(L′) are formed, meaning that this method is highly suitable for the rearation of these complexes in good yield. The crude products comprising the two complex types of the formula Ir(L)₂(L′) and of the formula Ir(L)(L′)₂ can be separated by chromatography as described under 2) and thus purified.

10 mmol of [Ir(L′)₂(HOMe)₂]A or [Ir(L′)₂(NCMe)₂]A are initially introduced in an apparatus with water separator in 100 ml of degassed solvent (see table). The indicated amount of ligand L is then added (amount see table), and the mixture is stirred at 180° C. for 48 h with exclusion of light, during which a small amount of a colourless liquid, which, according to NMR analysis, comprises MeOH or MeCN and water and thermal decomposition products of the solvent, collects in the water separator. The suspension is allowed to cool to room temperature, the precipitated solid is filtered off with suction, washed three times with 20-30 ml of ethanol each time and dried in vacuo. The complexes of the formula Ir(L)₂(L′) and of the formula Ir(L)(L′)₂ are isolated by chromatography, with the progress being monitored on TLC cards. Clean fractions are combined, evaporated virtually to dryness, during which the product frequently crystallises out. Ethanol is then added, the product is transferred onto a protective-gas frit with EtOH, washed a number of times with a little ethanol and dried in vacuo. If necessary, the product is re-chromatographed until a purity >99.5% or more has been reached. The heating is carried out in a high vacuum (p about 10⁻⁶ mbar) in the temperature range from about 200-300° C. The sublimation is carried out in a high vacuum (p about 10⁻⁶ mbar) in the temperature range from about 250-400° C., where the sublimation is preferably carried out in the form of a fractional sublimation.

| | | | Ir(L)₂(L′) Ir(L)(L′)₂ | |
|---|---|---|---|---|
| | [Ir(L′)₂(HOMe)₂]A or | | Stoichiometry [Ir(L)₂Cl]₂:L′ | |
| Ex. | [Ir(L′)₂(NCMe)₂]A | Ligand L | Solvent Adsorbent/eluent | Yield |
| Ir(L1)₂(L′6) | [Ir(L′6)₂(NCMe)₂]OTf 153540-10-4 | 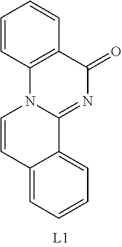 [SMILES: O=c1nc2c3ccccc3ccn2c2ccccc12] | 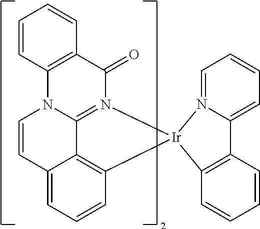 | 11% |
| Ir(L1)(L′6)₂ | | | 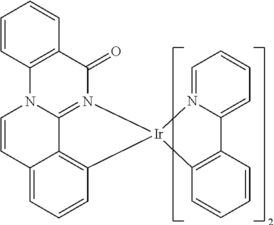 1:1 1,2-Propanediol Silica gel/DCM | 27% |
| Ir(L1)₂(L′6) | [Ir(L′6)₂(NCMe)₂]OTf | L1 | 1:2 | 37% |
| Ir(L1)(L′6)₂ | 153540-10-4 | | 1,2-Propanediol | 7% |
| | | | Silica gel/DCM | |
| Ir(L1)₂(L′6) | [Ir(L′6)₂(NCMe)₂]OTf | L1 | 1:4 | 46% |
| Ir(L1)(L′6)₂ | 153540-10-4 | | 1,2-Propanediol | 5% |
| | | | Silica gel/DCM | |
| Ir(L3)₂(L′23) | 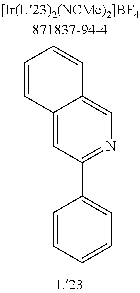 [SMILES: c1ccc(-c2cc3ccccc3cn2)cc1] | L3 | 1:3 1,2-Propanediol Silica gel/DCM | 42% |
| Ir(L3)₂(L′24) | 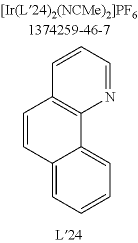 [SMILES: c1ccc2c(c1)ccc1cccnc12] | L8 | 1:3 1,2-Propanediol Silica gel DCM/EA 98/2 | 34% |
| Ir(L15)₂(L′25) | 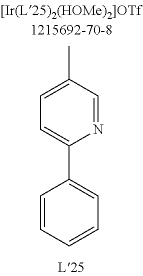 | L15 | 1:3 Ethylene glycol Silica gel DCM/THF 99/1 | 39% |

Production of OLEDs

1) Vacuum-Processed Devices

OLEDs according to the invention and OLEDs in accordance with the prior art are produced by a general process in accordance with WO 2004/058911, which is adapted to the circumstances described here (layer-thickness variation, materials used).

The results for various OLEDs are presented in the following examples. Glass plates with structured ITO (indium tin oxide) form the substrates to which the OLEDs are applied. The OLEDs have in principle the following layer structure: substrate/hole-injection layer 1 (HIL1) HAT-CN [105598-27-4], 5 nm/hole-transport layer 1 (HTL1), 75 nm/hole-transport layer 2 (HTL2), 10 nm/emission layer (EML)/electron-transport layer (ETL)/optional electron-injection layer (EIL) and finally a cathode. The cathode is formed by an aluminium layer with a thickness of 100 nm.

All materials are applied by thermal vapour deposition in a vacuum chamber. The emission layer here always consists of at least one matrix material (host material) and an emitting dopant (emitter), which is admixed with the matrix material or matrix materials in a certain proportion by volume by co-evaporation. An expression such as M1:M2:Ir complex (55%:35%:10%) here means that material M1 is present in the layer in a proportion by volume of 55%, M2 is present in the layer in a proportion of 35% and the Ir complex is present in the layer in a proportion of 10%. Analogously, the electron-transport layer may also consist of a mixture of two materials. The precise structure of the OLEDs is shown in Table 1. The materials used for the production of the OLEDs are shown in Table 6.

The OLEDs are characterised by standard methods. For this purpose, the electroluminescence spectra, the current efficiency (measured in cd/A), the external quantum efficiency (EQE in %) and the voltage (measured at 1000 cd/m² in V) are determined. In addition, the lifetime is determined. The lifetime is defined as the time after which the luminous density has dropped to a certain proportion from a certain initial luminous density. The expression LT80 means that the lifetime given is the time at which the luminous density has dropped to 80% of the initial luminous density, i.e. from, for example, 1000 cd/m² to 800 cd/m². The values for the lifetime can be converted to a figure for other initial luminous densities with the aid of conversion formulae known to the person skilled in the art.

Use of Compounds According to the Invention as Emitter Materials in Phosphorescent OLEDs

The compounds according to the invention can be employed, in particular, as phosphorescent emitter materials in the emission layer in OLEDs. The results for the OLEDs are summarised in Table 2.

TABLE 1
Structure of the OLEDs

| | EML | ETL | EIL |
|---|---|---|---|
| Ex. | Thickness | Thickness | Thickness |
| D-Ir(L1)₂(L′1) | M1:M2:Ir(L1)₂(L′1) | ETM1:ETM2 | — |
| | (45%:45%:10%) | (50%:50%) | |
| | 25 nm | 45 nm | |
| D-Ir(L12)₂(L′1) | M1:M2:Ir(L12)₂(L′1) | ETM1:ETM2 | ETM2 |
| | (45%:45%:10%) | (50%:50%) | 3 nm |
| | 25 nm | 45 nm | |
| D-Ir(L15)₂(L′1) | M1:M3:Ir(L15)₂(L′1) | ETM1:ETM2 | — |
| | (45%:50%:5%) | (50%:50%) | |
| | 25 nm | 45 nm | |
| D-Ir(L11)₂(L′2) | M1:M3:Ir(L11)₂(L′2) | ETM1:ETM2 | — |
| | (45%:50%:5%) | (50%:50%) | |
| | 25 nm | 45 nm | |
| D-Ir(L7)₂(L′2) | M1:Ir(L7)₂(L′2) | ETM1:ETM2 | — |
| | (80%:20%) | (50%:50%) | |
| | 25 nm | 45 nm | |
| D-Ir(L8)₂(L′2) | M1:M2:Ir(L8)₂(L′2) | ETM1:ETM2 | — |
| | (45%:45%:10%) | (50%:50%) | |
| | 25 nm | 45 nm | |
| D-Ir(L13)₂(L′3) | M1:M2:Ir(L13)₂(L′3) | ETM1:ETM2 | — |
| | (55%:35%:10%) | (50%:50%) | |
| | 25 nm | 45 nm | |
| D-Ir(L5)₂(L′4) | M1:M2:Ir(L5)₂(L′4) | ETM1:ETM2 | — |
| | (35%:58%:7%) | (50%:50%) | |
| | 25 nm | 45 nm | |
| D-Ir(L16)₂(L′5) | M1:M3:Ir(L16)₂(L′5) | ETM1 | ETM2 |
| | (20%:65%:15%) | 45 nm | 3 nm |
| | 25 nm | | |
| D-Ir(L1)₂(L′6) | M1:M3:Ir(L1)₂(L′6) | ETM1:ETM2 | — |
| | (45%:45%:10%) | (50%:50%) | |
| | 25 nm | 45 nm | |
| D-Ir(L1)(L′6)₂ | M1:M2:Ir(L1)(L′6)₂ | ETM3 | EIM1 |
| | (30%:60%:10%) | 45 nm | 1 nm |
| | 25 nm | | |
| D-Ir(L1)₂(L′7) | M1:M4:Ir(L1)₂(L′7) | ETM1:ETM2 | — |
| | (60%:30%:10%) | (50%:50%) | |
| | 25 nm | 45 nm | |
| D-Ir(L1)(L′7)₂ | M1:M2:Ir(L1)(L′7)₂ | ETM1:ETM2 | — |
| | (45%:45%:10%) | (50%:50%) | |
| | 25 nm | 45 nm | |
| D-Ir(L1)₂(L′8) | M1:M3:Ir(L1)₂(L′6) | ETM1:ETM2 | — |
| | (45%:45%:10%) | (50%:50%) | |
| | 25 nm | 45 nm | |
| D-Ir(L1)(L′8)₂ | M1:M2:Ir(L1)(L′8)₂ | ETM1:ETM2 | — |
| | (50%:40%:10%) | (50%:50%) | |
| | 25 nm | 45 nm | |
| D-Ir(L2)₂(L′9) | M1:M3:Ir(L1)₂(L′6) | ETM1:ETM2 | — |
| | (45%:47%:8%) | (50%:50%) | |
| | 25 nm | 45 nm | |
| D-Ir(L2)(L′9)₂ | M1:M2:Ir(L2)(L′9)₂ | ETM1:ETM2 | — |
| | (30%:60%:10%) | (50%:50%) | |
| | 25 nm | 45 nm | |
| D-Ir(L4)₂(L′10) | M1:M3:Ir(L4)₂(L′10) | ETM1:ETM2 | — |
| | (45%:45%:10%) | (50%:50%) | |
| | 25 nm | 45 nm | |
| D-Ir(L4)(L′10)₂ | M1:M2:Ir(L4)(L′10)₂ | ETM1:ETM2 | — |
| | (30%:60%:10%) | (50%:50%) | |
| | 25 nm | 45 nm | |
| D-Ir(L5)₂(L′11) | M1:M3:Ir(L5)₂(L′11) | ETM1:ETM2 | — |
| | (45%:45%:10%) | (50%:50%) | |
| | 25 nm | 45 nm | |
| D-Ir(L5)(L′11)₂ | M1:M2:Ir(L5)(L′11)₂ | ETM1:ETM2 | — |
| | (45%:45%:10%) | (50%:50%) | |
| | 25 nm | 45 nm | |
| D-Ir(L6)₂(L′12) | M1:M4:Ir(L6)₂(L′12) | ETM1:ETM2 | — |
| | (60%:25%:15%) | (50%:50%) | |
| | 25 nm | 45 nm | |
| D-Ir(L6)(L′12)₂ | M1:M2:Ir(L6)(L′12)₂ | ETM1:ETM2 | — |
| | (35%:55%:10%) | (50%:50%) | |
| | 25 nm | 45 nm | |
| D-Ir(L7)₂(L′13) | M1:M3:Ir(L7)₂(L′13) | ETM1:ETM2 | — |
| | (45%:45%:10%) | (50%:50%) | |
| | 25 nm | 45 nm | |
| D-Ir(L7)(L′13)₂ | M1:M2:Ir(L7)(L′13)₂ | ETM1:ETM2 | — |
| | (45%:45%:10%) | (50%:50%) | |
| | 25 nm | 45 nm | |
| D-Ir(L8)₂(L′6) | M1:M3:Ir(L8)₂(L′6) | ETM1:ETM2 | — |
| | (45%:45%:10%) | (50%:50%) | |
| | 25 nm | 45 nm | |
| D-Ir(L8)(L′6)₂ | M1:M2:Ir(L8)(L′6)₂ | ETM1:ETM2 | — |
| | (45%:45%:10%) | (50%:50%) | |
| | 25 nm | 45 nm | |
| D-Ir(L9)₂(L′14) | M1:M3:Ir(L9)₂(L′14) | ETM1:ETM2 | — |
| | (65%:25%:10%) | (50%:50%) | |
| | 25 nm | 45 nm | |
| D-Ir(L9)(L′14)₂ | M1:M2:Ir(L9)(L′14)₂ | ETM1:ETM2 | — |
| | (35%:55%:10%) | (50%:50%) | |
| | 25 nm | 45 nm | |
| D-Ir(L10)₂(L′15) | M1:M3:Ir(L10)₂(L′15) | ETM1:ETM2 | — |
| | (45%:45%:10%) | (50%:50%) | |
| | 25 nm | 45 nm | |
| D-Ir(L10)(L′15)₂ | M1:M2:Ir(L10)(L′15)₂ | ETM1:ETM2 | — |
| | (45%:45%:10%) | (50%:50%) | |
| | 25 nm | 45 nm | |
| D-Ir(L11)₂(L′8) | M1:M3:Ir(L11)₂(L′8) | ETM1:ETM2 | — |
| | (45%:45%:10%) | (50%:50%) | |
| | 25 nm | 45 nm | |
| D-Ir(L11)(L′8)₂ | M1:M2:Ir(L11)(L′8)₂ | ETM1:ETM2 | — |
| | (45%:45%:10%) | (50%:50%) | |
| | 25 nm | 45 nm | |
| D-Ir(L12)₂(L′16) | M1:M3:Ir(L12)₂(L′16) | ETM1:ETM2 | — |
| | (65%:25%:10%) | (50%:50%) | |
| | 25 nm | 45 nm | |
| D-Ir(L12)(L′16)₂ | M1:M2:Ir(L12)(L′16)₂ | ETM1:ETM2 | — |
| | (55%:35%:10%) | (50%:50%) | |
| | 25 nm | 45 nm | |
| D-Ir(L13)₂(L′17) | M1:M3:Ir(L13)₂(L′17) | ETM1:ETM2 | — |
| | (45%:45%:10%) | (50%:50%) | |
| | 25 nm | 45 nm | |
| D-Ir(L13)(L′17)₂ | M1:M2:Ir(L13)(L′17)₂ | ETM1:ETM2 | — |
| | (45%:45%:10%) | (50%:50%) | |
| | 25 nm | 45 nm | |
| D-Ir(L14)₂(L′8) | M1:M3:Ir(L14)₂(L′8) | ETM1:ETM2 | — |
| | (45%:45%:10%) | (50%:50%) | |
| | 25 nm | 45 nm | |
| D-Ir(L14)(L′8)₂ | M1:M2:Ir(L14)(L′8)₂ | ETM1:ETM2 | — |
| | (40%:50%:10%) | (50%:50%) | |
| | 25 nm | 45 nm | |
| D-Ir(L15)₂(L′18) | M1:M3:Ir(L15)₂(L′18) | ETM1:ETM2 | — |
| | (65%:25%:10%) | (50%:50%) | |
| | 25 nm | 45 nm | |
| D-Ir(L15)(L′18)₂ | M1:M2:Ir(L15)(L′18)₂ | ETM1:ETM2 | — |
| | (55%:35%:10%) | (50%:50%) | |
| | 25 nm | 45 nm | |
| D-Ir(L16)₂(L′19) | M1:M4:Ir(L16)₂(L′19) | ETM1:ETM2 | — |
| | (60%:30%:10%) | (50%:50%) | |
| | 25 nm | 45 nm | |
| D-Ir(L16)(L′19)₂ | M1:M2:Ir(L16)(L′19)₂ | ETM1:ETM2 | — |
| | (45%:45%:10%) | (50%:50%) | |
| | 25 nm | 45 nm | |
| D-Ir(L17)₂(L′20) | M1:M3:Ir(L17)₂(L′20) | ETM1:ETM2 | — |
| | (45%:45%:10%) | (50%:50%) | |
| | 25 nm | 45 nm | |
| D-Ir(L17)(L′20)₂ | M1:M2:Ir(L17)(L′20)₂ | ETM1:ETM2 | — |
| | (45%:45%:10%) | (50%:50%) | |
| | 25 nm | 45 nm | |
| D-Ir(L18)₂(L′21) | M1:M3:Ir(L18)₂(L′21) | ETM1:ETM2 | — |
| | (65%:25%:10%) | (50%:50%) | |
| | 25 nm | 45 nm | |
| D-Ir(L18)(L′21)₂ | M1:M2:Ir(L18)(L′21)₂ | ETM1:ETM2 | — |
| | (40%:50%:10%) | (50%:50%) | |
| | 25 nm | 45 nm | |
| D-Ir(L19)₂(L′22) | M1:M4:Ir(L19)₂(L′22) | ETM1:ETM2 | — |
| | (60%:30%:10%) | (50%:50%) | |
| | 25 nm | 45 nm | |
| D-Ir(L19)(L′22)₂ | M1:M2:Ir(L19)(L′22)₂ | ETM1:ETM2 | — |
| | (45%:45%:10%) | (50%:50%) | |
| | 25 nm | 45 nm | |
| D-Ir(L3)₂(L′23) | M1:M3:Ir(L3)₂(L′23) | ETM1:ETM2 | — |
| | (45%:45%:10%) | (50%:50%) | |
| | 25 nm | 45 nm | |
| D-Ir(L3)₂(L′24) | M1:M3:Ir(L3)₂(L′24) | ETM1:ETM2 | — |
| | (45%:45%:10%) | (50%:50%) | |
| | 25 nm | 45 nm | |
| D-Ir(L15)₂(L′25) | M1:M4:Ir(L15)₂(L′25) | ETM1:ETM2 | |
| | (60%:30%:10%) | (50%:50%) | |
| | 25 nm | 45 nm | |

TABLE 2
Results for the vacuum-processed OLEDs

| | EQE (%) | Voltage (V) | CIE x/y | LT80 (h) |
|---|---|---|---|---|
| Ex. | 1000 cd/m² | 1000 cd/m² | 1000 cd/m² | 1000 cd/m² |
| D-Ir(L1)₂(L′1) | 19.9 | 2.8 | 0.46/0.53 | 60000 |
| D-Ir(L12)₂(L′1) | 21.0 | 3.0 | 0.38/0.60 | 65000 |
| D-Ir(L15)₂(L′1) | 21.4 | 2.6 | 0.48/0.55 | 70000 |
| D-Ir(L11)₂(L′2) | 23.1 | 2.7 | 0.47/0.52 | 55000 |
| D-Ir(L7)₂(L′2) | 20.7 | 2.9 | 0.46/0.53 | 60000 |
| D-Ir(L8)₂(L′2) | 21.8 | 2.8 | 0.48/0.55 | 60000 |
| D-Ir(L13)₂(L′3) | 23.0 | 2.6 | 0.36/0.63 | 45000 |
| D-Ir(L5)₂(L′4) | 22.6 | 2.7 | 0.52/0.46 | 70000 |
| D-Ir(L16)₂(L′5) | 20.5 | 2.7 | 0.37/0.62 | 18000 |
| D-Ir(L1)₂(L′6) | 20.5 | 2.8 | 0.42/0.57 | 190000 |
| D-Ir(L1)(L′6)₂ | 21.8 | 2.7 | 0.44/0.55 | 220000 |
| D-Ir(L1)₂(L′7) | 22.0 | 2.6 | 0.45/0.53 | 210000 |
| D-Ir(L1)(L′7)₂ | 23.7 | 2.9 | 0.46/0.51 | 240000 |
| D-Ir(L1)₂(L′8) | 23.4 | 2.8 | 0.46/0.51 | 230000 |
| D-Ir(L1)(L′8)₂ | 22.8 | 2.8 | 0.51/0.48 | 250000 |
| D-Ir(L2)₂(L′9) | 23.0 | 2.7 | 0.41/0.58 | 230000 |
| D-Ir(L2)(L′9)₂ | 21.6 | 2.6 | 0.42/0.56 | 240000 |
| D-Ir(L4)₂(L′10) | 20.3 | 2.9 | 0.48/0.51 | 230000 |
| D-Ir(L4)(L′10)₂ | 21.0 | 2.7 | 0.51/0.48 | 250000 |
| D-Ir(L5)₂(L′11) | 21.1 | 2.6 | 0.56/0.42 | 240000 |
| D-Ir(L5)(L′11)₂ | 22.5 | 2.9 | 0.57/0.42 | 260000 |
| D-Ir(L7)₂(L′13) | 23.5 | 2.7 | 0.42/0.57 | 200000 |
| D-Ir(L7)(L′13)₂ | 22.9 | 2.7 | 0.44/0.55 | 210000 |
| D-Ir(L8)₂(L′6) | 21.3 | 2.6 | 0.42/0.56 | 250000 |
| D-Ir(L8)(L′6)₂ | 22.1 | 2.8 | 0.44/0.54 | 240000 |
| D-Ir(L9)₂(L′14) | 23.2 | 2.9 | 0.42/0.56 | 150000 |
| D-Ir(L9)(L′14)₂ | 22.4 | 2.7 | 0.43/0.57 | 160000 |
| D-Ir(L10)₂(L′15) | 22.6 | 2.7 | 0.59/0.40 | 230000 |
| D-Ir(L10)(L′15)₂ | 23.0 | 2.6 | 0.60/0.38 | 250000 |
| D-Ir(L11)₂(L′8) | 23.1 | 2.6 | 0.57/0.41 | 250000 |
| D-Ir(L11)(L′8)₂ | 21.8 | 2.7 | 0.58/0.41 | 250000 |
| D-Ir(L12)₂(L′16) | 22.2 | 2.6 | 0.41/0.58 | 190000 |
| D-Ir(L12)(L′16)₂ | 23.3 | 2.9 | 0.42/0.57 | 230000 |
| D-Ir(L13)₂(L′17) | 20.4 | 2.8 | 0.40/0.58 | 200000 |
| D-Ir(L13)(L′17)₂ | 20.8 | 2.9 | 0.41/0.58 | 210000 |
| D-Ir(L14)₂(L′8) | 23.1 | 2.8 | 0.45/0.54 | 250000 |
| D-Ir(L14)(L′8)₂ | 23.4 | 2.8 | 0.47/0.52 | 270000 |
| D-Ir(L15)₂(L′18) | 21.5 | 2.9 | 0.59/0.38 | 260000 |
| D-Ir(L15)(L′18)₂ | 21.3 | 2.7 | 0.60/0.39 | 260000 |
| D-Ir(L16)₂(L′19) | 21.6 | 2.8 | 0.38/0.60 | 200000 |
| D-Ir(L16)(L′19)₂ | 21.7 | 2.9 | 0.39/0.59 | 210000 |
| D-Ir(L17)₂(L′20) | 21.6 | 2.7 | 0.58/0.40 | 220000 |
| D-Ir(L17)(L′20)₂ | 21.3 | 2.6 | 0.60/0.38 | 240000 |
| D-Ir(L18)₂(L′21) | 22.5 | 2.6 | 0.40/0.58 | 190000 |
| D-Ir(L18)(L′21)₂ | 23.6 | 2.6 | 0.41/0.57 | 200000 |
| D-Ir(L19)₂(L′22) | 21.2 | 2.8 | 0.43/0.56 | 230000 |
| D-Ir(L19)(L′22)₂ | 21.5 | 2.9 | 0.44/0.54 | 230000 |
| D-Ir(L3)₂(L′23) | 22.1 | 2.7 | 0.59/0.38 | 270000 |
| D-Ir(L3)₂(L′24) | 21.9 | 2.8 | 0.55/0.43 | 280000 |
| D-Ir(L15)₂(L′25) | 21.4 | 2.6 | 0.44/0.55 | 250000 |

2) Solution-Processed Devices

A: From Soluble Functional Materials

The iridium complexes according to the invention can also be processed from solution, where they result in OLEDs which are significantly simpler as far as the process is concerned, compared with the vacuum-processed OLEDs, with nevertheless good properties. The production of components of this type is based on the production of polymeric light-emitting diodes (PLEDs), which has already been described many times in the literature (for example in WO 2004/037887). The structure is composed of substrate/ITO/PEDOT (80 nm)/interlayer (80 nm)/emission layer (80 nm)/cathode. To this end, use is made of substrates from Technoprint (soda-lime glass), to which the ITO structure (indium tin oxide) is applied as anode. The substrates are cleaned with DI water and a detergent (Deconex 15 PF) in a clean room and then activated by a UV/ozone plasma treatment. An 80 nm layer of PEDOT (PEDOT is a polythiophene derivative (Baytron P VAI 4083sp.) from H. C. Starck, Goslar, which is supplied as an aqueous dispersion) is then applied as buffer layer by spin coating, likewise in the clean room. The spin rate required depends on the degree of dilution and the specific spin coater geometry (typically for 80 nm: 4500 rpm). In order to remove residual water from the layer, the substrates are dried by heating on a hotplate at 180° C. for 10 minutes. The interlayer used serves for hole injection, in this case HIL-012 from Merck is used. The interlayer may alternatively also be replaced by one or more layers, which merely have to satisfy the condition of not being detached again by the subsequent processing step of EML deposition from solution. In order to produce the emission layer, the emitters according to the invention are dissolved in toluene together with the matrix materials. The typical solids content of such solutions is between 16 and 25 g/l if, as here, the typical layer thickness of 80 nm for a device is to be achieved by means of spin coating. The solution-processed devices comprise an emission layer comprising (polystyrene):M5:M6:Ir complex (35%:25%:30%:10%). The emission layer is applied by spin coating in an inert-gas atmosphere, in the present case argon, and dried by heating at 130° C. for 30 min. Finally, a cathode is applied by vapour deposition of barium (5 nm) and then aluminium (100 nm) (high-purity metals from Aldrich, particularly barium 99.99% (Order No. 474711); vapour-deposition equipment from Lesker, inter alia, typical vapour-deposition pressure 5×10⁻⁶ mbar). Optionally, firstly a hole-blocking layer and then an electron-transport layer and only then the cathode (for example Al or LiF/Al) can be applied by vacuum vapour deposition. In order to protect the device against air and atmospheric moisture, the device is finally encapsulated and then characterised. Table 3 summarises the data obtained.

TABLE 3
Results with materials processed from solution

| | | EQE (%) | Voltage (V) | CIE x/y |
|---|---|---|---|---|
| Ex. | Ir complex | 1000 cd/m² | 1000 cd/m² | 1000 cd/m² |
| L-Ir(L6)₂(L′12) | Ir(L6)₂(L′12) | 20.6 | 3.3 | 0.45/0.53 |
| L-Ir(L6)(L′12)₂ | Ir(L6)(L′12)₂ | 20.9 | 3.5 | 0.47/0.51 |

3) White-Emitting OLEDs

A white-emitting OLED having the following layer structure is produced in accordance with the general process from 1):

TABLE 4
Structure of the white OLEDs

| | | EML | EML | EML | | |
|---|---|---|---|---|---|---|
| | HTL2 | Red-orange | Blue | Green | HBL | ETL |
| Ex. | Thickness | Thickness | Thickness | Thickness | Thickness | Thickness |
| D-W1 | HTM2 | HTM2 | M1:M3:Ir-B | M3:Ir-G | M3 | ETM1:ETM2 |
| | 230 nm | Ir(L3)₂(L′23) | (45%:50%:5%) | (90%:10%) | 10 nm | (50%:50%) |
| | | (97%:3%) | 8 nm | 7 nm | | 30 nm |
| | | 10 nm | | | | |

TABLE 5
Device results

| | | | CIE x/y | LT50 |
|---|---|---|---|---|
| | EQE (%) | Voltage (V) | 1000 cd/m² | (h) |
| Ex. | 1000 cd/m² | 1000 cd/m² | CRI | 1000 cd/m² |
| D-W1 | 21.4 | 6.0 | 0.44/0.44 | 3200 |
| | | | 80 | |

TABLE 6
Structural formulae of the materials used

| | |
|---|---|
| 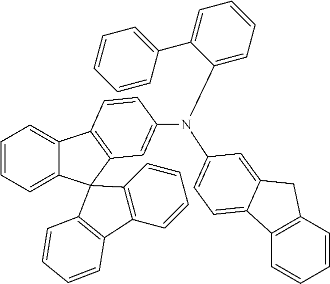 [SMILES: c1ccc(-c2ccccc2N(c2ccc3c(c2)Cc2ccccc2-3)c2ccc3c(c2)C2(c4ccccc4-c4ccccc42)c2ccccc2-3)cc1] | HTM1 |
| 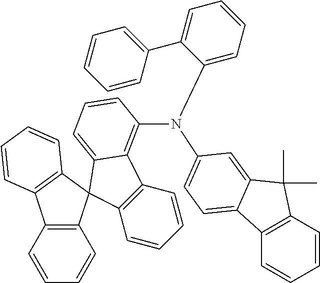 [SMILES: CC1(C)c2ccccc2-c2ccc(N(c3ccccc3-c3ccccc3)c3cccc4c3-c3ccccc3C43c4ccccc4-c4ccccc43)cc21] | HTM2 |
| 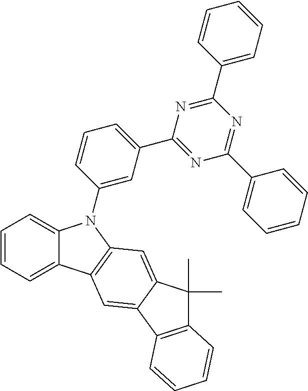 [SMILES: CC1(C)c2ccccc2-c2cc3c4ccccc4n(-c4cccc(-c5nc(-c6ccccc6)nc(-c6ccccc6)n5)c4)c3cc21] | M1 |
| 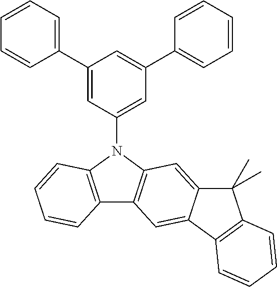 [SMILES: CC1(C)c2ccccc2-c2cc3c4ccccc4n(-c4cc(-c5ccccc5)cc(-c5ccccc5)c4)c3cc21] | M2 |
| 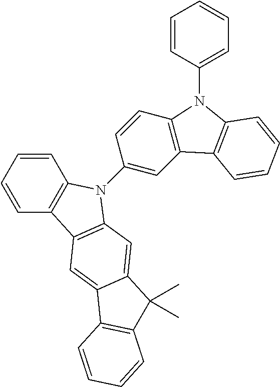 [SMILES: CC1(C)c2ccccc2-c2cc3c4ccccc4n(-c4ccc5c(c4)c4ccccc4n5-c4ccccc4)c3cc21] | M3 |
| 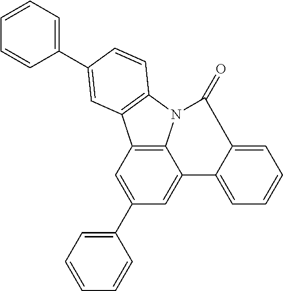 [SMILES: O=c1c2ccccc2c2cc(-c3ccccc3)cc3c4cc(-c5ccccc5)ccc4n1c23] | M4 |
| 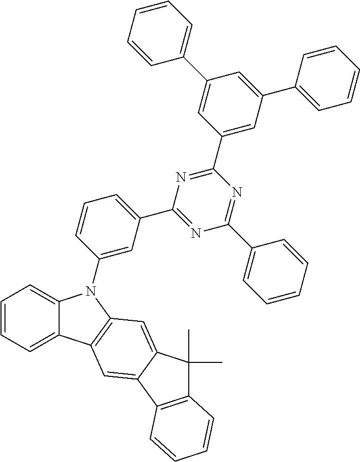 [SMILES: CC1(C)c2ccccc2-c2cc3c4ccccc4n(-c4cccc(-c5nc(-c6ccccc6)nc(-c6cc(-c7ccccc7)cc(-c7ccccc7)c6)n5)c4)c3cc21] | M5 |
| 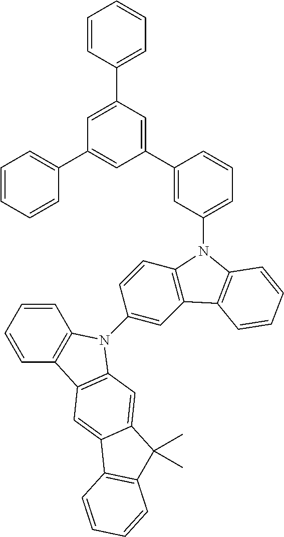 [SMILES: CC1(C)c2ccccc2-c2cc3c4ccccc4n(-c4ccc5c(c4)c4ccccc4n5-c4cccc(-c5cc(-c6ccccc6)cc(-c6ccccc6)c5)c4)c3cc21] | M6 |
| 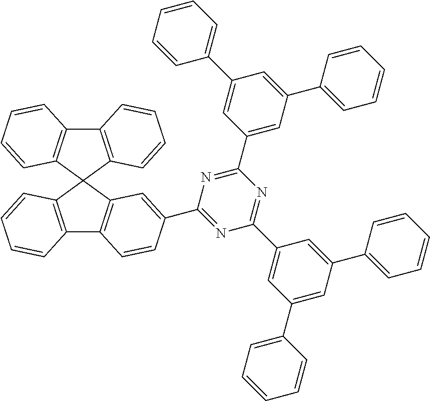 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1] | ETM1 |
| 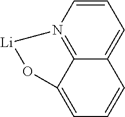 | ETM2 |
| 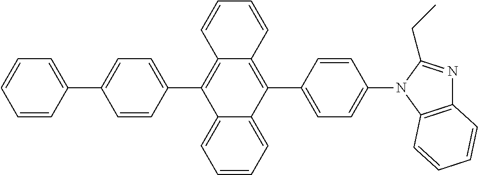 [SMILES: CCc1nc2ccccc2n1-c1ccc(-c2c3ccccc3c(-c3ccc(-c4ccccc4)cc3)c3ccccc23)cc1] | ETM3 |
| LiF | EIM1 |
| 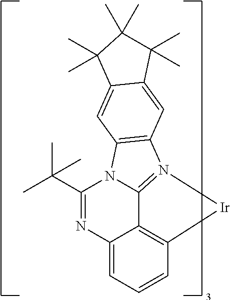 | Ir-B |
| 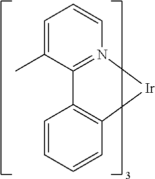 | Ir-G |

1-14. (canceled)

15. A compound of formula (1):
[Ir(L)ₙ(L′)ₘ] (1)
comprising a moiety Ir(L)ₙ of formula (2): 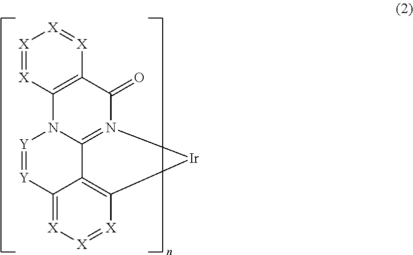
wherein
X is on each occurrence, identically or differently, CR or N, with the proviso that a maximum of two X per ligand is N;
Y is on each occurrence, identically or differently, CR or N, with the proviso that a maximum of one Y is N, or wherein the two Y together are a group of formula (3): 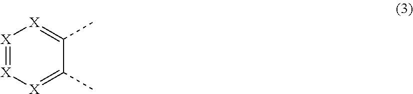
wherein the dashed bonds denote the linking of this group in the ligand;
R is on each occurrence, identically or differently, H, D, F, Cl, Br, I, N(R¹)₂, CN, Si(R¹)₃, B(OR¹)₂, C(═O)R¹, a straight-chain alkyl, alkoxy, or thioalkoxy group having 1 to 40 C atoms or a straight-chain alkenyl or alkynyl group having 2 to 40 C atoms or a branched or cyclic alkyl, alkenyl, alkynyl, alkoxy, or thioalkoxy group having 3 to 40 C atoms, each of which is optionally substituted by one or more radicals R¹, wherein one or more non-adjacent CH₂ groups are optionally replaced by R¹C═CR¹, Si(R¹)₂, C═O, NR¹, O, S, or CONR¹, and wherein one or more H atoms are optionally replaced by D, F, or CN, an aromatic or heteroaromatic ring system having 5 to 60 aromatic ring atoms optionally substituted by one or more radicals R¹, an aryloxy or heteroaryloxy group having 5 to 60 aromatic ring atoms optionally substituted by one or more radicals R¹, or a diarylamino group, diheteroarylamino group, or arylheteroarylamino group having 10 to 40 aromatic ring atoms optionally substituted by one or more radicals R¹; and wherein two or more adjacent radicals R optionally define a mono- or polycyclic, aliphatic, aromatic, and/or benzo-fused ring system with one another;
R¹ is on each occurrence, identically or differently, H, D, F, N(R²)₂, CN, Si(R²)₃, B(OR²)₂, C(═O)R², a straight-chain alkyl, alkoxy, or thioalkoxy group having 1 to 40 C atoms or a straight-chain alkenyl or alkynyl group having 2 to 40 C atoms or a branched or cyclic alkyl, alkenyl, alkynyl, alkoxy, or thioalkoxy group having 3 to 40 C atoms, each of which is optionally substituted by one or more radicals R², wherein one or more non-adjacent CH₂ groups are optionally replaced by R²C═CR², Si(R²)₂, C═O, NR², O, S, or CONR², and wherein one or more H atoms are optionally replaced by D, F, or CN, an aromatic or heteroaromatic ring system having 5 to 60 aromatic ring atoms optionally substituted by one or more radicals R², an aryloxy or heteroaryloxy group having 5 to 60 aromatic ring atoms optionally substituted by one or more radicals R², or a diarylamino group, diheteroarylamino group, or arylheteroarylamino group having 10 to 40 aromatic ring atoms optionally substituted by one or more radicals R²; and wherein two or more adjacent radicals R¹ optionally define a mono- or polycyclic, aliphatic ring system with one another;
R² is on each occurrence, identically or differently, H, D, F, or an aliphatic, aromatic and/or heteroaromatic organic radical having 1 to 20 C atoms, wherein one or more H atoms are optionally replaced by D or F; and wherein two or more substituents R² optionally define a mono- or polycyclic, aliphatic or aromatic ring system with one another;
L′ is, identically or differently on each occurrence, a monoanionic bidentate ligand which is different from L and whose coordinating atoms are selected, identically or differently on each occurrence, from the group consisting of C, N, O, and S;
n is 1 or 2;
m is 1 or 2;
wherein n+m=3.

16. The compound of claim 15, wherein R² is a hydrocarbon radical, wherein one or more H atoms are optionally replaced by D or F.

17. The compound of claim 15, wherein 0, 1, or 2 of X and Y in ligand L is N.

18. The compound of claim 17, wherein 0 or 1 of X and Y in ligand L is N.

19. The compound of claim 15, wherein the moiety Ir(L)ₙ of formula (2) is selected from the group consisting of the structures of formulae (4) to (24):

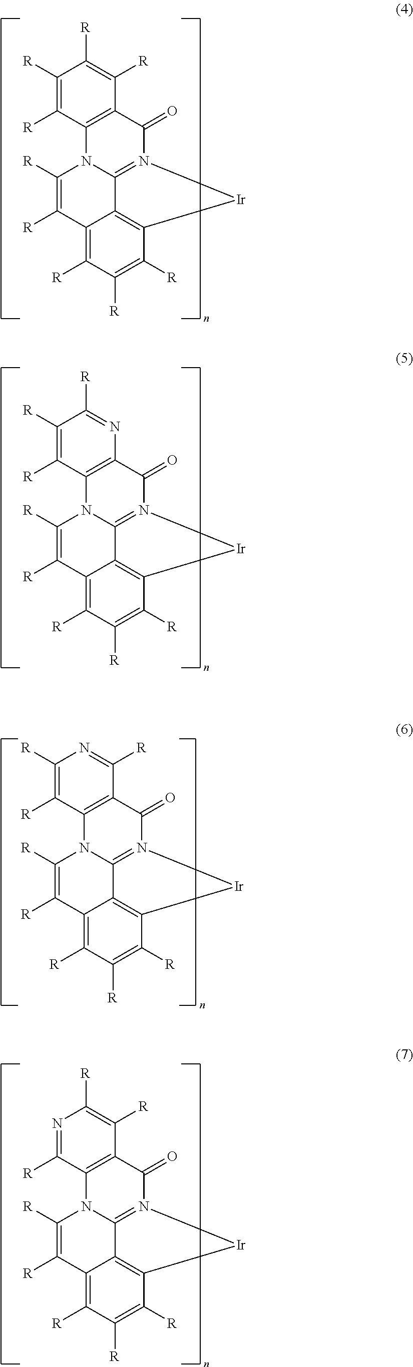

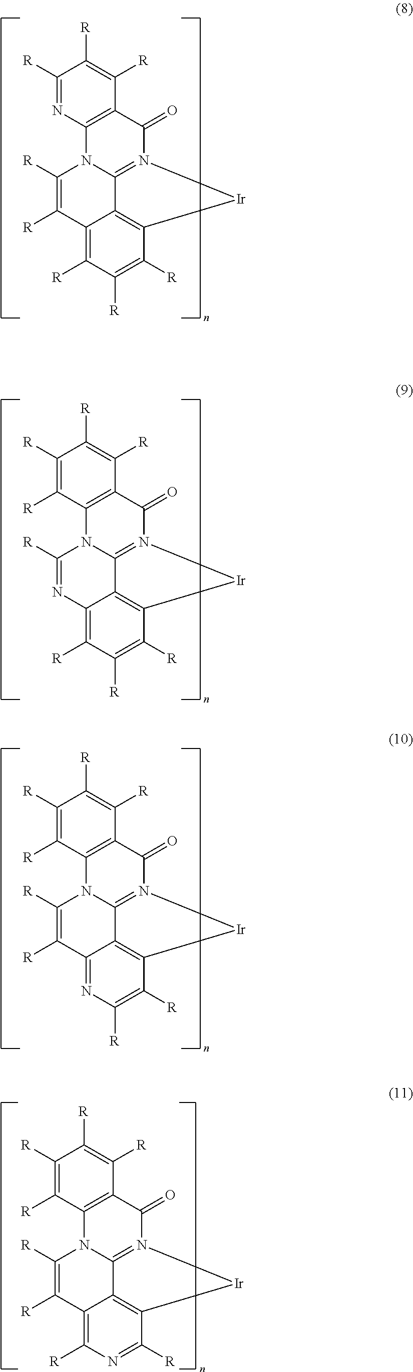

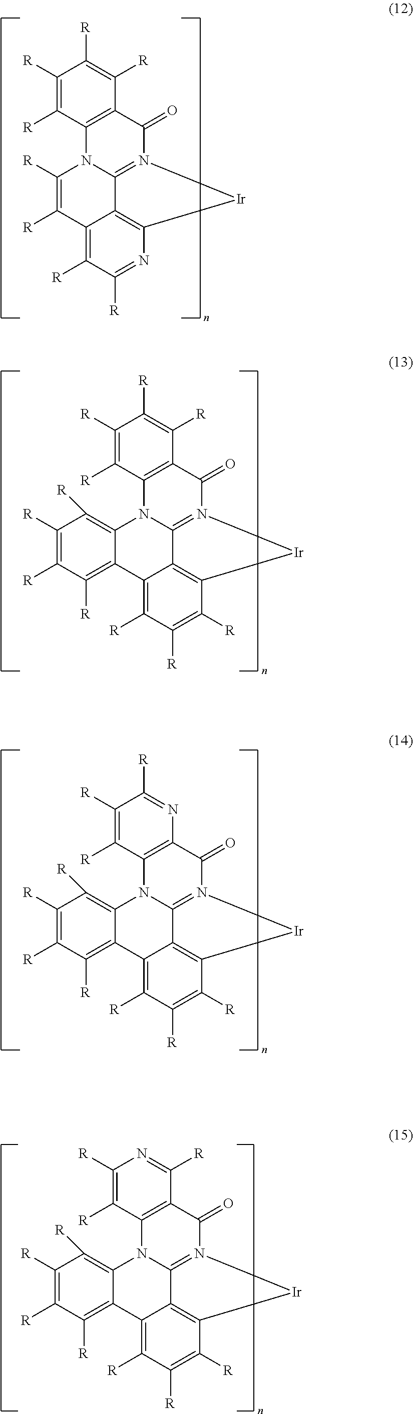

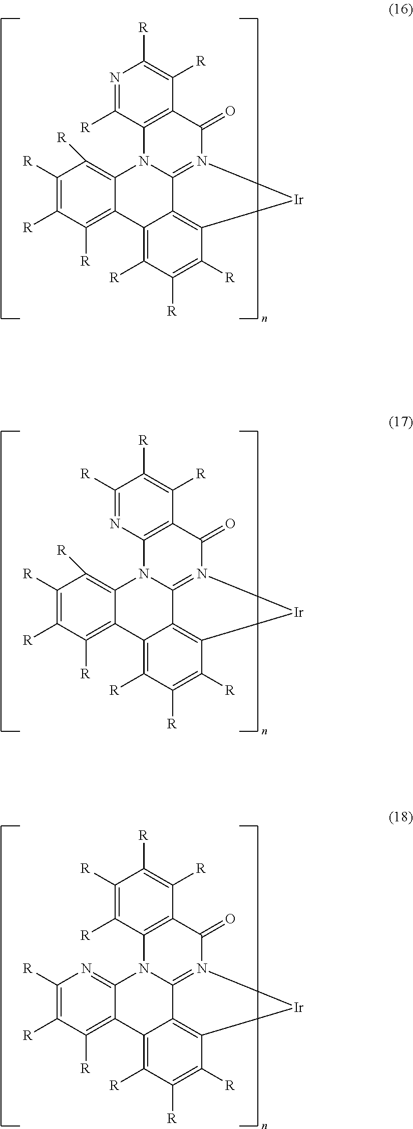

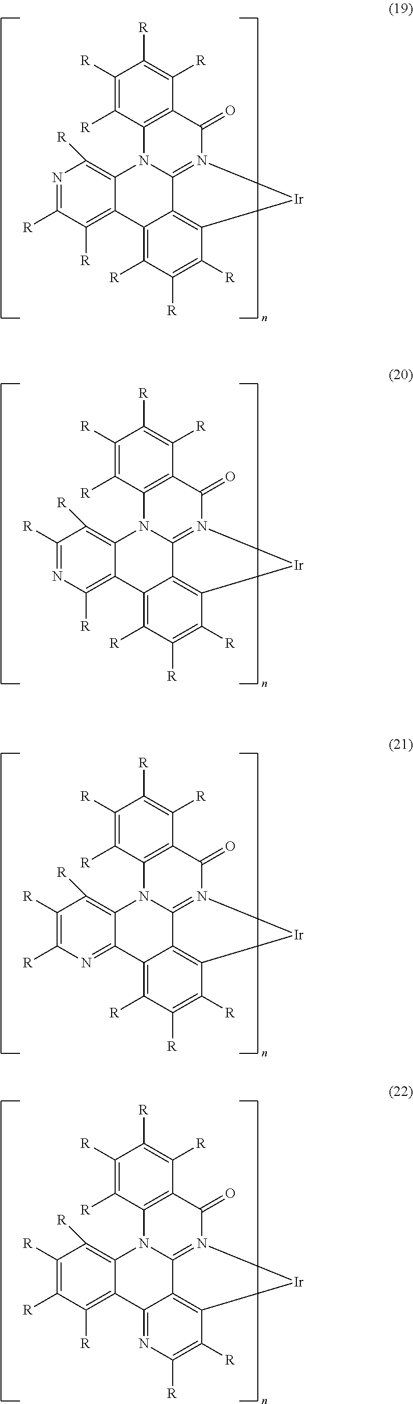

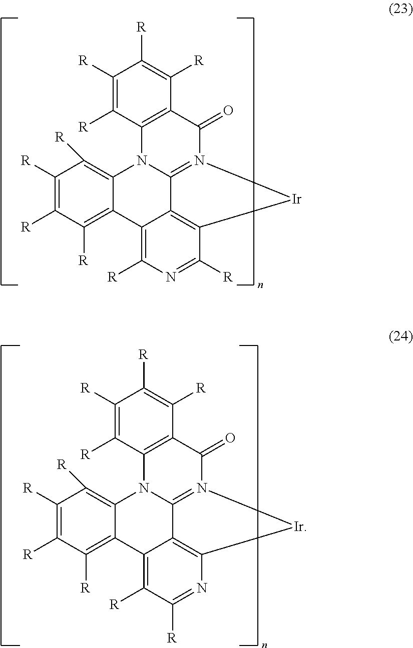

20. The compound of claim 15, wherein if one or more groups X or Y in the moiety of formula (2) is N, a group R selected from the group consisting of CF₃, OCF₃, alkyl or alkoxy groups having 1 to 10 C atoms, dialkylamino groups having 2 to 20 C atoms, aromatic or heteroaromatic ring systems, or aralkyl or heteroaralkyl groups is bonded as a substituent to a position adjacent to this nitrogen atom.

21. The compound of claim 19, wherein, for the structures of formulae (5) to (12) and (14) to (24), at least one group R bonded as a substituent to a position adjacent to a nitrogen atom is selected from the group consisting of CF₃, OCF₃, alkyl or alkoxy groups having 1 to 10 C atoms, dialkylamino groups having 2 to 20 C atoms, aromatic or heteroaromatic ring systems or aralkyl or heteroaralkyl groups.

22. The compound of claim 20, wherein the group R bonded as a substituent to a position adjacent to a nitrogen atom is selected from the group consisting of formulae (R-1) to (R-119): 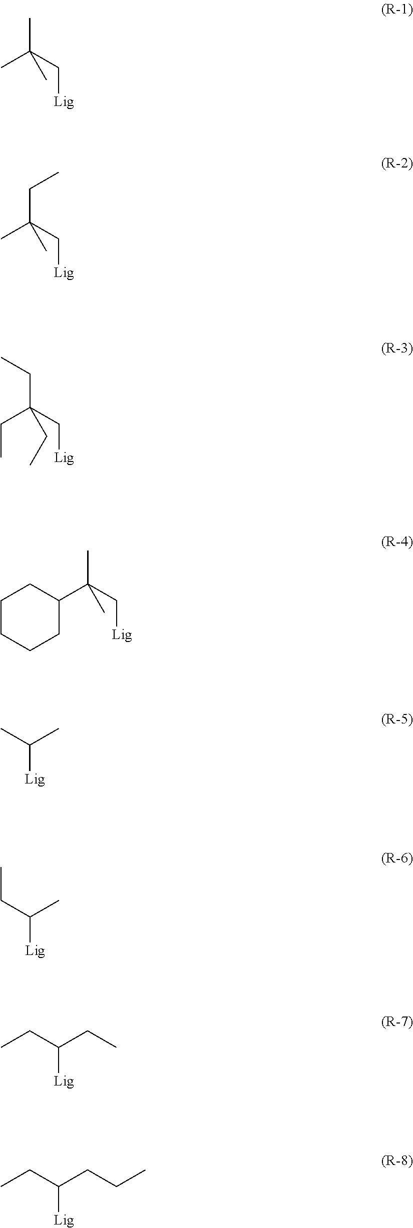 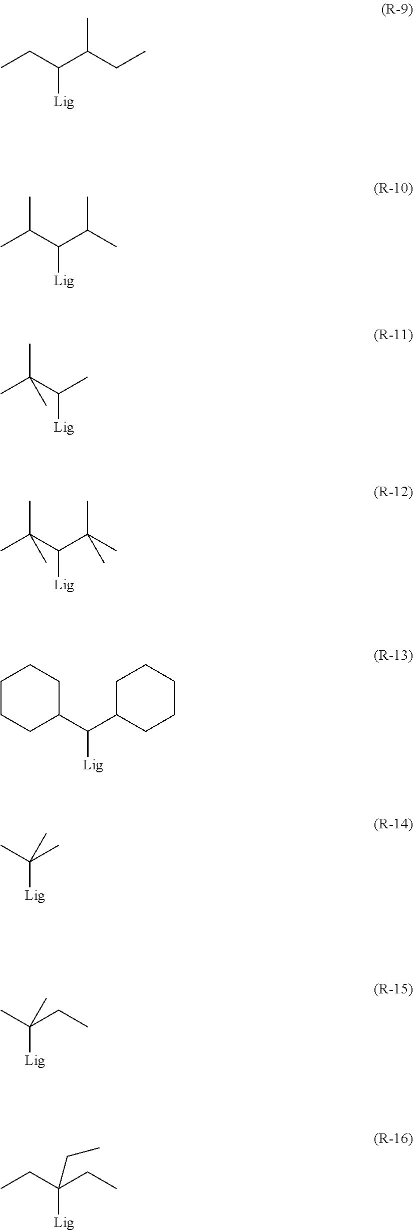 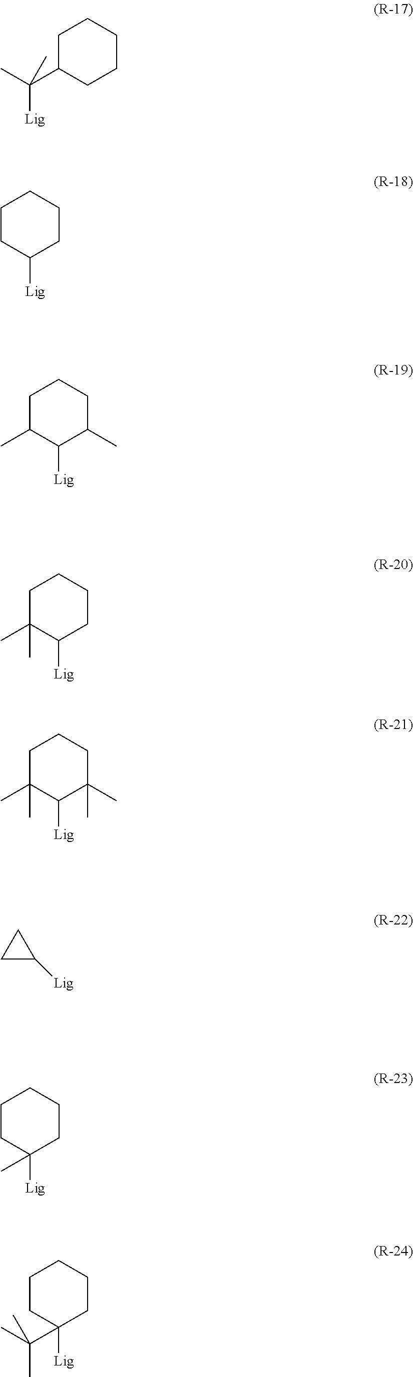 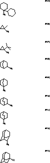 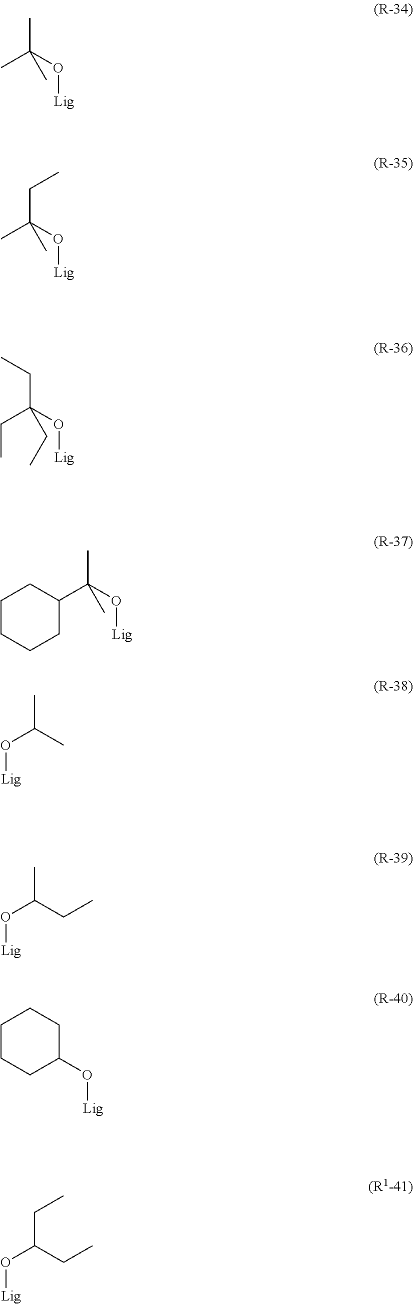 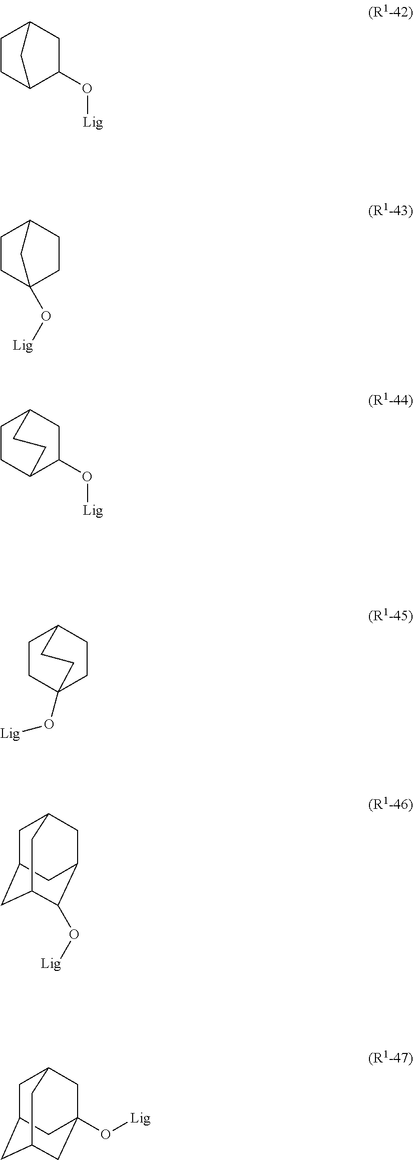 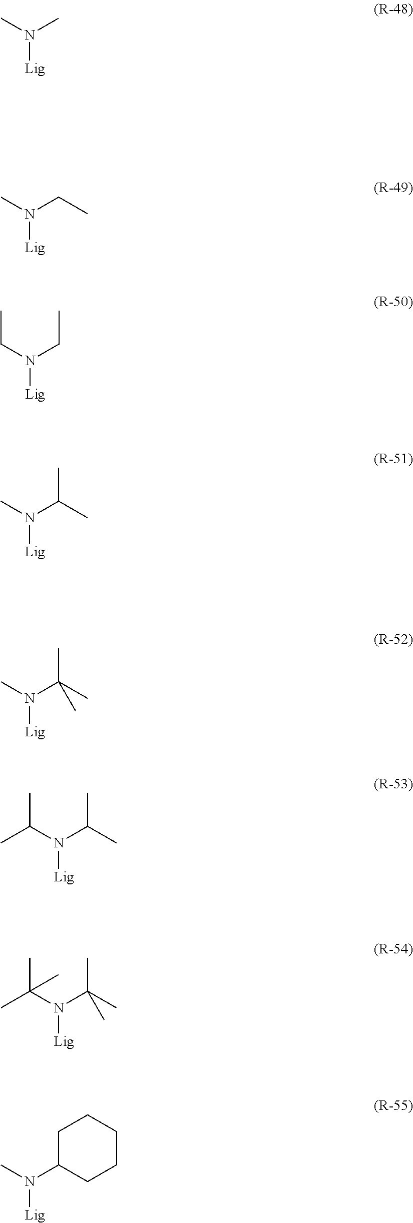 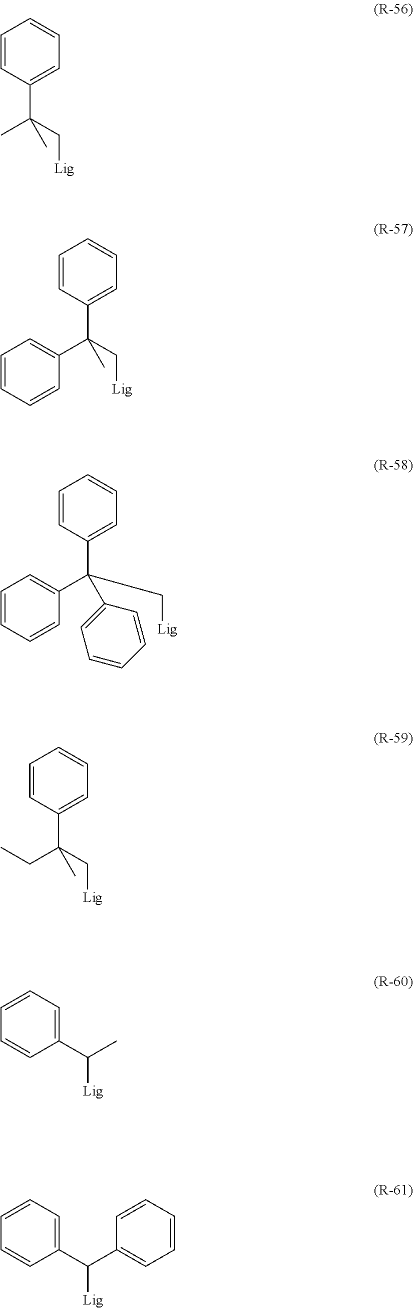 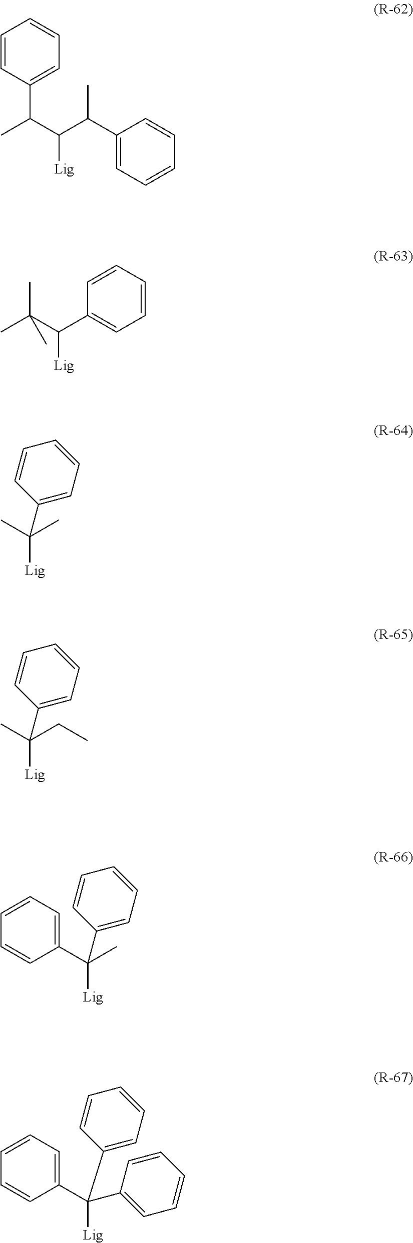 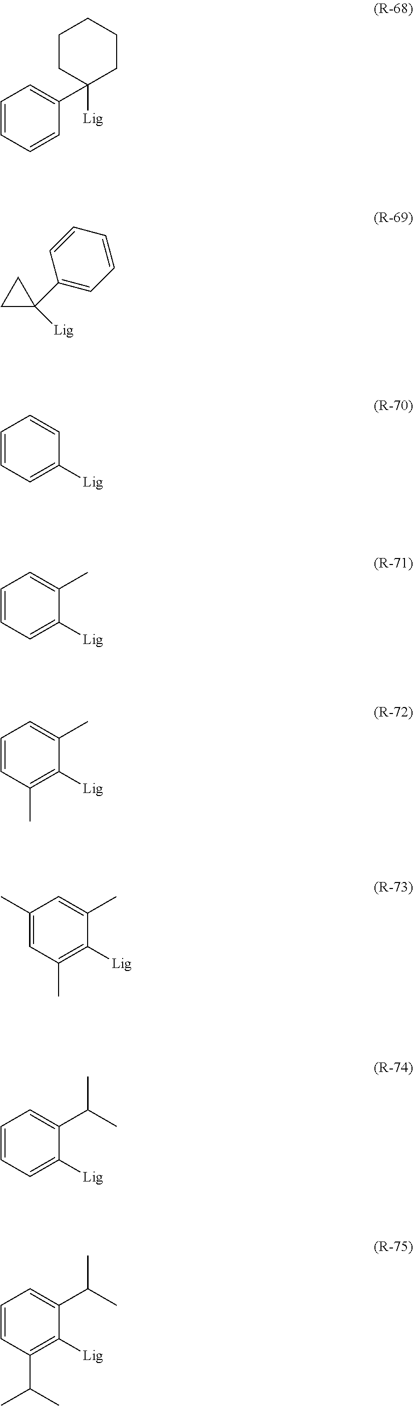 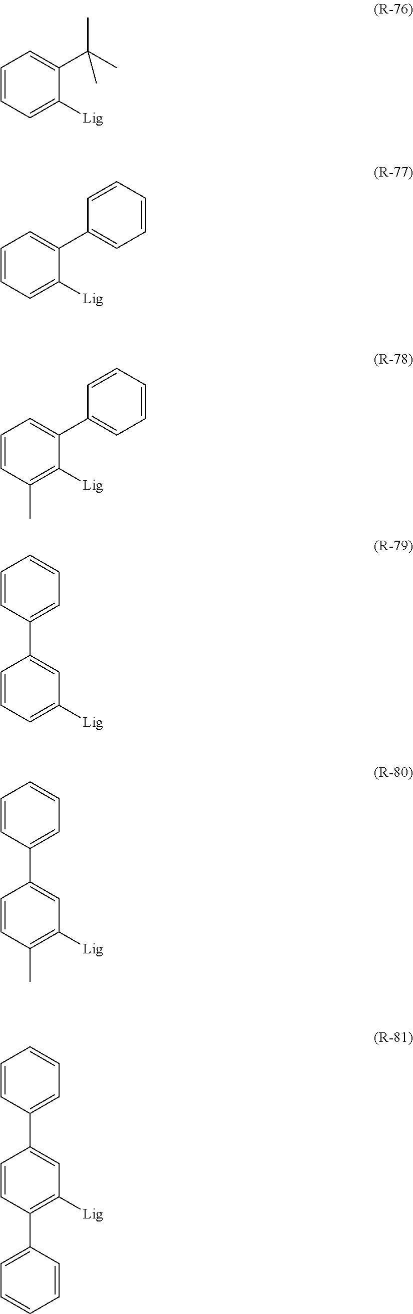 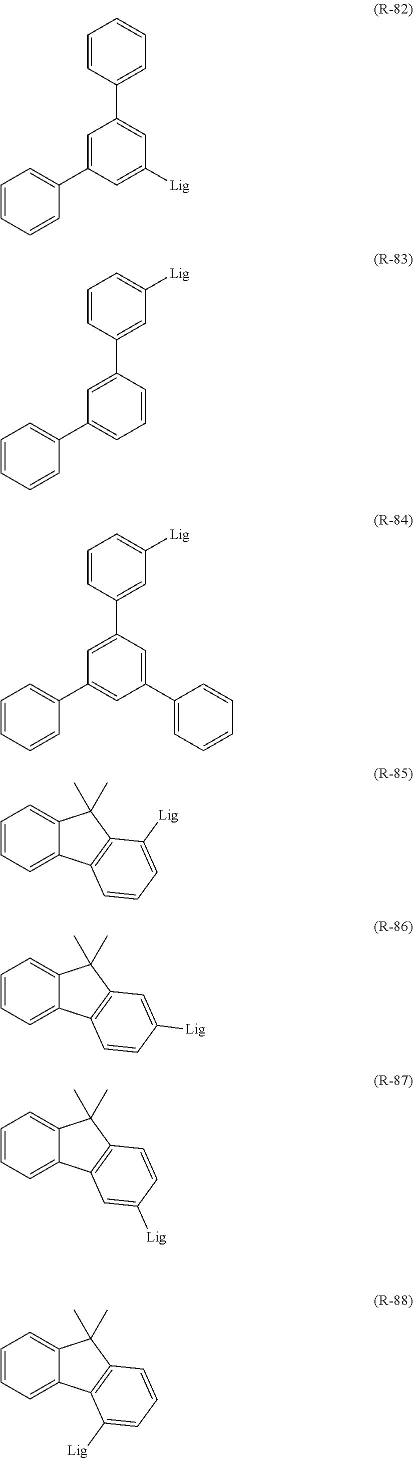 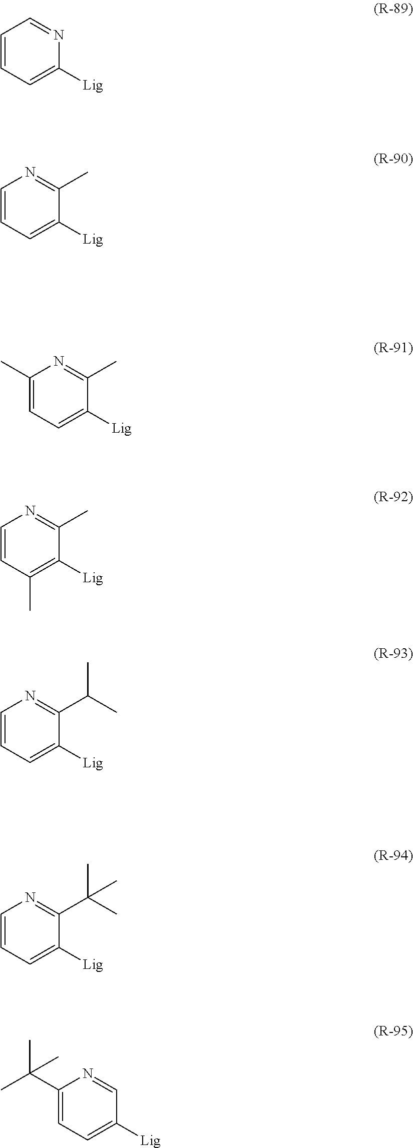 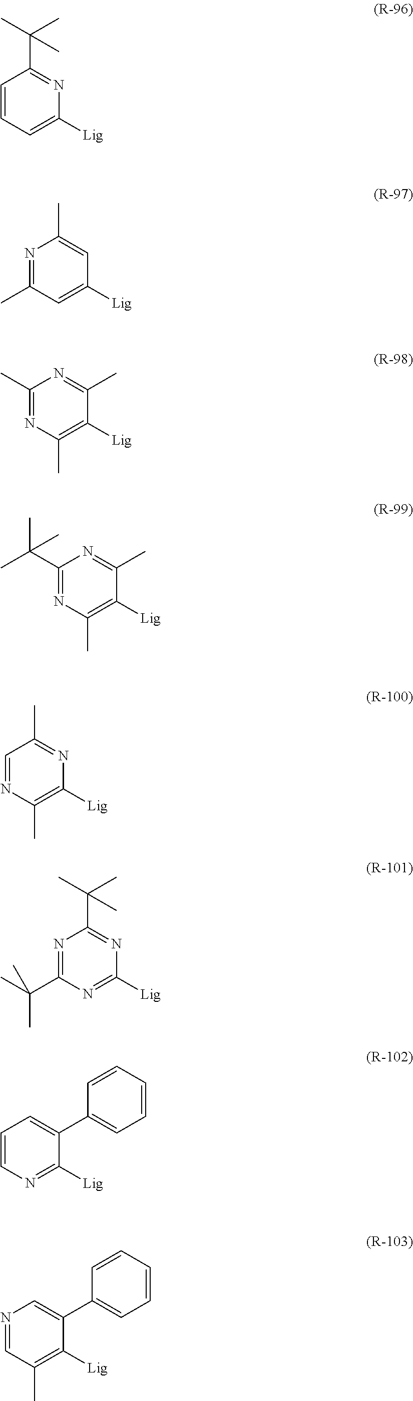 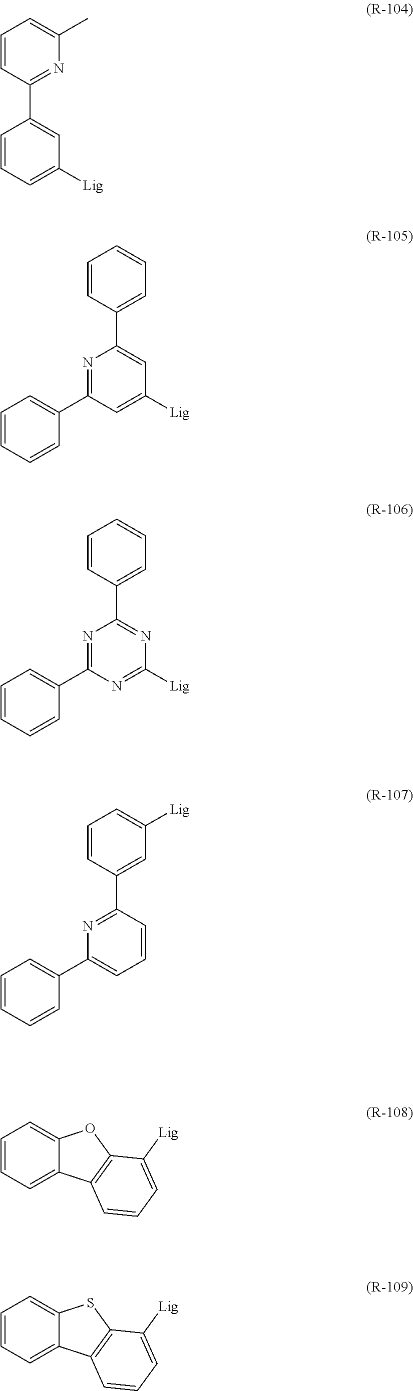 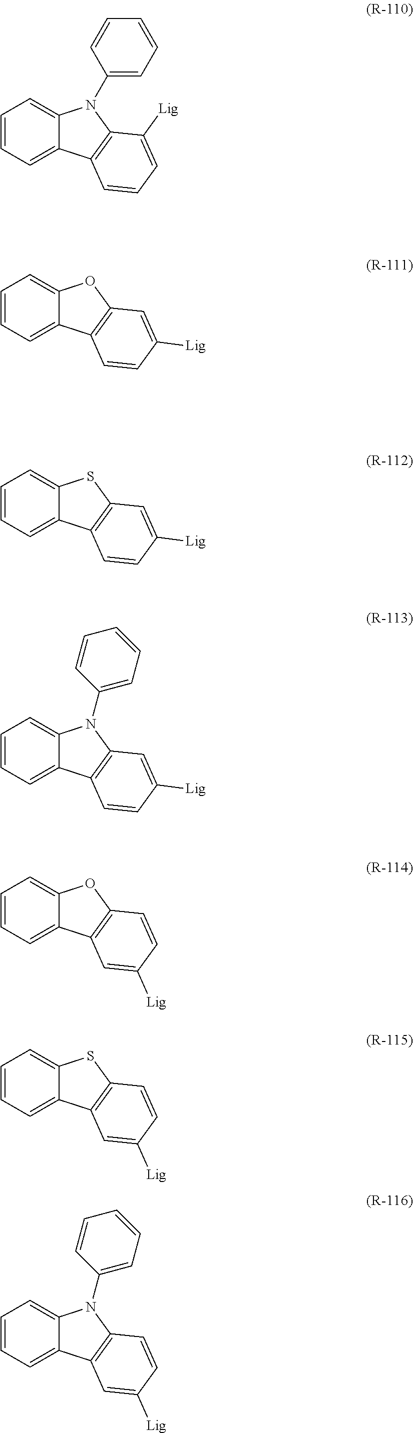 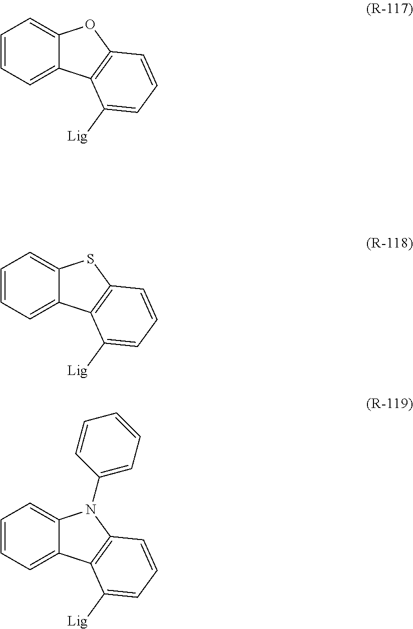
wherein
Lig denotes the linking of the group to the ligand, and the aromatic and heteroaromatic groups are each optionally substituted by one or more radicals R₁.

23. The compound of claim 21, wherein the at least one group R bonded as a substituent to a position adjacent to a nitrogen atom is selected from the group consisting of formulae (R-1) to (R-119): 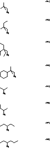 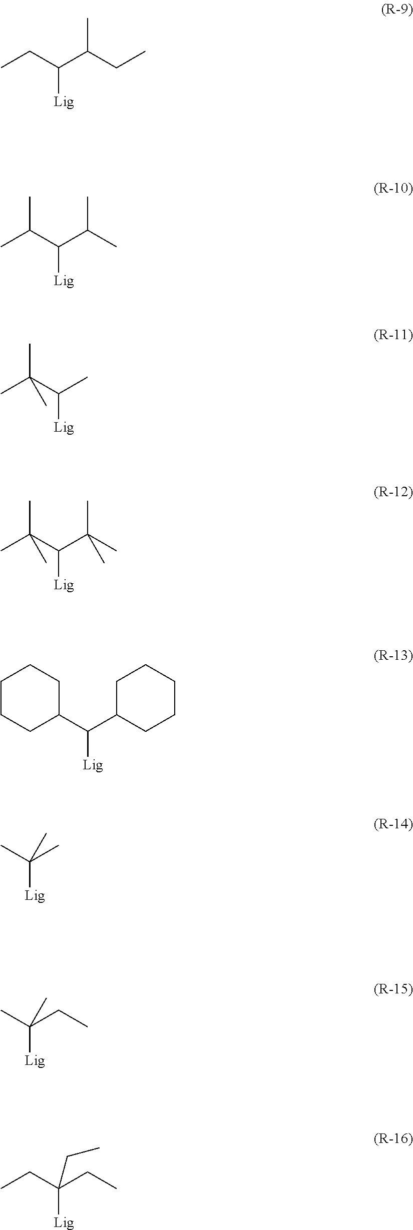 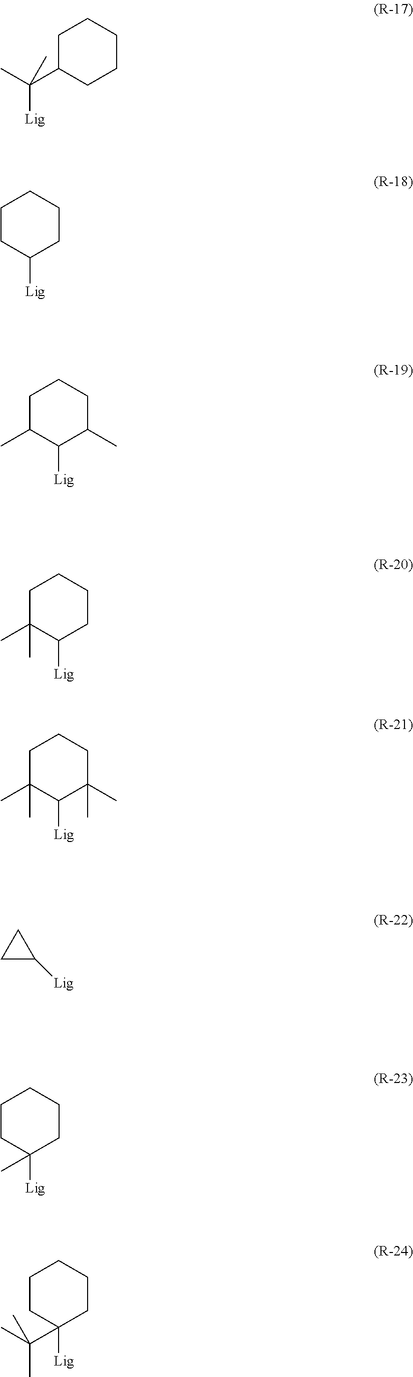 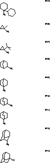 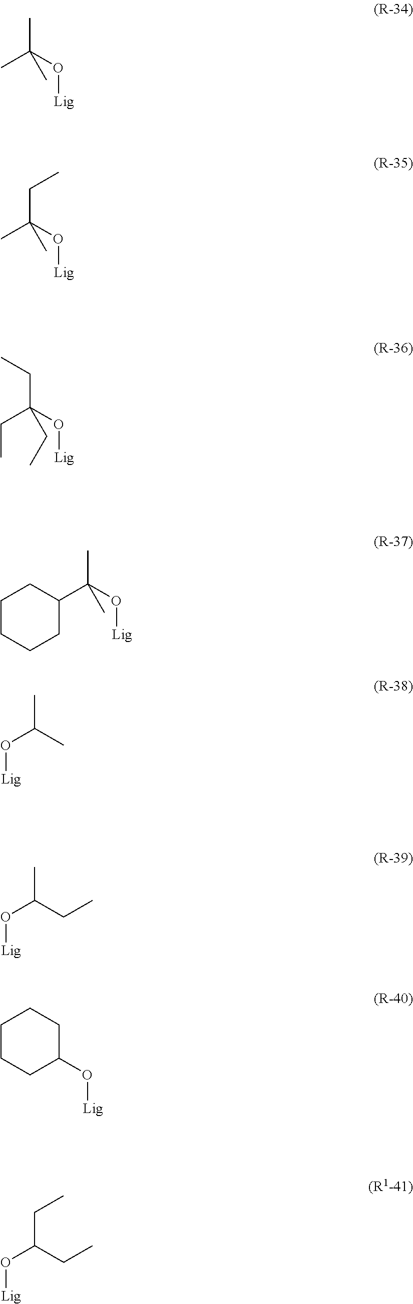 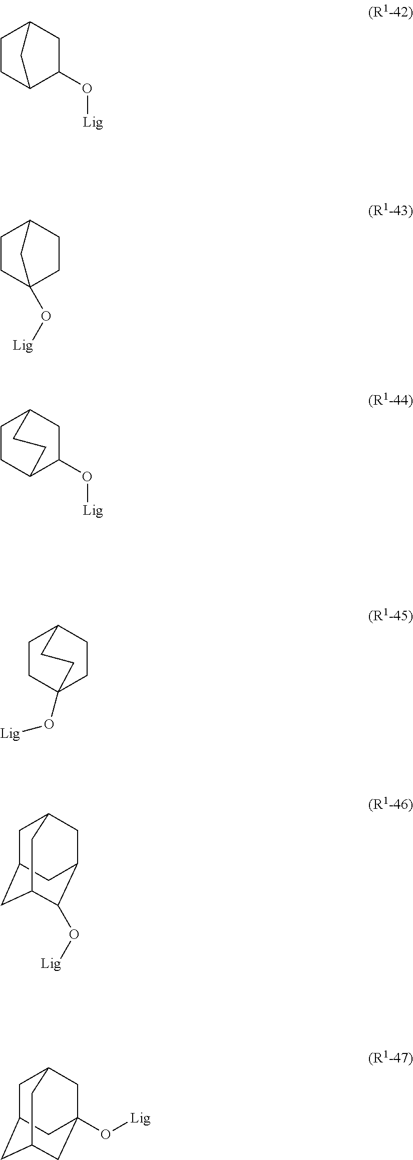 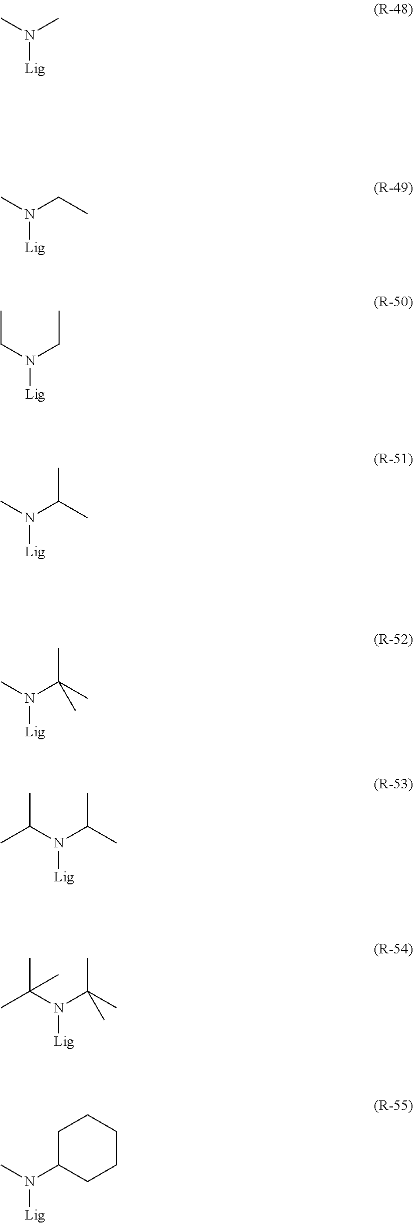 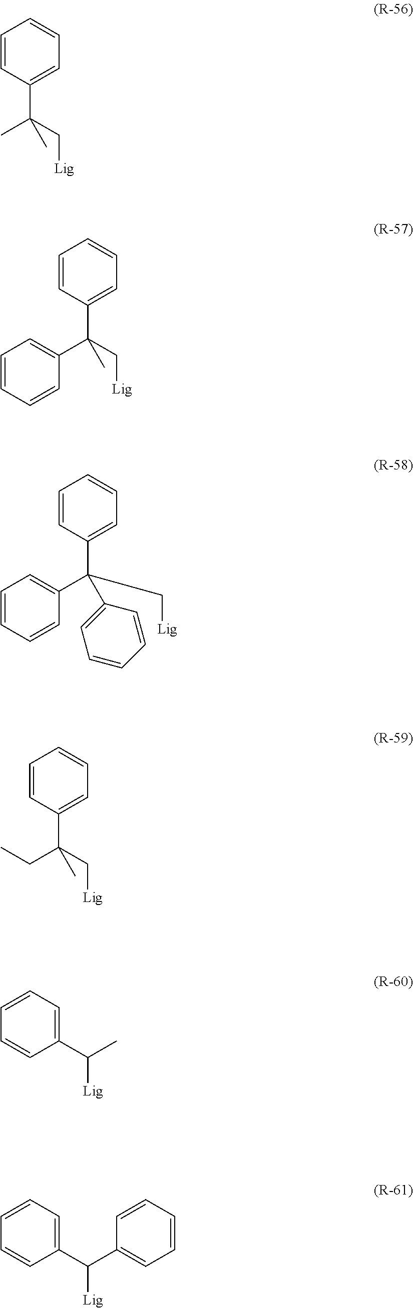 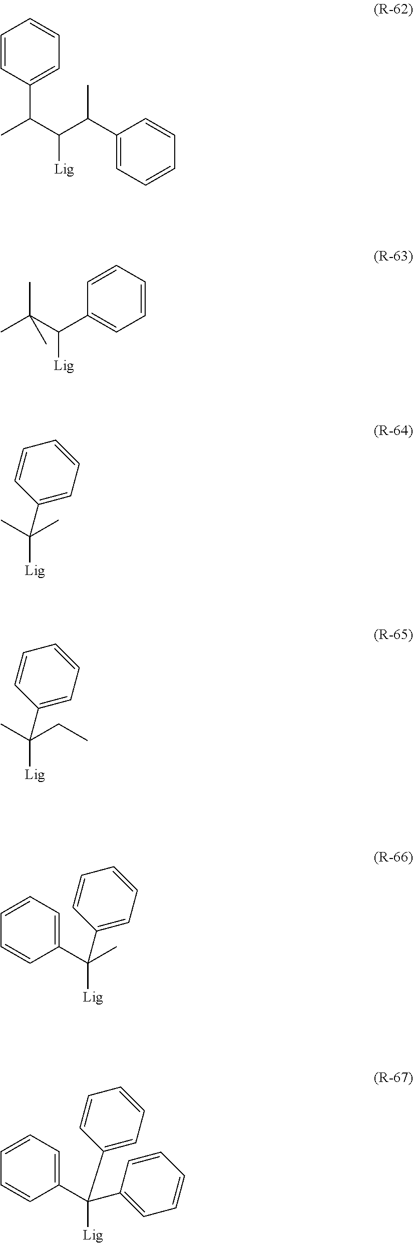 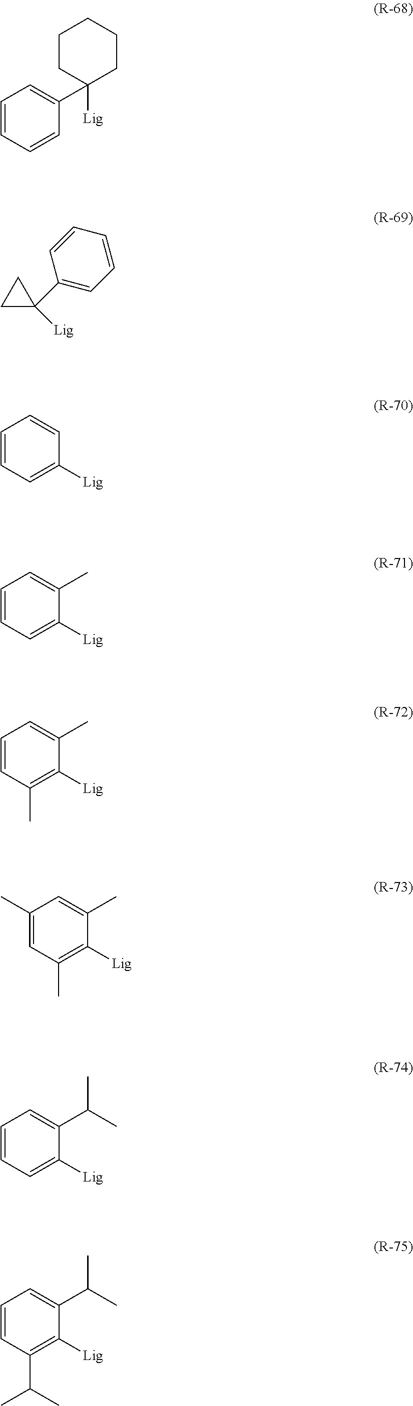 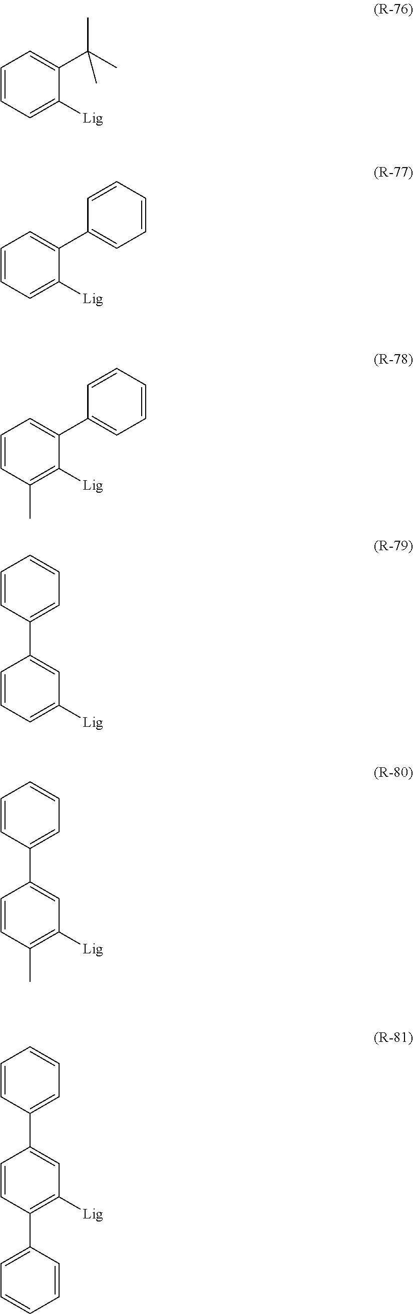 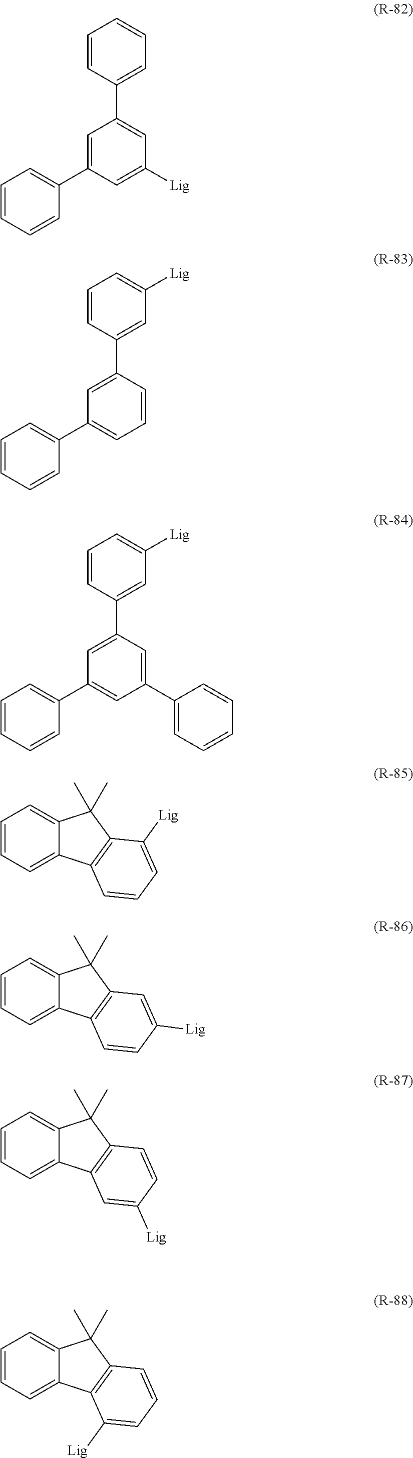 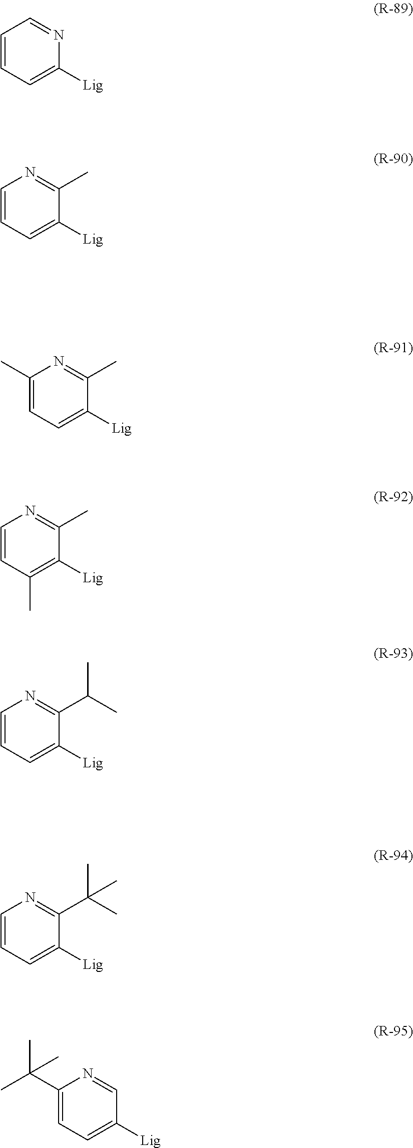 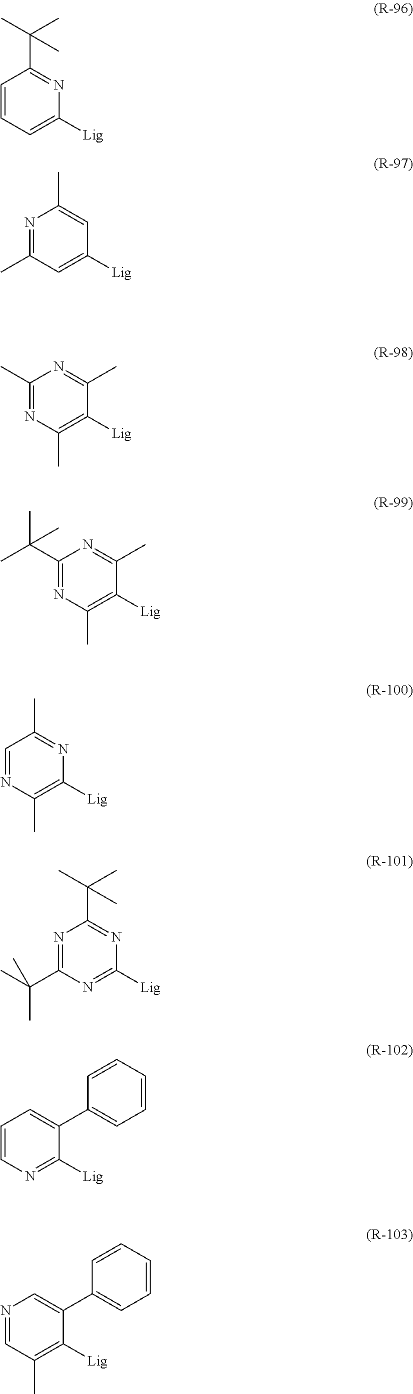 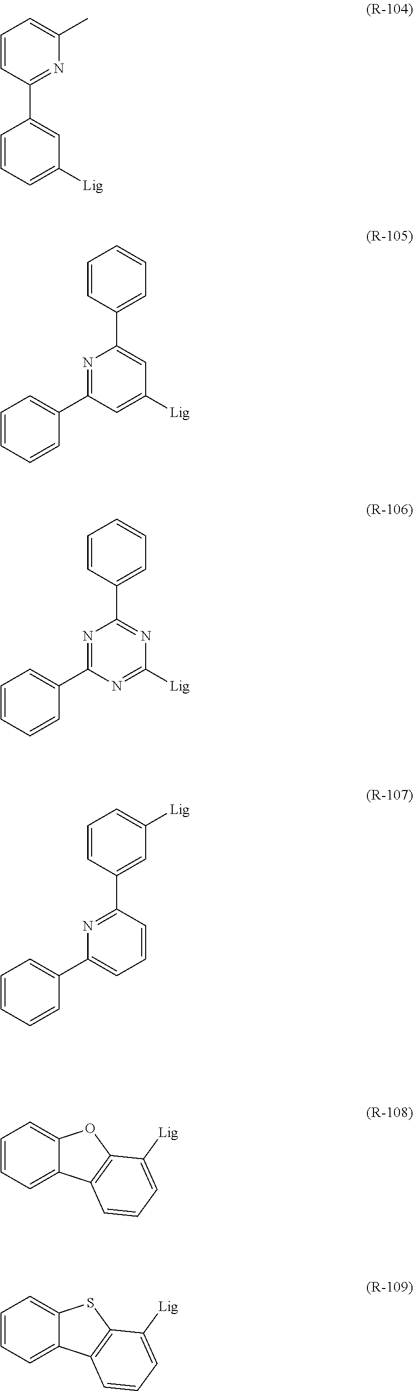 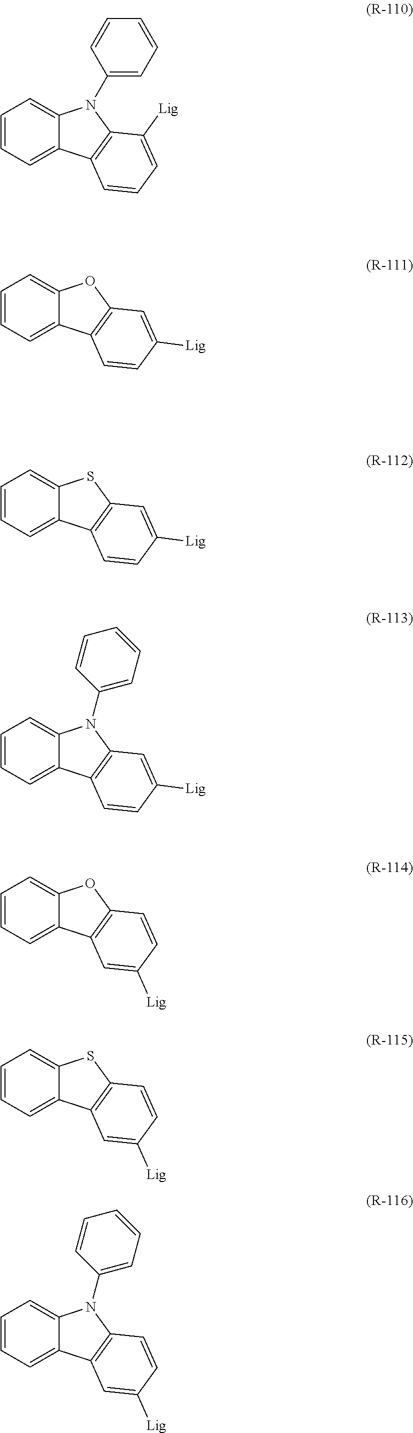 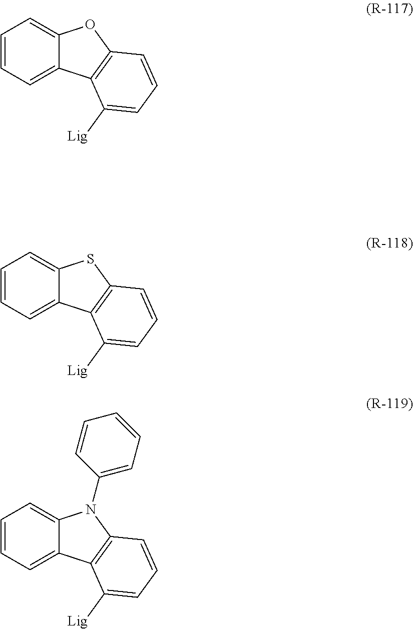
wherein
Lig denotes the linking of the group to the ligand, and the aromatic and heteroaromatic groups are each optionally substituted by one or more radicals R¹.

24. The compound of claim 15, wherein two adjacent X in the moiety of formula (2) are each CR and/or two adjacent Y are each CR, wherein both R, together with the C atoms, define a ring selected from the group consisting of formulae (25) to (31): 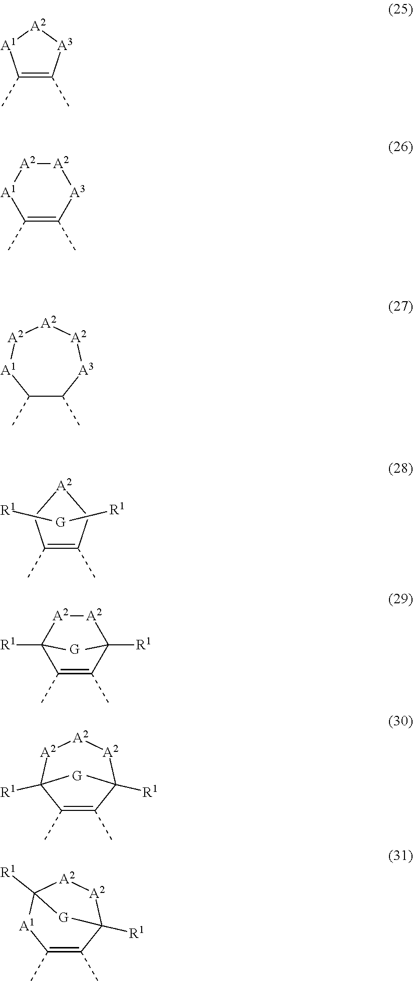
wherein
a plurality of R¹ are optionally linked to one another so as to define a further ring system;
the dashed bonds denote the linking of the two carbon atoms in the ligand;
A^{l} and A³ are, identically or differently on each occurrence, C(R³)₂, O, S, NR³, or C(═O);
A² is, identically or differently on each occurrence, C(R¹)₂, O, S, NR³, or C(═O); or wherein A²-A² in formulae (26), (27), (29), (30), and (31), apart from a combination of the above-mentioned groups, is optionally —CR²═CR²- or an ortho-linked arylene or heteroarylene group having 5 to 14 aromatic ring atoms optionally substituted by one or more radicals R²;
G is an alkylene group having 1, 2, or 3 C atoms optionally substituted by one or more radicals R², —CR²═CR²-, or an ortho-linked arylene or heteroarylene group having 5 to 14 aromatic ring atoms optionally substituted by one or more radicals R²;
R³ is, identically or differently on each occurrence, F, a straight-chain alkyl or alkoxy group having 1 to 10 C atoms, a branched or cyclic alkyl or alkoxy group having 3 to 10 C atoms, each of which are optionally substituted by one or more radicals R², wherein one or more non-adjacent CH₂ groups are optionally replaced by R²C═CR², C≡C, Si(R²)₂, C═O, NR², O, S, or CONR², and wherein one or more H atoms are optionally replaced by D or F, an aromatic or heteroaromatic ring system having 5 to 24 aromatic ring atoms optionally substituted by one or more radicals R², an aryloxy or heteroaryloxy group having 5 to 24 aromatic ring atoms optionally substituted by one or more radicals R², or an aralkyl or heteroaralkyl group having 5 to 24 aromatic ring atoms optionally substituted by one or more radicals R²; wherein two radicals R³ bonded to the same carbon atom optionally define an aliphatic or aromatic ring system with one another so as to define a spiro system; and wherein R³ optionally defines an aliphatic ring system with an adjacent radical R or R¹;
with the proviso that two heteroatoms in these groups are not bonded directly to one another and two groups C═O are not bonded directly to one another.

25. The compound of claim 24, wherein the structure of formulae (25) to (31) is selected from the group consisting of the structures of formulae (25-A) to (25-F), (26-A) to (26-F), (27-A) to (27-E), (28-A) to (28-C), (29-A), (30-A), and (31-A): 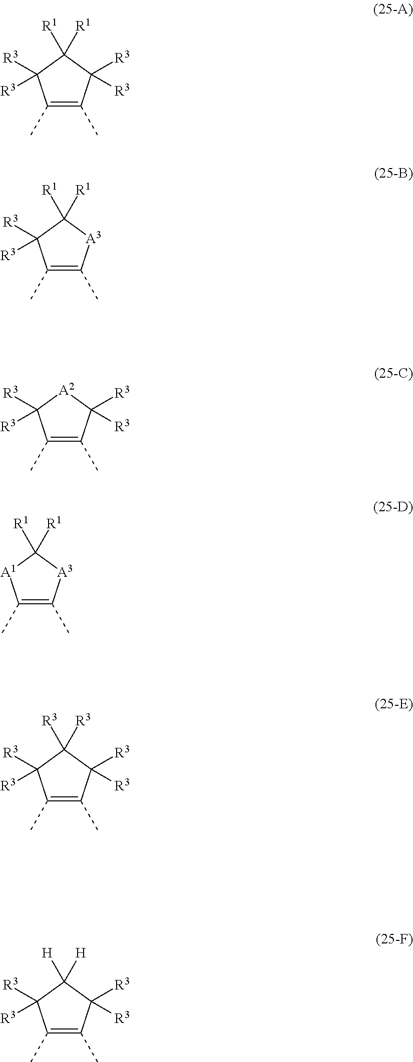 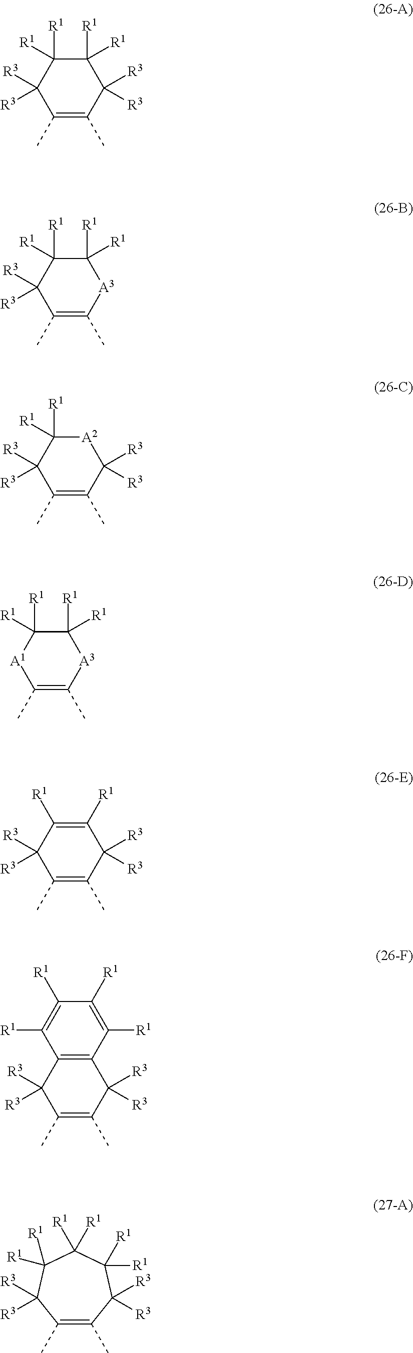 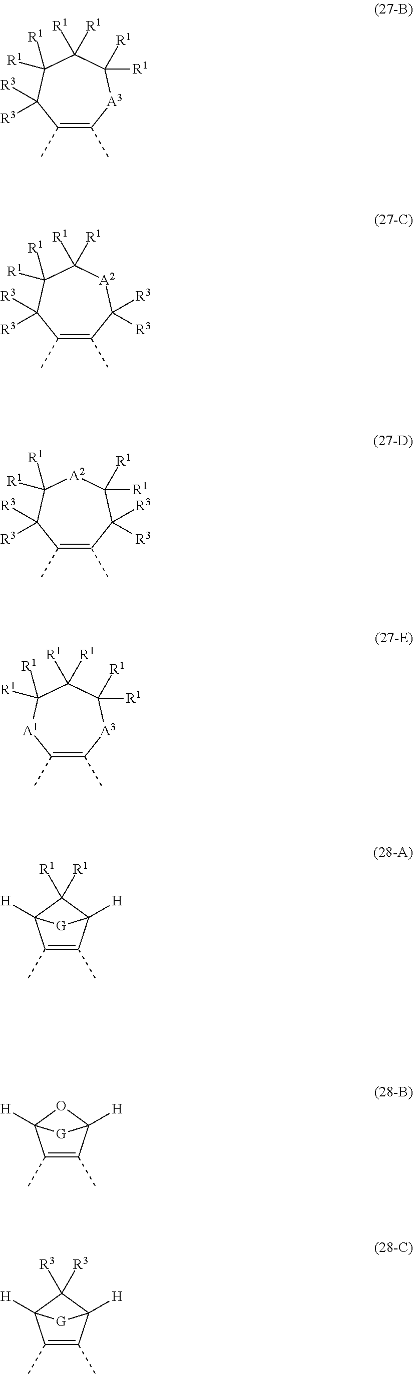 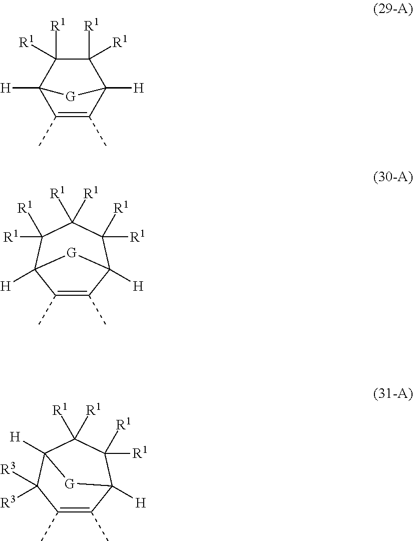
wherein
A¹, A² and A³ are, identically or differently on each occurrence, O or NR³.

26. The compound of claim 15, wherein the ligands L′ are selected from the group consisting of 1,3-diketonates derived from 1,3-diketones, 3-ketonates derived from 3-ketoesters, carboxylates derived from aminocarboxylic acids, carboxylates, 8-hydroxy- or 8-thiohydroxyquinolines, salicyliminates derived from salicylimines, and bidentate monoanionic ligands which, with the iridium, define a cyclometallated five-membered ring or six-membered ring having at least one iridium-carbon bond.

27. The compound of claim 15, wherein the ligands L′ are a combination of two of formulae (32) to (59), wherein the ligand L′ is formed from these groups by these groups bonding to one another, in each case at the position denoted by #: 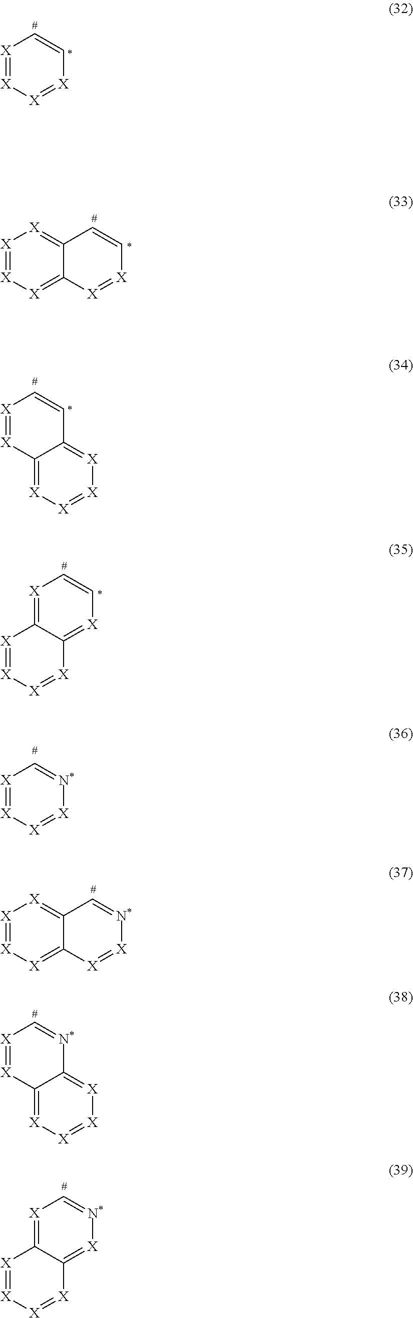 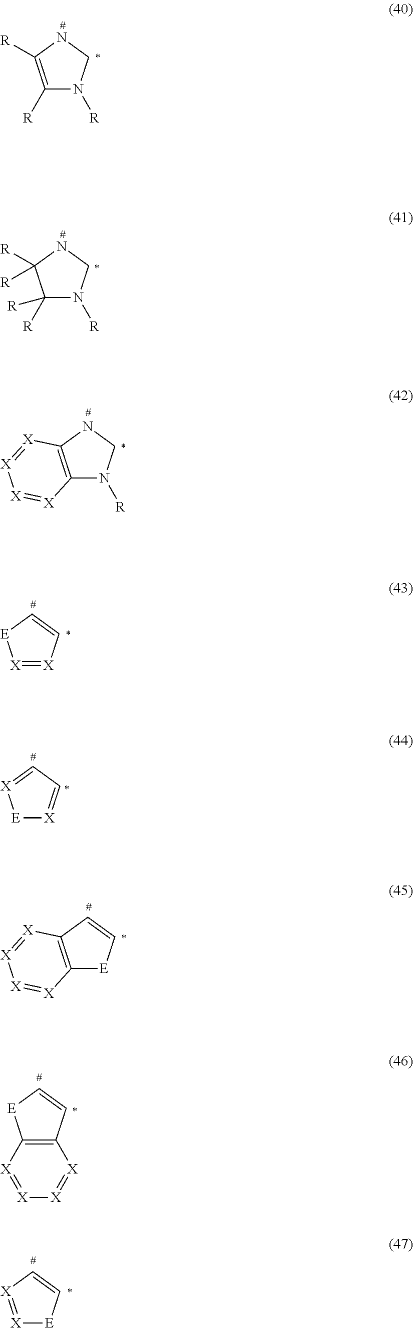 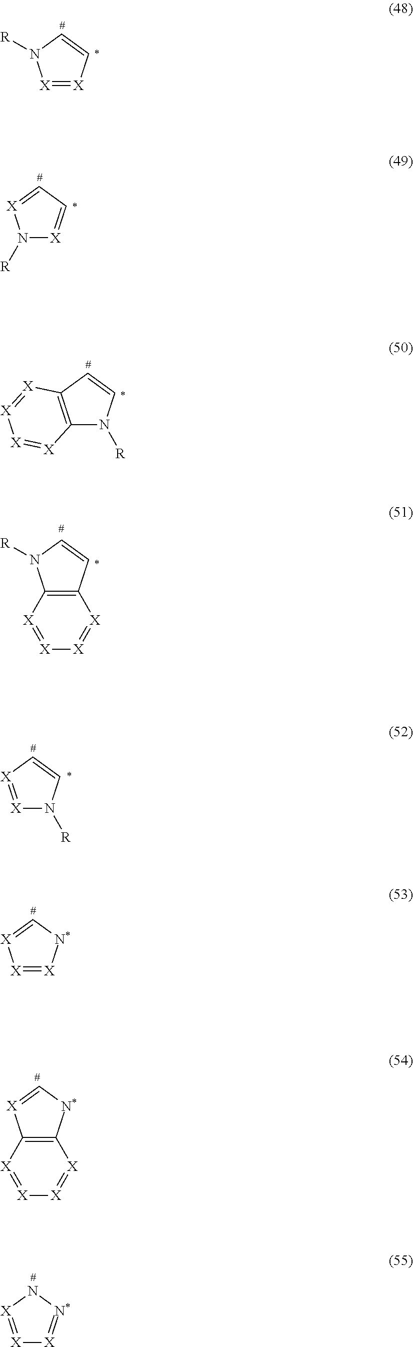 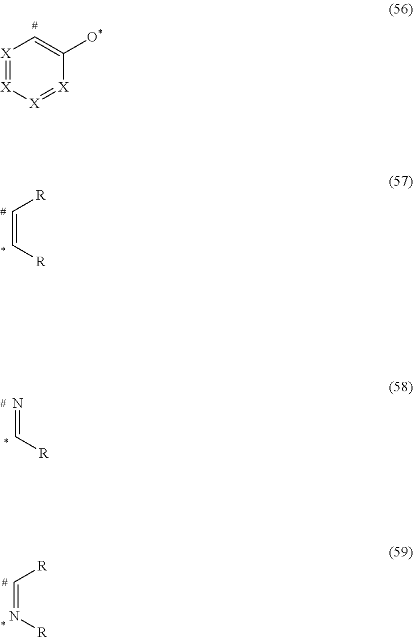
wherein
the position at which the groups coordinate to the metal is denoted by *; and
E is O, S, or CR₂.

28. A process for preparing the compound of claim 15 comprising reacting the corresponding free ligands L and L′ with iridium alkoxides of formula (60), iridium ketoketonates of formula (61), iridium halides of formula (62), dimeric iridium complexes of formula (63) or (64), or iridium compounds which carry both alkoxide and/or halide and/or hydroxyl and also ketoketonate radicals: 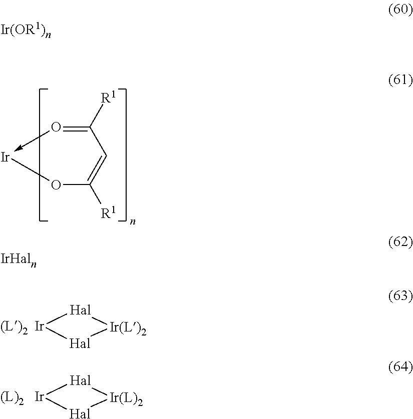
wherein
Hal is F, Cl, Br, or I.

29. A formulation comprising at least one compound of claim 15 and at least one further compound.

30. The formulation of claim 29, wherein the at least one further compound is a solvent.

31. An electronic device comprising the compound of claim 15.

32. An oxygen sensor comprising the compound of claim 15.

33. The electronic device of claim 31, wherein the electronic device is selected from the group consisting of organic electroluminescent devices, organic integrated circuits, organic field-effect transistors, organic thin-film transistors, organic light-emitting transistors, organic solar cells, organic optical detectors, organic photoreceptors, organic field-quench devices, light-emitting electrochemical cells, and organic laser diodes.

34. The electronic device of claim 33, wherein the electronic device is an organic electroluminescent device and wherein the compound is employed as emitting compound in one or more emitting layers.
